(19) United States
(12) Patent Application Publication
(10) Pub. No.: US 2022/0413384 A1
(43) Pub. Date: Dec. 29, 2022

(54) PHOTOSENSITIVE COMPOSITION, FILM, OPTICAL FILTER, SOLID-STATE IMAGING ELEMENT, AND IMAGE DISPLAY DEVICE

(71) Applicant: FUJIFILM Corporation, Tokyo (JP)

(72) Inventor: Hiroaki IDEI, Haibara-gun (JP)

(73) Assignee: FUJIFILM Corporation, Tokyo (JP)

(21) Appl. No.: 17/887,035

(22) Filed: Aug. 12, 2022

Related U.S. Application Data
(63) Continuation of application No. PCT/JP2021/005567, filed on Feb. 15, 2021.

(30) Foreign Application Priority Data
Feb. 20, 2020 (JP) 2020-026819

(51) Int. Cl. G03F 7/031; G03F 7/033; G03F 7/00

(52) U.S. Cl. CPC G03F 7/031; G03F 7/033; G03F 7/0007; G02B 1/04

(57) ABSTRACT

Provided are a photosensitive composition including a coloring material, a photopolymerization initiator, a polymerizable monomer, and a resin, in which the photopolymerization initiator includes an oxime compound OX having an aromatic ring group Ar^{OX1} in which an electron withdrawing group is introduced into an aromatic ring, and a value obtained by dividing a mass of the polymerizable monomer by a mass of the photopolymerization initiator is 0.5 to 5.5; a film; an optical filter; a solid-state imaging element; and an image display device.

### CROSS-REFERENCE TO RELATED APPLICATIONS

This application is a Continuation of PCT International Application No. PCT/JP2021/005567 filed on Feb. 15, 2021, which claims priority under 35 U.S.C § 119(a) to Japanese Patent Application No. 2020-026819 filed on Feb. 20, 2020. Each of the above application(s) is hereby expressly incorporated by reference, in its entirety, into the present application.

### BACKGROUND OF THE INVENTION

### 1. Field of the Invention

The present invention relates to a photosensitive composition including a coloring material, a photopolymerization initiator, a polymerizable monomer, and a resin. The present invention further relates to a film formed of the photosensitive composition, an optical filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter has been used as a key device in a display or an optical element. The color filter normally includes pixels of three primary colors of red, green, and blue, and acts to separate transmitted light into the three primary colors.

Colored pixels of each color of the color filter are manufactured by forming a pattern by a photolithography method using a photosensitive composition including a coloring material such as a pigment. For example, in a photosensitive composition for forming a red pixel, a diketopyrrolopyrrole pigment or the like is used as a coloring material (for example, JP2019-200343A).

### SUMMARY OF THE INVENTION

In recent years, there has been an increasing demand for photosensitive compositions used for forming an optical filter such as a color filter. As such required characteristics, in a case where a pixel (patterned film) is formed on a support by a photolithography method using the photosensitive composition, it is required to have excellent light resistance and adhesiveness to the support, and to be able to form a pixel with small color unevenness and surface roughness. In recent years, it has been required to satisfy these characteristics at a higher level.

From intensive studies with regard to the photosensitive composition disclosed in Examples of JP2019-200343A, the present inventor has found that, for a pixel formed of this photosensitive composition, there is room for further improvement in these characteristics.

Therefore, an object of the present invention is to provide a photosensitive composition which has excellent light resistance and adhesiveness to a support and with which a pixel with small color unevenness and surface roughness can be formed, a film, an optical filter, a solid-state imaging element, and an image display device.

According to the studies conducted by the present inventors, it has been found that the above-described objects can be achieved by a photosensitive composition described below, thereby leading to the completion of the present invention. Therefore, the present invention provides the following.

<1> A photosensitive composition comprising:

a coloring material;

a photopolymerization initiator,

a polymerizable monomer, and

a resin,

in which the photopolymerization initiator includes an oxime compound OX having an aromatic ring group Ar^{OX1} in which an electron withdrawing group is introduced into an aromatic ring, and

a value obtained by dividing a mass of the polymerizable monomer by a mass of the photopolymerization initiator is 0.5 to 5.5.

<2> The photosensitive composition according to <1>,

in which a content of the oxime compound OX in the photopolymerization initiator is 50% to 100% by mass.

<3> The photosensitive composition according to <1> or <2>,

in which the electron withdrawing group included in the aromatic ring group Ar^{OX1} is at least one selected from an acyl group or a nitro group.

<4> The photosensitive composition according to <1> or <2>,

in which the electron withdrawing group included in the aromatic ring group Ar^{OX1} is an acyl group.

<5> The photosensitive composition according to any one of <1> to <4>,

in which the aromatic ring group Ar^{OX1} is a group represented by Formula (OR-1),

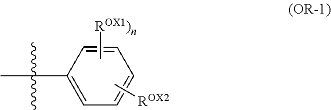

in the formula, R^{OX1} represents a substituent, R^{OX2} represents an electron withdrawing group, n represents an integer of 0) to 4, and a wavy line represents a bonding site.

<6> The photosensitive composition according to any one of <1> to <5>,

in which the oxime compound OX has at least one group selected from a group represented by Formula (OR-11) or a group represented by Formula (OR-12),

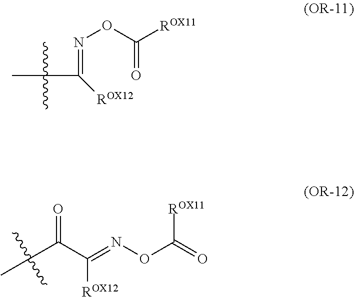

in the formula, R^{OX11} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyl group, an acyloxy group, an amino group, a phosphinoyl group, a carbamoyl group, or a sulfamoyl group,
R^{OX12} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyloxy group, or an amino group, and
a wavy line represents a bonding site.

<7> The photosensitive composition according to any one of <1> to <6>,

in which the oxime compound OX is at least one selected from a compound represented by Formula (OX1) or a compound represented by Formula (OX2),

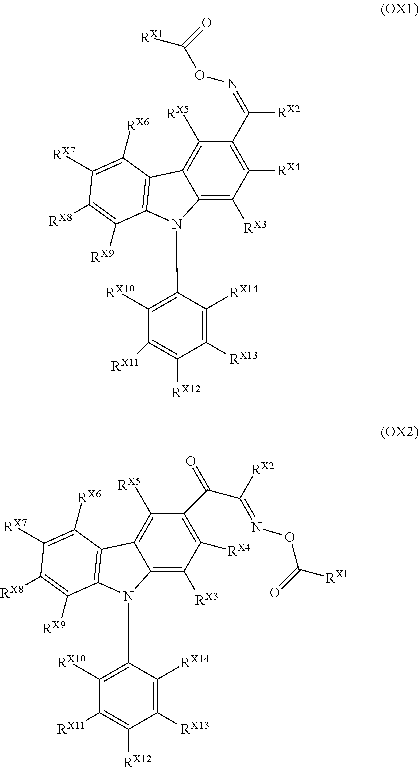

in the formula, R^{X1} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyl group, an acyloxy group, an amino group, a phosphinoyl group, a carbamoyl group, or a sulfamoyl group,
R^{X2} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyloxy group, or an amino group,
R^{X3} to R^{X14} each independently represent a hydrogen atom or a substituent, and
at least one of R^{X10}, . . . , or R^{X14} is an electron withdrawing group.

<8> The photosensitive composition according to any one of <1> to <7>,

in which the polymerizable monomer includes a compound having 3 ethylenically unsaturated bond-containing groups.

<9> The photosensitive composition according to any one of <1> to <8>,

in which an ethylenically unsaturated bond-containing group value of the polymerizable monomer is 100 to 300 g/mol.

<10> The photosensitive composition according to any one of <1> to <9>.

in which a content of the coloring material in a total solid content of the photosensitive composition is 50% by mass or more.

<11> The photosensitive composition according to any one of <1> to <10>,

in which a content of the polymerizable monomer in a total solid content of the photosensitive composition is 1% to 25% by mass.

<12> The photosensitive composition according to any one of <1> to <11>,

in which the photosensitive composition is used for a solid-state imaging element.

<13> The photosensitive composition according to any one of <1> to <12>,

in which the photosensitive composition is a photosensitive composition for forming a pixel for a cyan color, a yellow color, or a magenta color.

<14> A film formed of the photosensitive composition according to any one of <1> to <13>.

<15> An optical filter comprising:

the film according to <14>.

<16> A solid-state imaging element comprising:

the film according to <14>.

<17> An image display device comprising:

the film according to <14>.

According to the present invention, it is possible to provide a photosensitive composition which has excellent light resistance and adhesiveness to a support and with which a pixel with small color unevenness and surface roughness can be formed, a film, an optical filter, a solid-state imaging element, and an image display device.

### DESCRIPTION OF THE PREFERRED EMBODIMENTS

Hereinafter, the details of the present invention will be described.

In the present specification, “to” is used to refer to a meaning including numerical values denoted before and after “to” as a lower limit value and an upper limit value.

In the present specification, unless specified as a substituted group or as an unsubstituted group, a group (atomic group) denotes not only a group (atomic group) having no substituent but also a group (atomic group) having a substituent. For example, an “alkyl group” includes not only an alkyl group having no substituent (unsubstituted alkyl group), but also an alkyl group having a substituent (substituted alkyl group).

In the present specification, unless specified otherwise. “exposure” denotes not only exposure using light but also drawing using a corpuscular beam such as an electron beam or an ion beam. In addition, examples of light used for the exposure include actinic rays or radiation such as a bright line spectrum of a mercury lamp, far ultraviolet rays typified by an excimer laser, extreme ultraviolet rays (EUV light), X-rays, or electron beams.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in structural formulae, Me represents a methyl group, Et represents an ethyl group, Bu represents a butyl group, and Ph represents a phenyl group.

In the present specification, a weight-average molecular weight and a number-average molecular weight are values in terms of polystyrene through measurement by a gel permeation chromatography (GPC) method.

In the present specification, a total solid content denotes the total mass of all the components of the composition excluding a solvent.

In the present specification, a pigment means a compound which is hardly dissolved in a solvent.

In the present specification, the term “step” is not only an independent step, but also includes a step which is not clearly distinguished from other steps in a case where an intended action of the step is obtained.

<Photosensitive Composition>

A photosensitive composition according to an embodiment of the present invention includes a coloring material, a photopolymerization initiator, a polymerizable monomer, and a resin, in which the photopolymerization initiator includes an oxime compound OX having an aromatic ring group Ar^{OX1} in which an electron withdrawing group is introduced into an aromatic ring, and a value obtained by dividing a mass of the polymerizable monomer by a mass of the photopolymerization initiator is 0.5 to 5.5.

With the photosensitive composition according to the embodiment of the present invention, it is possible to have excellent light resistance and adhesiveness to a support, and to form a pixel with small color unevenness and surface roughness. The reason for obtaining such an effect is presumed as follows.

In the photosensitive composition according to the embodiment of the present invention, it is presumed that the above-described oxime compound OX used as the photopolymerization initiator easily interacts with the coloring material, and in the photosensitive composition, it is presumed that the coloring material and the oxime compound OX are present in close proximity to each other. In a case where an amount of the photopolymerization initiator is too small with respect to the polymerizable monomer, a frequency of collision between active species such as radicals, which are generated from the photopolymerization initiator by light irradiation during exposure, and the polymerizable monomer tends to decrease, and it is presumed that points where a curing reaction of the polymerizable monomer in an exposed portion does not proceed sufficiently are likely to be present. In addition, in a case where the amount of the photopolymerization initiator is too large with result to the polymerizable monomer, curing of the polymerizable monomer around the coloring material tends to proceed locally on a surface of the film with a large amount of light during exposure, and as a result, it is presumed that the surface roughness of the film (pixel) after development tends to be large. In the photosensitive composition according to the embodiment of the present invention, since the above-described oxime compound OX is included as the photopolymerization initiator, and the value obtained by dividing the mass of the polymerizable monomer by the mass of the photopolymerization initiator is 0.5 to 5.5, it is presumed that the light irradiation during exposure can uniformly promote the curing of the photosensitive composition layer in the exposed portion. As a result, it is presumed that the adhesiveness is good, and the color unevenness and surface roughness of the film (pixel) after development can be smaller.

In addition, in the photosensitive composition according to the embodiment of the present invention, the above-described oxime compound OX used as the photopolymerization initiator has the aromatic ring group Ar^{OX1} in which an electron withdrawing group is introduced into an aromatic ring, and it is presumed that a site of this aromatic ring group Ar^{OX1} acts as an ultraviolet absorber. As a result, it is presumed that the pixel having excellent light resistance can be formed.

In the photosensitive composition according to the embodiment of the present invention, the value obtained by dividing the mass of the polymerizable monomer by the mass of the photopolymerization initiator (hereinafter, also referred to as an M/i ratio) is 0.5 to 5.5. From the reason that the adhesiveness is good and a pixel with smaller color unevenness can be formed, the upper limit of the M/I ratio is preferably 4.0 or less and more preferably 3.5 or less. In addition, from the reason that a pixel with smaller surface roughness can be formed, the lower limit of the M/I ratio is preferably 1.0 or more, more preferably 1.5 or more, and still more preferably 2.0 or more. In the present specification, the “mass of the polymerizable monomer” used for calculating the above-described M/I ratio is the total mass of all polymerizable monomers included in the photosensitive composition. Therefore, in a case where two or more kinds of polymerizable monomers are included in the photosensitive composition, the total mass thereof is taken as the mass of the polymerizable monomer. Similarly, the “mass of the photopolymerization initiator” used for calculating the above-described MA ratio is the total mass of all photopolymerization initiators included in the photosensitive composition. Therefore, in a case where two or more kinds of photopolymerization initiators are included in the photosensitive composition, the total mass thereof is taken as the mass of the photopolymerization initiator.

In addition, in the photosensitive composition according to the embodiment of the present invention, a value obtained by dividing the mass of the polymerizable monomer by a mass of the oxime compound OX (hereinafter, also referred to as an M/I^{OX} ratio) is preferably 0.5 to 5.5. In addition, from the reason that the adhesiveness is good and a pixel with smaller color unevenness can be formed, the upper limit of the M/I^{OX} ratio is preferably 4.0 or less and more preferably 3.5 or less. In addition, from the reason that a pixel with smaller surface roughness can be formed, the lower limit of the M/I^{OX} ratio is preferably 1.0 or more, more preferably 1.5 or more, and still more preferably 2.0 or more. In the present specification, the “mass of the oxime compound OX” used for calculating the above-described M/I^{OX} ratio is the total mass of all oxime compounds OX included in the photosensitive composition. Therefore, in a case where two or more kinds of oxime compounds OX are included in the photosensitive composition, the total mass thereof is taken as the mass of the oxime compound OX.

In addition, in the photosensitive composition according to the embodiment of the present invention, a value obtained by dividing the mass of the polymerizable monomer by a mass of the coloring material (hereinafter, also referred to as an M/P ratio) is preferably 0.01 to 1.0. From the viewpoint of spectral characteristics of the film, the upper limit of the M/P ratio is preferably 0.5 or less and more preferably 0.35 or less. In addition, from the reason that the adhesiveness is good and a pixel with smaller color unevenness can be easily formed, the lower limit of the MP ratio is preferably 0.03 or more, more preferably 0.05 or more, and still more preferably 0.1 or more. In the present specification, the “mass of the coloring material” used for calculating the above-described M/P ratio is the total mass of all coloring materials included in the photosensitive composition. Therefore, in a case where two or more kinds of coloring materials are included in the photosensitive composition, the total mass thereof is taken as the mass of the coloring material.

The photosensitive composition according to the embodiment of the present invention is preferably used as a photosensitive composition for an optical filter. Examples of the optical filter include a color filter and a near infrared transmitting filter, and a color filter is preferable.

In addition, the photosensitive composition according to the embodiment of the present invention can be preferably used as a photosensitive composition for a solid-state imaging element, and can be more preferably used as a photosensitive composition for forming a pixel of a color filter used in the solid-state imaging element.

Examples of the color filter include a filter having a colored pixel which transmits light having a specific wavelength, and a filter having at least one colored pixel selected from a red pixel, a blue pixel, a green pixel, a yellow pixel, a cyan pixel, or a magenta pixel is preferable. The colored pixel of the color filter can be formed using a photosensitive composition containing a chromatic coloring material.

That is, the photosensitive composition according to the embodiment of the present invention can be preferably used as a photosensitive composition for forming a red, blue, green, yellow, cyan, or magenta pixel.

Examples of one aspect thereof include an aspect in which the photosensitive composition according to the embodiment of the present invention is used as a photosensitive composition for forming a red, blue, or green pixel. In this case, it is possible to form a pixel having a higher color value and excellent spectral characteristics.

Examples of another aspect thereof include an aspect in which the photosensitive composition according to the embodiment of the present invention is used as a photosensitive composition for forming a yellow, cyan, or magenta pixel. Pixels of these hues tend to have a large effect on the spectral characteristics due to color unevenness, but according to the present invention, a pixel with smaller color unevenness can be formed, so that in a case of being applied to pixels of these hues, the effects of the present invention are more prominently exhibited.

The near infrared transmitting filter is a filter which transmits at least a part of near infrared rays. Examples of the near infrared transmitting filter include a filter which shields at least a part of visible light and transmits at least a part of near infrared rays. Preferred examples of the near infrared transmitting filter include filters satisfying spectral characteristics in which the maximum value of a transmittance in a wavelength range of 400 to 640 nm is 20% or less (preferably 15% or less and more preferably 10% or less) and the minimum value of a transmittance in a wavelength range of 1100 to 1300 nm is 70% or more (preferably 75% or more and more preferably 80% or more). The near infrared transmitting filter is preferably a filter which satisfies any one of the following spectral characteristics (1) to (4).

(1): filter in which the maximum value of a transmittance in a wavelength range of 400 to 640 nm is 20% or less (preferably 15% or less and more preferably 10% or less) and the minimum value of a transmittance in a wavelength range of 800 to 1300 nm is 70% or more (preferably 75% or more and more preferably 80% or more).

(2): filter in which the maximum value of a transmittance in a wavelength range of 400 to 750 nm is 20% or less (preferably 15% or less and more preferably 10% or less) and the minimum value of a transmittance in a wavelength range of 900 to 1300 nm is 70% or more (preferably 75% or more and more preferably 80% or more).

(3): filter in which the maximum value of a transmittance in a wavelength range of 400 to 830 nm is 20% or less (preferably 15% or less and more preferably 10% or less) and the minimum value of a transmittance in a wavelength range of 1000 to 1300 nm is 70% or more (preferably 75% or more and more preferably 80% or more).

(4): filter in which the maximum value of a transmittance in a wavelength range of 400 to 950 nm is 20% or less (preferably 15% or less and more preferably 10% or less) and the minimum value of a transmittance in a wavelength range of 1100 to 1300 nm is 70% or more (preferably 75% or more and more preferably 80% or more).

Hereinafter, each of the components used in the photosensitive composition according to the embodiment of the present invention will be described.

<<Coloring Material>>

The photosensitive composition according to the embodiment of the present invention contains a coloring material. Examples of the coloring material include a chromatic coloring material and a black coloring material, and a chromatic coloring material is preferable. In a case of using a chromatic coloring material as the coloring material, the photosensitive composition according to the embodiment of the present invention can be preferably used as a photosensitive composition for forming a colored pixel in a color filter.

The coloring material may be a pigment or a dye. The pigment and the dye may be used in combination. In addition, the pigment may be either an inorganic pigment or an organic pigment. In addition, as the pigment, a material in which a part of an inorganic pigment or an organic-inorganic pigment is substituted with an organic chromophore can also be used. By substituting an inorganic pigment or an organic-inorganic pigment with an organic chromophore, hue design can be easily performed.

An average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersion stability of the pigment in the photosensitive composition is good. In the present invention, the primary particle diameter of the pigment can be determined from a captured image obtained by observing primary particles of the pigment using a transmission electron microscope. Specifically, a projected area of the primary particles of the pigment is determined, and the corresponding equivalent circle diameter is calculated as the primary particle diameter of the pigment. In addition, the average primary particle diameter in the present invention is an arithmetic average of particle diameters with respect to 400 primary particles of the pigment. In addition, the primary particle of the pigment refers to a particle which is independent without aggregation.

The coloring material used in the present invention preferably includes the pigment. A content of the pigment in the coloring material is preferably 50% by mass or more, more preferably 70% by mass or more, still more preferably 80% by mass or more, and particularly preferably 90% by mass or more.

(Chromatic Coloring Material)

Examples of the chromatic coloring material include a coloring material having a maximal absorption wavelength in a wavelength range of 400 to 700 nm. Examples thereof include a yellow coloring material, an orange coloring material, a red coloring material, a green coloring material, a violet coloring material, and a blue coloring material. Specific examples of the chromatic coloring material include the following.

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106,108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), 234 (aminoketone-based), 235 (aminoketone-based), 236 (aminoketone-based), and the like (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, 73, and the like (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 291, 294 (xanthene-based, Organo Ultramarine, Bluish Red), 295 (monoazo-based), 296 (diazo-based), 297 (aminoketone-based), and the like (all of which are red pigments);

C. I. Pigment Green 7, 10, 36, 37, 58, 59, 62, 63, 64 (phthalocyanine-based), 65 (phthalocyanine-based), 66 (phthalocyanine-based), and the like (all of which are green pigments):

C. I. Pigment Violet 1, 19, 23, 27, 32, 37, 42, 60 (triarylmethanes-based), 61 (xanthene-based), and the like (all of which are violet pigments); and

C. I. Pigment Blue 1, 2, 15, 15:1, 15:2, 15:3, 15:4, 15:6, 16, 22, 29, 60, 64, 66, 79, 80, 87 (monoazo-based), 88 (methine-based), and the like (all of which are blue pigments).

In addition, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green coloring material. Specific examples thereof include the compounds described in WO2015/118720A. In addition, as the green coloring material, a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, a compound described in JP2019-038958A, and the like can also be used.

In addition, as the blue coloring material, an aluminum phthalocyanine compound having a phosphorus atom can also be used. Specific examples thereof include the compounds described in paragraphs 0022 to 0030 of JP2012-247591A and paragraph 0047 of JP2011-157478A.

In addition, as the yellow coloring material, compounds described in JP2017-201003A, compounds described in JP2017-197719A, compounds described in paragraph Nos. 0011 to 0062 and 0137 to 0276 of JP2017-171912A, compounds described in paragraph Nos. 0010 to (062 and 0138 to 0295 of JP2017-171913A, compounds described in paragraph Nos. 0011 to 0062 and 0139 to 0190 of JP2017-171914A, compounds described in paragraph Nos. 0010 to 0065 and 0142 to 0222 of JP2017-171915A, quinophthalone compounds described in paragraph Nos. 0011 to 0034 of JP2013-054339A, quinophthalone compounds described in paragraph Nos. 013 to 0058 of JP2014-026228A, isoindoline compounds described JP2018-062644A, quinophthalone compounds described in JP218-203798A, quinophthalone compounds described in JP2018-062578A, quinophthalone compounds described in JP64320778, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-20914A, quinophthalone compounds described in JP2013-209435A, quinophthalone compounds described in JP2013-181015A, quinophthalone compounds described in JP2013-061622A, quinophthalone compounds described in JP2013-054339A, quinophthalone compounds described in JP2013-032486A, quinophthalone compounds described in JP2012-2261 IA, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, a compound represented by Formula (QP1), a compound represented by Formula (QP2), compounds described in KR10-2014-0034963A, compounds described in JP2017-095706A, compounds described in TW2019-20495A, and compounds described in JP6607427B can also be used. In addition, from the viewpoint of improving a color value, a multimerized compound of these compounds is also preferably used. In addition, as the yellow coloring material, from the viewpoint of improving resistance, it is also preferable to use C. I. Pigment Yellow 129 or C. I. Pigment Yellow 215.

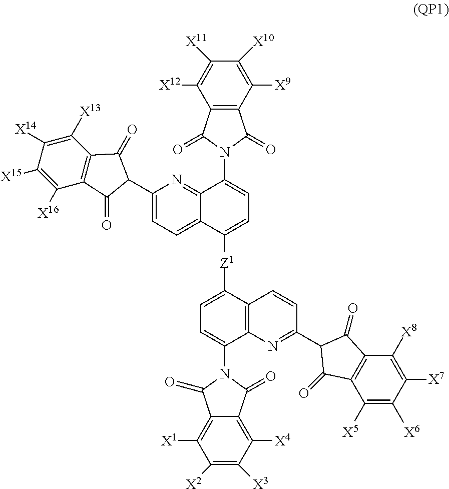

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph No. 0016 of JP6443711B.

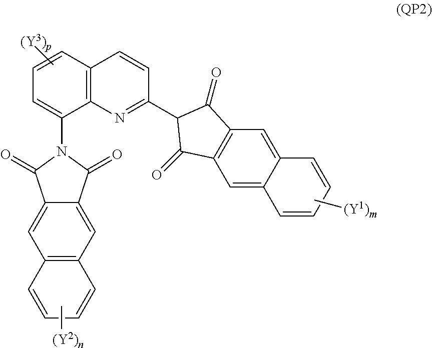

In Formula (QP2), Y¹ to Y³ each independently represent a halogen atom, n and m represent an integer of 0 to 6, and p represents an integer of 0 to 5. (n+m) is 1 or more. Specific examples of the compound represented by Formula (QP2) include compounds described in paragraph Nos. 0047 and 0048 of JP6432077B.

A diketopyrrolopyrrole pigment described in JP2017-201384A, in which the structure has at least one substituted bromine atom, a diketopyrrolopyrrole pigment described in paragraph Nos. 0016 to 0022 of JP6248838B, a red coloring material described in JP6516119B, a red coloring material described in JP6525101B, and the like can also be used as the red coloring material. In addition, as the red coloring material, a compound having a structure that an aromatic ring group in which a group bonded with an oxygen atom, a sulfur atom, or a nitrogen atom is introduced to an aromatic ring is bonded to a diketopyrrolopyrrole skeleton can also be used.

In addition, as the coloring material, a pigment (hereinafter, also referred to as a pigment DPP) having a structure in which an aromatic ring group Ar^{D1} having an electron donating group introduced into the aromatic ring is bonded to a diketopyrrolopyrrole skeleton can also be used. The pigment DPP is a diketopyrrolopyrrole pigment. In the present specification, the electron donating group is an atomic group which donates an electron to the substituted atomic group by an inductive effect or a resonance effect in organic electron theory. Examples of the electron donating group include groups having a negative value as a substituent constant (σp+) of Hammett equation. The substituent constant (σp+) of Hammett equation can be referred to from Graduate School Lecture Organic Chemistry 1. Molecular Structure and Reaction-Organometallic Chemistry, 1st Edition, page 175. The electron donating group is preferably a group having a substituent constant (σp+) of Hammett equation of −0.01 or less, more preferably a group having a substituent constant (σp+) of Hammett equation of −0.15 or less, and still more preferably a group having a substituent constant (σp+) of Hammett equation of −0.3 or less.

In the pigment DPP, examples of the electron donating group included in the above-described aromatic ring group Ar^{D1} include a hydroxy group, an alkyl group, an alkoxy group, an alkylthio group, an aryl group, an aryloxy group, and an amino group.

The alkyl group, alkoxy group, and alkylthio group preferably have 1 to 10 carbon atoms and more preferably have 1 to 5 carbon atoms. These groups may be linear, branched, or cyclic, and are preferably linear or branched.

The aryl group and aryloxy group preferably have 6 to 20 carbon atoms and more preferably have 6 to 10 carbon atoms.

Examples of the amino group include a group represented by —NRa¹Ra². Ra¹ and Ra² each independently represent a hydrogen atom, an alkyl group, an aryl group, or a heterocyclic group. Ra¹ and Ra² may be bonded to each other to form a ring. The alkyl group represented by Ra¹ and Ra² preferably has 1 to 30 carbon atoms, more preferably has 1 to 15 carbon atoms, and still more preferably has 1 to 8 carbon atoms. The alkyl group may be any of linear, branched, and cyclic forms, and is preferably linear or branched and more preferably linear. The aryl group represented by Ra¹ and Ra² preferably has 6 to 30 carbon atoms, more preferably has 6 to 20 carbon atoms, and still more preferably has 6 to 12 carbon atoms. The heterocyclic group represented by Ra¹ and Ra² may be a single ring or a fused ring. The heterocyclic group is preferably a single ring or a fused ring having 2 to 4 fused numbers. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

As the electron donating group, an alkyl group, an alkoxy group, an aryl group, or an amino group is preferable, and from the reason that it is easy to obtain a film with spectral characteristics suitable for red color, an alkyl group, an alkoxy group, or an aryl group is more preferable, an alkyl group or an aryl group is still more preferable, and an alkyl group is particularly preferable.

The pigment DPP is preferably a compound represented by Formula (DPP1), and more preferably a compound represented by Formula (DPP2).

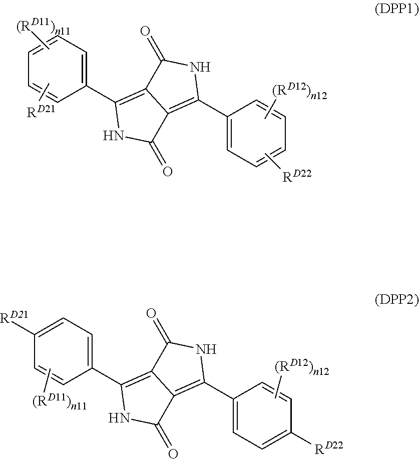

In the formulae, R^{D11} and R^{D12} each independently represent a substituent, R^{D21} and R^{D22} each independently represent an electron donating group, and n11 and n12 each independently represent an integer of 0 to 4.

Examples of the substituent represented by R^{D11} and R^{D12} include groups selected from the group of substituents T described later and the above-described electron donating group, and the electron donating group is preferable. In a case where n11 is 2 or more, n11 R^{D11}'s may be the same or different from each other. In addition, in a case where n12 is 2 or more, n12 R^{D12}'s may be the same or different from each other.

Examples of the electron donating group represented by R^{D21} and R^{D22} include the above-described groups, and the preferred range is also the same.

n11 and n12 each independently represent an integer of 0 to 4, and preferably an integer of 0 to 3, more preferably an integer of 0 to 2, still more preferably 0 or 1, and particularly preferably 0.

(Substituent T)

Examples of a substituent T include a halogen atom, a cyano group, a nitro group, an alkyl group, an alkenyl group, an aryl group, a heterocyclic group, —ORt¹, —CORt¹, —COORt¹, —OCORt¹, —NRt¹Rt², —NRt³CORt¹, —CONRt¹Rt², —NRt¹CONRt¹Rt², —NRt³COORt¹, —SRt¹, —SO₂Rt¹, —SO₂ORt¹, —NRt³SO₂Rt¹, and —SO₂NRt¹Rt². Rt¹ to Rt³ each independently represent a hydrogen atom, an alkyl group, an aryl group, or a heterocyclic group. Rt¹ and Rt² may be bonded to each other to form a ring.

Examples of the halogen atom include a fluorine atom, a chlorine atom, a bromine atom, and an iodine atom.

The alkyl group preferably has 1 to 30 carbon atoms, more preferably has 1 to 15 carbon atoms, and still more preferably 1 to 8 carbon atoms. The alkyl group may be any of linear, branched, and cyclic forms, but is preferably linear or branched and more preferably linear.

The alkenyl group preferably has 2 to 30 carbon atoms, more preferably has 2 to 15 carbon atoms, and particularly preferably has 2 to 8 carbon atoms. The alkenyl group may be any of linear, branched, and cyclic forms, but is preferably linear or branched and more preferably linear.

The aryl group preferably has 6 to 30 carbon atoms, more preferably has 6 to 20 carbon atoms, and still more preferably has 6 to 12 carbon atoms.

The heterocyclic group may be a single ring or a fused ring. The heterocyclic group is preferably a single ring or a fused ring having 2 to 4 fused numbers. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

The alkyl group, the aryl group, and the heterocyclic group may have a substituent or may be unsubstituted. Examples of the substituent include groups selected from the group of substituents T described above.

Specific examples of the pigment DPP include compounds having the following structures. A compound having a structure represented by Formula (R1) is Color Index (C. I.) Pigment Red 272, and a compound having a structure represented by Formula (R10) is C. I. Pigment Red 264. The pigment DPP preferably includes at least one selected from C. I. Pigment Red 264 or C. I. Pigment Red 272, and more preferably includes C. I. Pigment Red 272.

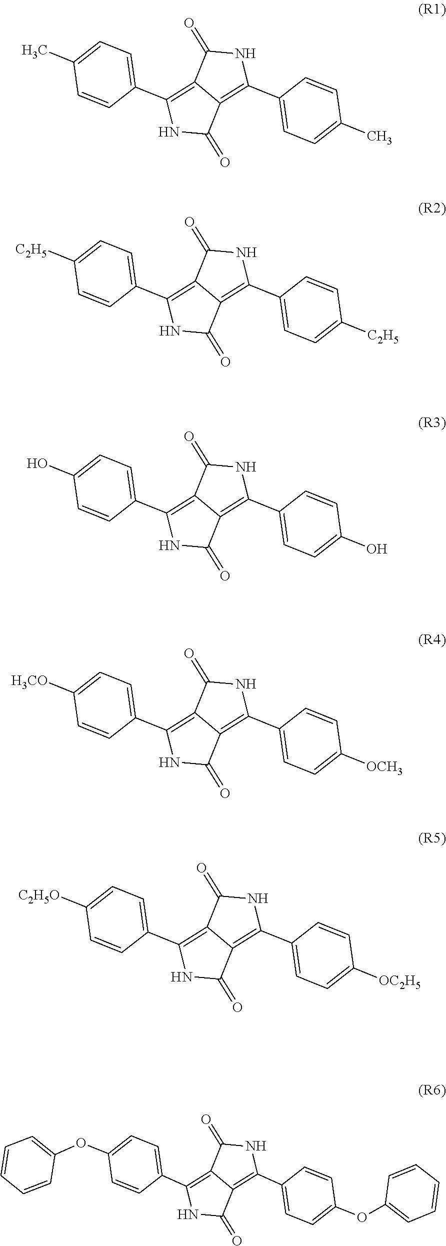

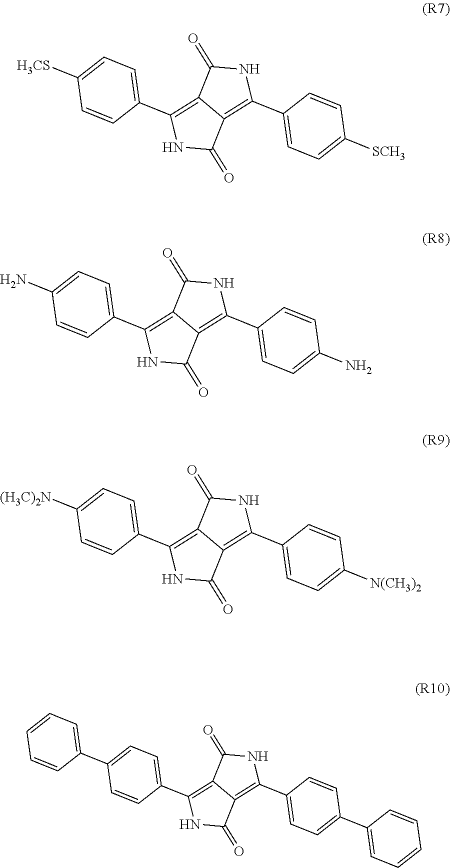

In addition, a dye can also be used as the chromatic coloring material. The dye is not particularly limited and a known dye can be used. Examples thereof include a pyrazoleazo compound, an anilinoazo compound, a triarylmethane compound, an anthraquinone compound, an anthrapyridone compound, a benzylidene compound, an oxonol compound, a pyrazolotriazoleazo compound, a pyridoneazo compound, a cyanine compound, a phenothiazine compound, a pyrrolopyrazoleazomethine compound, a xanthene compound, a phthalocyanine compound, a benzopyran compound, an indigo compound, and a pyrromethene compound. In addition, the thiazole compound described in JP2012-158649A, the azo compound described in JP2011-184493A, or the azo compound described in JP2011-145540A can also be used. In addition, as the dye, a coloring agent multimer can also be used. The coloring agent multimer has two or more coloring agent structures in one molecule, and preferably has three or more coloring agent structures in one molecule. The upper limit is particularly not limited, but may be 100 or less. A plurality of coloring agent structures included in one molecule may be the same coloring agent structure or different coloring agent structures. A weight-average molecular weight (Mw) of the coloring agent multimer is preferably 2000 to 50000. The lower limit is more preferably 3000 or more and still more preferably 6000 or more. The upper limit is more preferably 30000 or less and still more preferably 20000 or less. As the coloring agent multimer, the compounds described in JP2011-213925A, JP2013-041097A, JP2015-028144A, JP2015-030742A, JP2016-102191A, WO2016/031442A, or the like can also be used.

Two or more kinds of chromatic coloring materials may be combined to form red, green, blue, cyan, magenta, or yellow. For example, C. I. Pigment Green 7, C. I. Pigment Green 36, C. I. Pigment Yellow 139, and C. I. Pigment Yellow 185 may be combined to form green, or C. I. Pigment Green 58, C. I. Pigment Yellow 150, and C. I. Pigment Yellow 185 may be combined to form green.

In addition, in a case where the chromatic coloring material is used in a combination of two or more kinds thereof, the combination of two or more kinds of chromatic coloring materials may form black. Examples of such a combination include the following aspects (1) to (7). In a case where two or more chromatic coloring materials are included in the photosensitive composition and the combination of two or more chromatic coloring materials forms black, the photosensitive composition according to the embodiment of the present invention can be preferably used as a photosensitive composition for forming the near infrared transmitting filter.
(1) aspect in which a red coloring material and a blue coloring material are contained.
(2) aspect in which a red coloring material, a blue coloring material, and a yellow coloring material are contained.
(3) aspect in which a red coloring material, a blue coloring material, a yellow coloring material, and a violet coloring material are contained.
(4) aspect in which a red coloring material, a blue coloring material, a yellow coloring material, a violet coloring material, and a green coloring material are contained.
(5) aspect in which a red coloring material, a blue coloring material, a yellow coloring material, and a green coloring material are contained.
(6) aspect in which a red coloring material, a blue coloring material, and a green coloring material are contained.
(7) aspect in which a yellow coloring material and a violet coloring material are contained.

(Black Coloring Material)

Examples of the black coloring material include a bisbenzofuranone compound, an azomethine compound, a perylene compound, and an azo compound. Among these, a bisbenzofuranone compound or a perylene compound is preferable. Examples of the bisbenzofuranone compound include compounds described in JP2010-534726A, JP2012-515233A, JP2012-515234A, WO2014/208348A, JP2015-525260A, and the like, and the bisbenzofuranone compound is available, for example, as “Irgaphor Black” manufactured by BASF SE. Examples of the perylene compound include C. I. Pigment Black 31 and 32. Examples of the azomethine compound include the compounds described in JP1989-170601A (JP-H01-170601A) and JP1990-034664A (JP-102-0346(AA), and the azomethine compound is available, for example, “CHROMOFINE BLACK A1103” manufactured by Dainichiseika Color & Chemicals Mfg. Co., Ltd.

A content of the coloring material in the total solid content of the photosensitive composition is preferably 20% by mass or more, more preferably 30% by mass or more, still more preferably 40% by mass or more, and even more preferably 45% by mass or more, and particularly preferably 50% by mass or more. In addition, the upper limit of the content of the coloring material in the total solid content of the photosensitive composition is preferably 80% by mass or less, more preferably 70% by mass or less, and still more preferably 60% by mass or less.

In addition, a content of the pigment in the total solid content of the photosensitive composition is preferably 20% by mass or more, more preferably 30% by mass or more, still more preferably 40% by mass or more, and even more preferably 45% by mass or more, and particularly preferably 50% by mass or more. In addition, the upper limit of the content of the pigment in the total solid content of the photosensitive composition is preferably 80% by mass or less, more preferably 70% by mass or less, and still more preferably 60% by mass or less.

<<Photopolymerization Initiator>>

The photosensitive composition according to the embodiment of the present invention includes a photopolymerization initiator. As the photopolymerization initiator, a photopolymerization initiator which includes an oxime compound OX having an aromatic ring group Ar^{OX1} in which an electron withdrawing group is introduced into an aromatic ring (hereinafter, also referred to as an oxime compound OX) is used. In the oxime compound OX, the aromatic ring group Ar^{OX1} is preferably bonded to a site including an oxime structure of the oxime compound OX through an aromatic ring to which the electron withdrawing group is bonded. That is, the electron withdrawing group of the aromatic ring group Ar^{OX1} is preferably bonded to the site including the oxime structure of the oxime compound OX through an aromatic ring electron-withdrawn by the electron withdrawing group. Specifically, it is preferable that the aromatic ring side of the aromatic ring group Ar^{OX1} is a bonding side with the site including the oxime structure of the oxime compound OX. In the present specification, the electron withdrawing group is an atomic group which withdraws an electron from the substituted atomic group by an inductive effect or a resonance effect in organic electron theory. Examples of the electron withdrawing group include groups having a positive value as a substituent constant (σp−) of Hammett equation. The substituent constant (σp−) of Hammett equation can be referred to from Graduate School Lecture Organic Chemistry I. Molecular Structure and Reaction-Organometallic Chemistry, 1st Edition, page 175. The electron withdrawing group is preferably a group having a substituent constant (σp−) of Hammett equation of 0.01 or more, more preferably a group having a substituent constant (σp−) of Hammett equation of 0.1 or more, and still more preferably a group having a substituent constant (σp−) of Hammett equation of 0.3 or more.

In the oxime compound OX, examples of the electron withdrawing group included in the above-described aromatic ring group Ar^{OX1} include an acyl group, a nitro group, a trifluoromethyl group, an alkylsulfinyl group, an arylsulfinyl group, an alkylsulfonyl group, an arylsulfonyl group, and a cyano group. Among these, an acyl group or a nitro group is preferable, and from the reason that it is easy to form a film with more excellent light resistance, an acyl group is more preferable, and a benzoyl group is still more preferable. The benzoyl group may have a substituent. Examples of the substituent include groups selected from the group of substituents T described above, and a halogen atom, a cyano group, a nitro group, a hydroxy group, an alkyl group, an alkoxy group, an aryl group, an aryloxy group, a heterocyclic group, a heterocyclic oxy group, an alkenyl group, an alkylsulfanyl group, an arylsulfanyl group, an acyl group, or an amino group is preferable, an alkyl group, an alkoxy group, an aryl group, an aryloxy group, a heterocyclic oxy group, an alkylsulfanyl group, an arylsulfanyl group, or an amino group is more preferable, and an alkoxy group, an alkylsulfanyl group, or an amino group is still more preferable. Examples of the halogen atom include a fluorine atom, a chlorine atom, a bromine atom, and an iodine atom. Examples of the alkyl group, alkoxy group, aryl group, aryloxy group, heterocyclic group, heterocyclic oxy group, alkenyl group, alkylsulfanyl group, arylsulfanyl group, acyl group, and amino group include groups described as groups represented by R^{OX11} described later.

The above-described aromatic ring group Ar^{OX1} is preferably a group represented by Formula (OR-1). According to this aspect, the above-described effects of the present invention are more prominently exhibited.

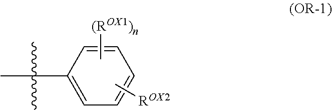

In the formula, R^{OX1} represents a substituent, R^{OX2} represents an electron withdrawing group, n represents an integer of 0 to 4, and a wavy line represents a bonding site.

In Formula (OR-1), examples of the substituent represented by R^{OX1} include groups selected from the group of substituents T described above and the above-described electron withdrawing group, and the electron withdrawing group is preferable. In a case where n is 2 or more, n R^{OX1}'s may be the same or different from each other.

In Formula (OR-1), examples of the electron withdrawing group represented by R^{OX2} include the above-described groups, and the preferred range is also the same.

In Formula (OR-1), n represents an integer of 0 to 4, is preferably an integer of 0 to 3, more preferably an integer of 0 to 2, still more preferably 0 or 1, and particularly preferably 0.

In Formula (OR-1), a wavy line represents a bonding site. At the position of the wavy line in Formula (OR-1), the above-described aromatic ring group Ar^{OX1} is bonded to other atomic groups constituting the oxime compound OX to form the oxime compound OX.

The oxime compound OX preferably has at least one group selected from a group represented by Formula (OR-11) or a group represented by Formula (OR-12), and more preferably has a group represented by Formula (OR-12).

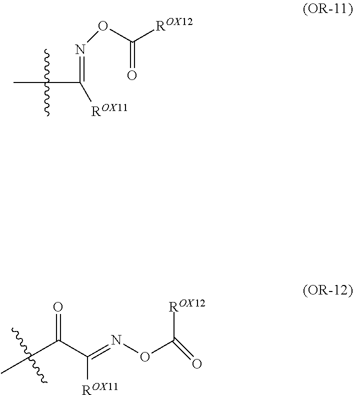

In the formula, R^{OX11} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyl group, an acyloxy group, an amino group, a phosphinoyl group, a carbamoyl group, or a sulfamoyl group.

R^{OX12} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyloxy group, or an amino group, and

a wavy line represents a bonding site.

R^{OX11} is preferably an alkyl group, an alkoxy group, an aryl group, an aryloxy group, or a heterocyclic group, more preferably an alkyl group, an aryl group, or a heterocyclic group, and still more preferably an alkyl group. In addition, R^{OX12} is preferably an alkyl group, an alkenyl group, an alkoxy group, an aryl group, an aryloxy group, a heterocyclic group, a heterocyclic oxy group, or an acyloxy group, more preferably an alkyl group, an alkenyl group, an aryl group, or a heterocyclic group, and still more preferably an alkyl group.

The above-described group represented by R^{OX11} and R^{OX12} may further have a substituent. Examples of the further substituent include groups selected from the group of substituents T described above.

The alkyl group represented by R^{OX11} and R^{OX12} preferably has 1 to 18 carbon atoms, more preferably has 1 to 15 carbon atoms, and still more preferably has 1 to 8 carbon atoms. The alkyl group may be linear, branched, or cyclic. In a case where the number of carbon atoms in the alkyl group is 2 or more, an ether bond may be included between carbon atoms. Specific examples of the alkyl group represented by R^{OX11} and R^{OX12} include a methyl group, an ethyl group, a propyl group, a butyl group, a pentyl group, a hexyl group, a heptyl group, an octyl group, a nonyl group, a decyl group, a dodecyl group, an octadecyl group, an isopropyl group, an isobutyl group, an isopentyl group, a sec-butyl group, a tert-butyl group, a sec-pentyl group, a tert-pentyl group, a tert-octyl group, a neopentyl group, a cyclopropyl group, a cyclobutyl group, a cyclopentyl group, a cyclohexyl group, an adamantyl group, a norbornyl group, a boronyl group, and a 4-decylcyclohexyl group. In addition, specific examples of the alkyl group including an ether bond between carbon atoms include —CH₂—O—CH₃, —CH₂—CH—O—CH₂—CH₃, —CH—CH₂—CH₂—O—CH₂—CH₃, —(CH₂—CH₂—O)ₙ—CH₃ (here, n is 1 to 8), —(CH₂—CH₂—CH₂—O)ₘ—CH₃ (here, m is 1 to 5), —CH₂—CH(CH₃)—O—CH₂—CH₃—, —CH₂—CH—(OCH₃)₂, and groups shown below.

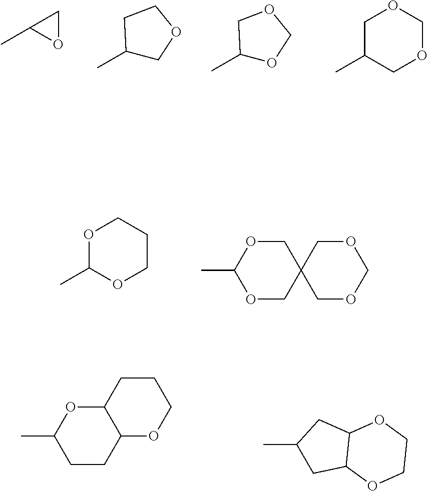

The alkenyl group represented by R^{OX11} and R^{OX12} preferably has 2 to 18 carbon atoms, more preferably has 2 to 15 carbon atoms, and still more preferably has 2 to 8 carbon atoms. The alkenyl group may be linear, branched, or cyclic. Specific examples of the alkenyl group include a vinyl group, a 1-propenyl group, an allyl group, a 2-butenyl group, a 3-butenyl group, an isopropenyl group, an isobutenyl group, a 1-pentenyl group, a 2-pentenyl group, a 3-pentenyl group, a 4-pentenyl group, a 1-hexenyl group, a 2-hexenyl group, a 3-hexenyl group, a 4-hexenyl group, a 5-hexenyl group, a cyclopentenyl group, a cyclohexenyl group, a 1,3-butadienyl group, a cyclohexadienyl group, and a cyclopentadienyl group.

The alkoxy group represented by R^{OX11} and R^{OX12} preferably has 1 to 18 carbon atoms, more preferably has 1 to 15 carbon atoms, and still more preferably has 1 to 8 carbon atoms. The alkoxy group may be linear, branched, or cyclic. In a case where the number of carbon atoms in the alkoxy group is 2 or more, an ether bond may be included between carbon atoms. Specific examples of the alkoxy group represented by R^{OX11} and R^{OX12} include a methyloxy group, an ethyloxy group, a propyloxy group, a butyloxy group, a pentyloxy group, a hexyloxy group, a heptyloxy group, an octyloxy group, a nonyloxy group, a decyloxy group, a dodecyloxy group, an octadecyloxy group, an isopropyloxy group, an isobutyloxy group, an isopentyloxy group, a sec-butyloxy group, a tert-butyloxy group, a sec-pentyloxy group, a tert-pentyloxy group, a tert-octyloxy group, a neopentyloxy group, a cyclopropyloxy group, a cyclobutyloxy group, a cyclopentyloxy group, a cyclohexyloxy group, an adamantyloxy group, a norbomyloxy group, a boronyloxy group, and a 4-decylcyclohexyloxy group. In addition, specific examples of the alkoxy group including an ether bond between carbon atoms include —O—CH₂—O—CH₃, —O—CH₂CH₂—O—CH₂—CH₃, —O—CH₂—CH₂—CH₂—O—CH₂—CH₃, —O—(CH₂—CH₂—O)ₙ—CH₃ (here, n is 1 to 8), —O—(CH₂—CH₂—CH₂—O)ₘ—CH₃ (here, m is 1 to 5), —O—CH₂—CH(CH₃)—O—CH₂—CH₃—, —O—CH₂—CH—(OCH₃)₂, and groups shown below.

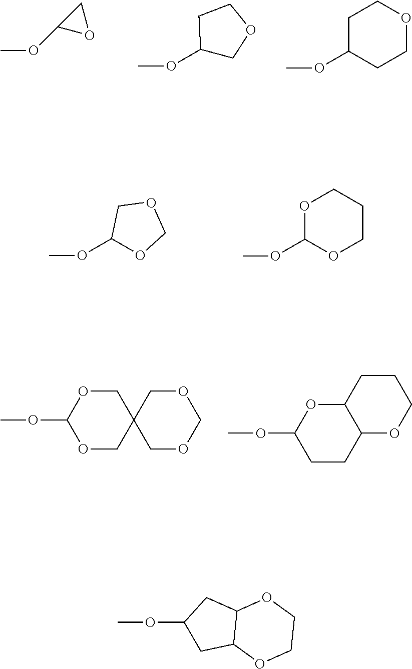

The aryl group represented by R^{OX11} and R^{OX12} preferably has 6 to 24 carbon atoms and more preferably has 6 to 12 carbon atoms. Specific examples of the aryl group include a phenyl group, a 1-naphthyl group, a 2-naphthyl group, a 1-anthryl group, a 9-anthryl group, a 2-phenanthryl group, a 3-phenanthryl group, a 9-phenanthryl group, a 1-pyrenyl group, a 5-naphthacenyl group, a 1-indenyl group, a 2-azulenyl group, a 1-acenaphthyl group, a 2-fluorenyl group, a 9-fluorenyl group, a 3-perylenyl group, an o-tolyl group, an m-tolyl group, a p-tolyl group, a 2,3-xylyl group, a 2,5-xylyl group, a mesityl group, a p-cumenyl group, a p-dodecylphenyl group, a p-cyclohexylphenyl group, a 4-biphenyl group, an o-fluorophenyl group, an m-chlorophenyl group, a p-bromophenyl group, a p-hydroxyphenyl group, an m-carboxyphenyl group, an o-mercaptophenyl group, a p-cyanophenyl group, an m-nitrophenyl group, an m-azidophenyl group.

The aryloxy group represented by R^{OX11} and R^{OX12} preferably has 6 to 24 carbon atoms and more preferably has 6 to 12 carbon atoms. Specific examples of the aryloxy group include a phenoxy group, a 1-naphthyloxy group, a 2-naphthyloxy group, a 9-anthryloxy group, a 9-phenanthryloxy group, a 1-pyrenyloxy group, a 5-naphthacenyloxy group, a 1-indenyloxy group, a 2-azulenyloxy group, a 1-acenaphthyloxy group, and a 9-fluorenyloxy group.

A hetero ring of the heterocyclic group or heterocyclic oxy group represented by R^{OX11} and R^{OX12} may be a single ring or a fused ring. The hetero ring is preferably a single ring or a fused ring having 2 to 4 fused numbers. The number of heteroatoms constituting the ring of the hetero ring is preferably 1 to 3. The heteroatom constituting the ring of the hetero ring is preferably a nitrogen atom, an oxygen atom, or a sulfur atom. The number of carbon atoms constituting the ring of the hetero ring is preferably 3 to 30, more preferably 3 to 18, and more preferably 3 to 12.

Examples of the heterocyclic group include a 2-thienyl group, a 2-benzothienyl group, a naphtho[2,3-b]thienyl group, a 3-thianthrenyl group, a 2-thianthrenyl group, a 2-furyl group, a 2-benzofuryl group, a pyranyl group, an isobenzofuranyl group, a chromenyl group, a xanthenyl group, a phenoxathiinyl group, a 2H-pyrrolyl group, a pyrrolyl group, an imidazolyl group, a pyrazolyl group, a pyridyl group, a pyrazinyl group, a pyrimidinyl group, a pyridadinyl group, an indolizinyl group, an isoindolyl group, a 3H-indolyl group, a 2-indolyl group, a 3-indolyl group, a 1H-indazolyl group, a purinyl group, a 4H-quinolizinyl group, an isoquinolyl group, a quinolyl group, a phthalazinyl group, a naphthalazinyl group, a quinoxalinyl group, a quinazolinyl group, a cinnolinyl group, a pteridinyl group, a 4aH-carbazolyl group, a 2-carbarolyl group, a 3-carbazolyl group, a β-carbolinyl group, a phenanthridinyl group, a 2-acrydinyl group, a perimidinyl group, a phenanthrolinyl group, a phenazinyl group, a phenalsadinyl group, an isothiazolyl group, a phenothiazinyl group, an isoxazolyl group, a furazanyl group, a 3-phenixazinyl group, an isochromanyl group, a chromanyl group, a pyrrolidinyl group, a pyrrolinyl group, an imidazolidinyl group, an imidazolinyl group, a pyrazolydinyl group, a pyrazolinyl group, a piperidyl group, a piperazinyl group, an indolinyl group, an isoindrinyl group, a quinuclidinyl group, a morpholinyl group, a thioxanthryl group, a 4-quinolinyl group, a 4-quinolinyl group, an isoquinolyl group, a 3-phenothiazinyl group, a 2-phenoxatyynyl group, and a 3-cummarinyl group. Specific examples of the heterocyclic oxy group include a 2-furanyloxy group, a 2-thienyloxy group, a 2-indolyloxy group, a 3-indolyloxy group, a 2-benzofuryloxy group, a 2-benzothienyloxy group, a 2-carbazolyloxy group, a 3-carbazolyloxy group, a 4-carbazolyloxy group, and 9-acrydinyloxy group.

The alkylsulfanyl group represented by R^{OX11} and R^{OX12} preferably has 1 to 18 carbon atoms, more preferably has 1 to 15 carbon atoms, and still more preferably has 1 to 8 carbon atoms. The alkylsulfanyl group may be linear or branched. Specific examples of the alkylsulfanyl group include a methylthio group, an ethylthio group, a propylthio group, a butylthio group, a pentylthio group, a hexylthio group, an octylthio group, a decylthio group, a dodecylthio group, and an octadecylthio group.

The arylsulfanyl group represented by R^{OX11} and R^{OX12} preferably has 6 to 18 carbon atoms. Specific examples of the arylsulfanyl group include a phenylthio group, a 1-naphthylthio group, a 2-naphthylthio group, a 9-anthrylthio group, and a 9-phenanthrylthio group.

The alkylsulfinyl group represented by R^{OX11} and R^{OX12} preferably has 1 to 20 carbon atoms, more preferably has 1 to 15 carbon atoms, and still more preferably has 1 to 8 carbon atoms. The alkylsulfinyl group may be linear or branched. Specific examples of the alkylsulfinyl group include a methylsulfinyl group, an ethylsulfinyl group, a propylsulfinyl group, an isopropylsulfinyl group, a butylsulfinyl group, a hexylsulfinyl group, a cyclohexylsulfinyl group, an octylsulfinyl group, a 2-ethylhexylsulfinyl group, a decanoylsulfinyl group, a dodecanoylsulfinyl group, an octadecanoylsulfinyl group, a cyanomethylsulfinyl group, and a methyloxymethylsulfinyl group.

The arylsulfinyl group represented by R^{OX11} and R^{OX12} preferably has 6 to 30 carbon atoms. Specific examples of the arylsulfinyl group include a phenylsulfinyl group, a 1-naphthylsulfinyl group, a 2-naphthylsulfinyl group, a 2-chlorophenylsulfinyl group, a 2-methylphenylsulfinyl group, a 2-methyloxyphenylsulfinyl group, a 2-butyloxyphenylsulfinyl group, a 3-chlorophenylsulfinyl group, a 3-trifluoromethylphenylsulfinyl group, a 3-cyanophenylsulfinyl group, a 3-nitrophenylsulfinyl group, a 4-fluorophenylsulflinyl group, a 4-cyanophenylsulfinyl group, a 4-methyloxyphenylsulfinyl group, a 4-methylsulfanylphenylsulfinyl group, a 4-phenylsulfanylphenylsulfinyl group, and a 4-dimethylaminophenylsulfinyl group.

The alkylsulfonyl group represented by R^{OX11} and R^{OX12} preferably has 1 to 20 carbon atoms, more preferably has 1 to 15 carbon atoms, and still more preferably has 1 to 8 carbon atoms. The alkylsulfonyl group may be linear or branched. Specific examples of the alkylsulfonyl group include a methylsulfonyl group, an ethylsulfonyl group, a propylsulfonyl group, an isopropylsulfonyl group, a butylsulfonyl group, a hexylsulfonyl group, a cyclohexylsulfonyl group, an octylsulfonyl group, a 2-ethylhexylsulfonyl group, a decanoylsulfonyl group, a dodecanoylsulfonyl group, an octadecanoylsulfonyl group, a cyanomethylsulfonyl group, and a methyloxymethylsulfonyl group.

The arylsulfonyl group represented by R^{OX11} and R^{OX12} preferably has 6 to 30 carbon atoms. Specific examples of the arylsulfonyl group include a phenylsulfonyl group, a 1-naphthylsulfonyl group, a 2-naphthylsulfonyl group, a 2-chlorophenylsulfonyl group, a 2-methylphenylsulfonyl group, a 2-methyloxyphenylsulfonyl group, a 2-butyloxyphenylsulfonyl group, a 3-chlorophenylsulfonyl group, a 3-trifluoromethylphenylsulfonyl group, a 3-cyanophenylsulfonyl group, a 3-nitrophenylsulfonyl group, a 4-fluorophenylsulfonyl group, a 4-cyanophenylsulfonyl group, a 4-methyloxyphenylsulfonyl group, a 4-methylsulfanylphenylsulfonyl group, a 4-phenylsulfanylphenylsulfonyl group, and a 4-dimethylaminophenylsulfonyl group.

Examples of the acyl group represented by R^{OX11} include a group in which a hydrogen atom, an alkyl group having 1 to 18 carbon atoms, an alkenyl group having 2 to 18 carbon atoms, an alkoxy group having 1 to 18 carbon atoms, an aryl group having 6 to 18 carbon atoms, an aryloxy group having 6 to 18 carbon atoms, or a heterocyclic group is bonded to a carbonyl group. Specific examples of the acyl group include a formyl group, an acetyl group, a propionyl group, a butyryl group, an isobutyryl group, a valeryl group, an isovaleryl group, a pivaloyl group, a lauroyl group, a myristoyl group, a palmitoyl group, a stearoyl group, a cyclopentylcarbonyl group, a cyclohexylcarbonyl group, an acryloyl group, a methacryloyl group, a crotonoyl group, an isocrotonoyl group, an oleoyl group, a cinnamoyl group, a benzoyl group, a methyloxycarbonyl group, an ethyloxycarbonyl group, a propyloxycarbonyl group, a butyloxycarbonyl group, a hexyloxycarbonyl group, an octyloxycarbonyl group, a decyloxycarbonyl group, an octadecyloxycarbonyl group, a trifluoromethyloxycarbonyl group, a benzoyl group, a toluoyl group, a 1-naphthoyl group, a 2-naphthoyl group, a 9-anthrylcarbonyl group, a phenyloxycarbonyl group, a 4-methylphenyloxycarbonyl group, a 3-nitrophenyloxycarbonyl group, a 4-dimethylaminophenyloxycarbonyl group, a 2-methylsulfanylphenyloxycarbonyl group, a 1-naphthoyloxycarbonyl group, a 2-naphthoyloxycarbonyl group, a 9-anthranyloxycarbonyl group, a 3-furoyl group, a 2-thenoyl group, a nicothinoyl group, and an isonicothinoyl group.

The acyloxy group represented by R^{OX11} and R^{OX12} preferably has 2 to 20 carbon atoms. Specific examples of the acyloxy group include an acetyloxy group, a propanoyloxy group, a butanoyloxy group, a pentanoyloxy group, a trifluoromethylcarbonyloxy group, a benzoyloxy group, a 1-naphthylcarbonyloxy group, and a 2-naphthylcarbonyloxy group.

Examples of the amino group represented by R^{OX11} and R^{OX12} include —NH₂, an alkylamino group, a dialkylamino group, an arylamino group, a diarylamino group, an alkylarylamino group, a benzylamino group, and a dibenzylamino group. Examples of the alkylamino group include a methylamino group, an ethylamino group, a propylamino group, a butylamino group, a pentylamino group, a hexylamino group, a heptylamino group, an octylamino group, a nonylamino group, a decylamino group, a dodecylamino group, an octadecylamino group, an isopropylamino group, an isobutylamino group, an isopentylamino group, a sec-butylamino group, a tert-butylamino group, a sec-pentylamino group, a tert-pentylamino group, a tert-octylamino group, a neopentylamino group, a cyclopropylamino group, a cyclobutylamino group, a cyclopentylamino group, a cyclohexylamino group, a cycloheptylamino group, a cyclooctylamino group, a cyclododecylamino group, a 1-adamantamino group, and a 2-adamantamino group. Examples of the dialkylamino group include a dimethylamino group, a diethylamino group, a dipropylamino group, a dibutylamino group, a dipentylamino group, a dihexylamino group, a diheptylamino group, a dioctylamino group, a dinonylamino group, a didecylamino group, a didodecylamino group, a dioctadecylamino group, a diisopropylamino group, a diisobutylamino group, a diisopentylamino group, a methylethylamino group, a methylpropylamino group, a methylbutylamino group, a methylisobutylamino group, a cyclopropylamino group, a pyrrolidino group, a piperidino group, and a piperazino group. Examples of the arylamino group include an anilino group, a 1-naphthylamino group, a 2-naphthylamino group, an o-toluidino group, a m-toluidino group, a p-toluidino group, a 2-biphenylamino group, a 3-biphenylamino group, a 4-biphenylamino group, a 1-fluoreneamino group, a 2-fluoreneamino group, a 2-thiazoleamino group, and a p-terphenylamino group. Examples of the diarylamino group include a diphenylamino group, a ditrilamino group, an N-phenyl-1-naphthylamino group, an N-phenyl-2-naphthylamino group. Examples of the alkylarylamino group include an N-methylanilino group, an N-methyl-2-pyridino group, an N-ethylanilino group, an N-propylanilino group, an N-butylanilino group, an N-isopropyl group, an N-pentylanilino group, an N-ethylanilino group, and an N-methyl-1-naphthylamino group.

The phosphinoyl group represented by R^{OX11} preferably has 2 to 50 carbon atoms. Specific examples of the phosphinoyl group include a dimethylphosphinoyl group, a diethylphosphinoyl group, a dipropylphosphinoyl group, a diphenylphosphinoyl group, a dimethoxyphosphinoyl group, a diethoxyphosphinoyl group, a dibenzoylphosphinoyl group, and a bis(2,4,6-trimethylphenyl)phosphinoyl group.

The carbamoyl group represented by R^{OX11} preferably has 2 to 30 carbon atoms. Specific examples of the carbamoyl group include an N-methylcarbamoyl group, an N-ethylcarbamoyl group, an N-propylcarbamoyl group, an N-butylcarbamoyl group, an N-hexylcarbamoyl group, an N-cyclohexylcarbamoyl group, an N-octylcarbamoyl group, an N-decylcarbamoyl group, an N-octadecylcarbamoyl group, an N-phenylcarbamoyl group, an N-2-methylphenylcarbamoyl group, an N-2-chlorophenylcarbamoyl group, an N-2-isopropoxyphenylcarbamoyl group, an N-2-(2-ethylhexyl)phenylcarbamoyl group, an N-3-chlorophenylcarbamoyl group, an N-3-nitrophenylcarbamoyl group, an N-3-cyanophenylcarbamoyl group, an N-4-methoxyphenylcarbamoyl group, an N-4-cyanophenylcarbamoyl group, an N-4-methylsulfanylphenylcarbamoyl group, an N-4-phenylsulfanylphenylcarbamoyl group, an N-methyl-N-phenylcarbamoyl group, an N,N-dimethylcarbamoyl group, an N,N-dibutylcarbamoyl group, and an N,N-diphenylcarbamoyl group.

The sulfamoyl group represented by R^{OX11} preferably has 0 to 30 carbon atoms. Specific examples of the sulfamoyl group include a sulfamoyl group, an N-alkylsulfamoyl group, an N-arylsulfamoyl group, an N,N-dialkylsulfamoyl group, an N,N-diarylsulfamoyl group, and an N-alkyl-N-arylsulfamoyl group. More specific examples thereof include an N-methylsulfamoyl group, an N-ethylsulfamoyl group, an N-propylsulfamoyl group, an N-butylsulfamoyl group, an N-hexylsulfamoyl group, an N-cyclohexylsulfamoyl group, an N-octylsulfamoyl group, an N-2-ethylhexylsulfamoyl group, an N-decylsulfamoyl group, an N-octadecylsulfamoyl group, an N-phenylsulfamoyl group, an N-2-methylphenylsulfamoyl group, an N-2-chlorophenylsulfamoyl group, an N-2-methoxyphenylsulfamoyl group, an N-2-isopropoxyphenylsulfamoyl group, an N-3-chlorophenylsulfamoyl group, an N-3-nitrophenylsulfamoyl group, an N-3-cyanophenylsulfamoyl group, an N-4-methoxyphenylsulfamoyl group, an N-4-cyanophenylsulfamoyl group, an N-4-dimethylaminophenylsulfamoyl group, an N-4-methylsulfanylphenylsulfamoyl group, an N-4-phenylsulfanylphenylsulfamoyl group, an N-methyl-N-phenylsulfamoyl group, an N,N-dimethylsulfamoyl group, an N,N-dibutylsulfamoyl group, and an N,N-diphenylsulfamoyl group.

In Formula (OR-11) and Formula (OR-12), a wavy line represents a bonding site. At the position of the wavy line in Formula (OR-11) or the position of the wavy line in Formula (OR-12), Formula (OR-11) or Formula (OR-12) is bonded to other atomic groups constituting the oxime compound OX to form the oxime compound OX.

The oxime compound OX is preferably at least one selected from a compound represented by Formula (OX1) or a compound represented by Formula (OX2), and from the reason that the adhesiveness of the obtained pixel can be further improved, more preferably a compound represented by Formula (OX2).

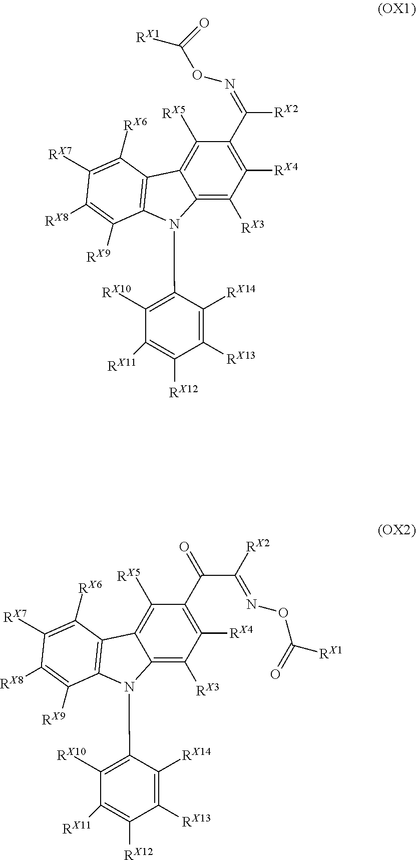

In the formula, R^{X1} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyl group, an acyloxy group, an amino group, a phosphinoyl group, a carbamoyl group, or a sulfamoyl group.

R^{X2} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyloxy group, or an amino group,

R^{X3} to R^{X14} each independently represent a hydrogen atom or a substituent, and

at least one of RX¹⁰, . . . , or R^{X14} is an electron withdrawing group.

In the formulae, R^{X1} is preferably an alkyl group, an alkoxy group, an aryl group, an aryloxy group, or a heterocyclic group, more preferably an alkyl group, an aryl group, or a heterocyclic group, and still more preferably an alkyl group. In addition, R^{X2} is preferably an alkyl group, an alkenyl group, an alkoxy group, an aryl group, an aryloxy group, a heterocyclic group, a heterocyclic oxy group, or an acyloxy group, more preferably an alkyl group, an alkenyl group, an aryl group, or a heterocyclic group, and still more preferably an alkyl group.

R^{X1} in the formulae is the same as R^{OX11} in Formula (OR-11) and Formula (OR-12) described above, and the preferred range is also the same.

R^{X2} in the formulae is the same as R^{OX12} in Formula (OR-11) and Formula (OR-12) described above, and the preferred range is also the same.

R^{X3} to R^{X14} each independently represent a hydrogen atom or a substituent.

Examples of the substituent represented by R^{X3} to R^{X9} include groups selected from the group of substituents T described above, the group represented by Formula (OR-11) described above, and the group represented by Formula (OR-12) described above.

R^{X3} to R^{X5} are each independently preferably a hydrogen atom, a halogen atom, a cyano group, a nitro group, an alkyl group, an alkenyl group, an alkoxy group, an aryl group, an aryloxy group, a heterocyclic group, a heterocyclic oxy group, an alkylsulfanyl group, an arylsulfanyl group, an acyl group, or an amino group, more preferably a hydrogen atom, a halogen atom, a nitro group, an alkyl group, an aryl group, or a heterocyclic group, still more preferably a hydrogen atom, a nitro group, an alkyl group, or an aryl group, and particularly preferably a hydrogen atom. Examples of the halogen atom include a fluorine atom, a chlorine atom, a bromine atom, and an iodine atom. Examples of the alkyl group, alkenyl group, alkoxy group, aryl group, aryloxy group, heterocyclic group, heterocyclic oxy group, alkylsulfanyl group, arylsulfanyl group, acyl group, and amino group include groups described as groups represented by R^{OX11} described above. The alkyl group, alkenyl group, alkoxy group, aryl group, aryloxy group, heterocyclic group, heterocyclic oxy group, alkylsulfanyl group, arylsulfanyl group, acyl group, and amino group may further have a substituent. Examples of the further substituent include groups selected from the group of substituents T described above.

R^{X6} to R^{X10} are each independently preferably a hydrogen atom, a halogen atom, a cyano group, an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an amino group, the group represented by Formula (OR-11) described above, or the group represented by Formula (OR-12) described above, more preferably a hydrogen atom, a halogen atom, a cyano group, an alkyl group, an aryl group, a heterocyclic group, or an amino group, still more preferably a hydrogen atom, a cyano group, an alkyl group, or an aryl group, even more preferably a hydrogen atom, an alkyl group, or an aryl group, even still more preferably a hydrogen atom or an alkyl group, and particularly preferably a hydrogen atom. Examples of the halogen atom include a fluorine atom, a chlorine atom, a bromine atom, and an iodine atom. Examples of the alkyl group, alkenyl group, alkoxy group, aryl group, aryloxy group, heterocyclic group, heterocyclic oxy group, alkylsulfanyl group, arylsulfanyl group, alkylsulfinyl group, arylsulfinyl group, alkylsulfonyl group, arylsulfonyl group, and amino group include groups described as groups represented by R^{OX11} described above. The alkyl group, alkenyl group, alkoxy group, aryl group, aryloxy group, heterocyclic group, heterocyclic oxy group, alkylsulfanyl group, arylsulfanyl group, alkylsulfinyl group, arylsulfinyl group, alkylsulfonyl group, arylsulfonyl group, and amino group may further have a substituent. Examples of the further substituent include groups selected from the group of substituents T described above.

Examples of the substituent represented by R^{X10} to R^{X14} include groups selected from the group of substituents T described above and the above-described electron withdrawing group. However, at least one of R^{X10}, . . . , or R^{X14} is an electron withdrawing group.

The substituent represented by R^{X10} to R^{X14} is preferably a nitro group, a halogen atom, a cyano group, an alkyl group, an alkoxy group, an aryl group, an aryloxy group, a heterocyclic group, a heterocyclic oxy group, an alkenyl group, an alkylsulfanyl group, an arylsulfanyl group, an acyl group, or an amino group. Examples of the alkyl group, alkoxy group, aryl group, aryloxy group, heterocyclic group, heterocyclic oxy group, alkenyl group, alkylsulfanyl group, arylsulfanyl group, acyl group, and amino group include groups described as groups represented by R^{OX11} described above. The alkyl group, alkoxy group, aryl group, aryloxy group, heterocyclic group, heterocyclic oxy group, alkenyl group, alkylsulfanyl group, arylsulfanyl group, acyl group, and amino group may further have a substituent. Examples of the further substituent include groups selected from the group of substituents T described above.

In addition, examples of the electron withdrawing group represented by R^{X10} to R^{X14} include an acyl group, a nitro group, a trifluoromethyl group, an alkylsulfinyl group, an arylsulfinyl group, an alkylsulfonyl group, an arylsulfonyl group, and a cyano group. Among these, an acyl group or a nitro group is preferable, and from the reason that it is easy to form a film with more excellent light resistance, an acyl group is more preferable, and a benzoyl group is still more preferable. The benzoyl group may have a substituent. Examples of the substituent include groups selected from the group of substituents T described above, and a halogen atom, a cyano group, a nitro group, a hydroxy group, an alkyl group, an alkoxy group, an aryl group, an aryloxy group, a heterocyclic group, a heterocyclic oxy group, an alkenyl group, an alkylsulfanyl group, an arylsulfanyl group, an acyl group, or an amino group is preferable, an alkyl group, an alkoxy group, an aryl group, an aryloxy group, a heterocyclic oxy group, an alkylsulfanyl group, an arylsulfanyl group, or an amino group is more preferable, and an alkoxy group, an alkylsulfanyl group, or an amino group is still more preferable. Examples of the halogen atom include a fluorine atom, a chlorine atom, a bromine atom, and an iodine atom. Examples of the alkyl group, alkoxy group, aryl group, aryloxy group, heterocyclic group, heterocyclic oxy group, alkenyl group, alkylsulfanyl group, arylsulfanyl group, acyl group, and amino group include groups described as groups represented by R^{OX11} described above.

In the formulae, it is preferable that R^{X12} is an electron withdrawing group, and R^{X10}, R^{X11}, R^{X13}, and R^{X14} are hydrogen atoms.

Specific examples of the oxime compound OX include compounds having the following structures and compounds described in paragraph Nos. 0083 to 0105 of JP4600600B.

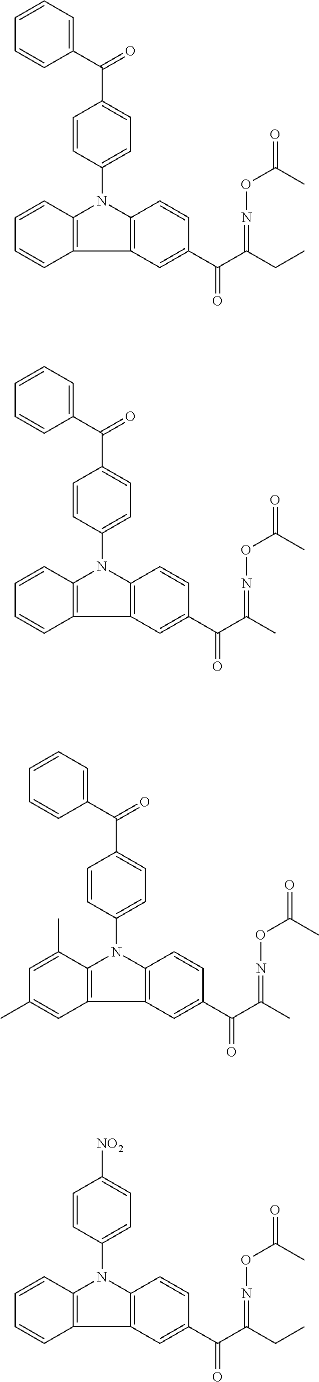

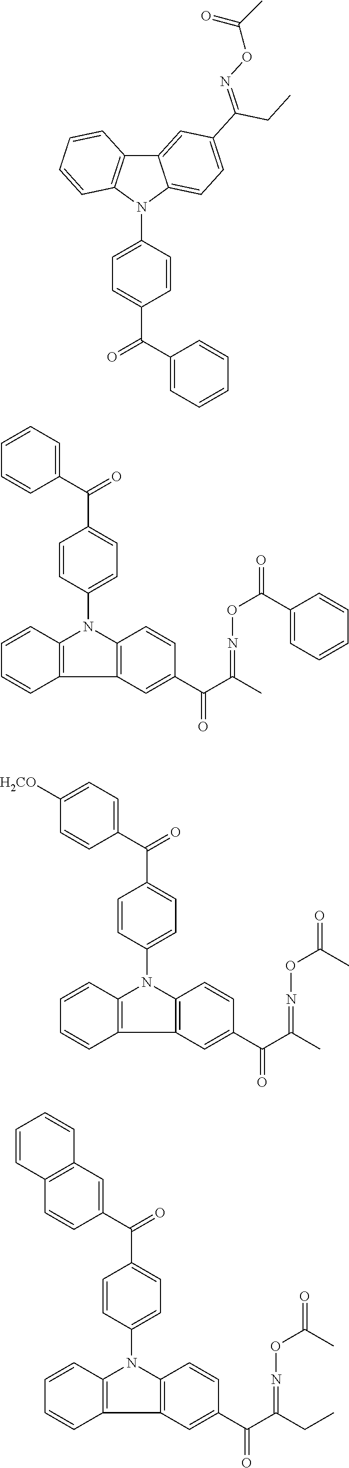

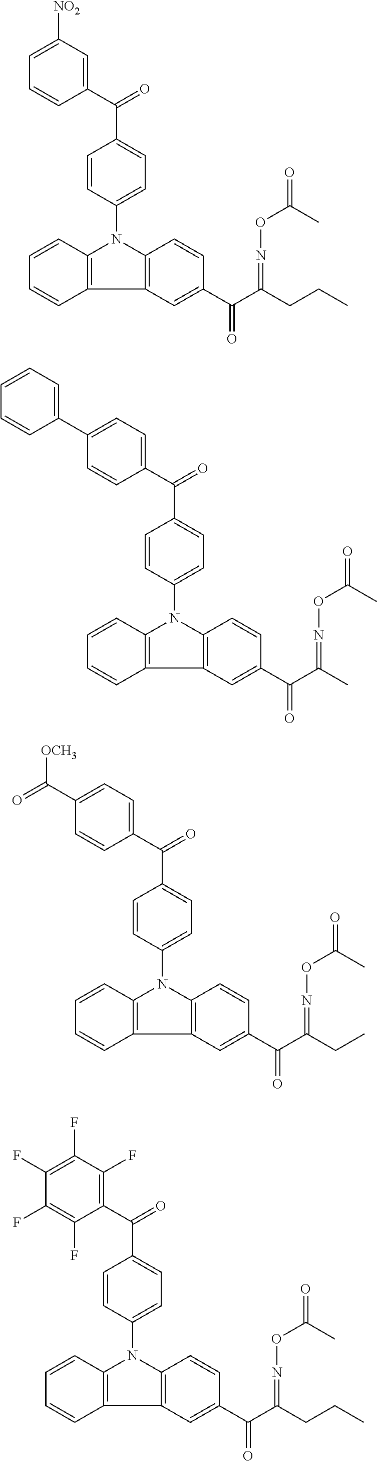 [SMILES: CCCC(=NOC(C)=O)C(=O)c1ccc2c(c1)c1ccccc1n2-c1ccc(C(=O)c2cccc([N+](=O)[O-])c2)cc1 ; CC(=O)ON=C(C)C(=O)c1ccc2c(c1)c1ccccc1n2-c1ccc(C(=O)c2ccc(-c3ccccc3)cc2)cc1 ; CCC(=NOC(C)=O)C(=O)c1ccc2c(c1)c1ccccc1n2-c1ccc(C(=O)c2ccc(C(=O)OC)cc2)cc1 ; CCCC(=NOC(C)=O)C(=O)c1ccc2c(c1)c1ccccc1n2-c1ccc(C(=O)c2c(F)c(F)c(F)c(F)c2F)cc1]

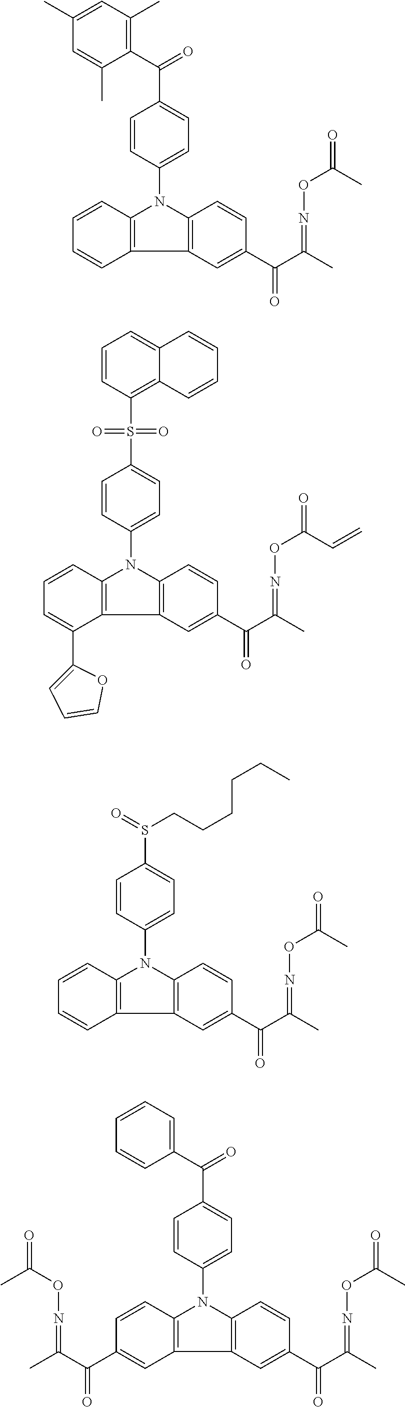

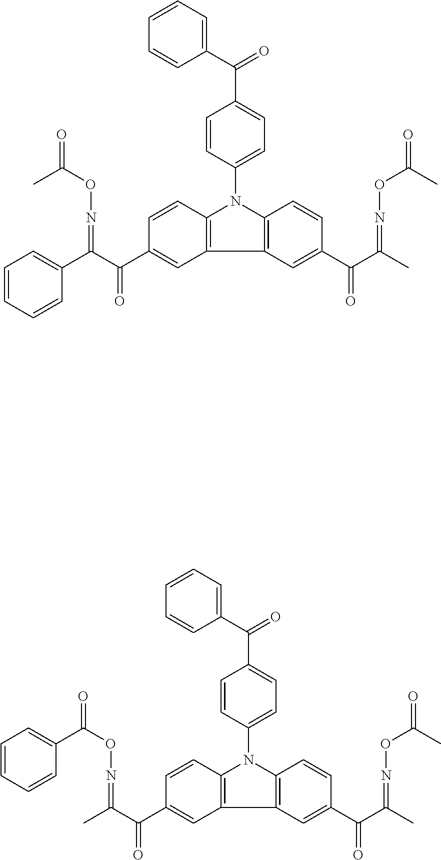 [SMILES: CC(=O)ON=C(C)C(=O)c1ccc2c(c1)c1cc(C(=O)C(=NOC(C)=O)c3ccccc3)ccc1n2-c1ccc(C(=O)c2ccccc2)cc1 ; CC(=O)ON=C(C)C(=O)c1ccc2c(c1)c1cc(C(=O)C(C)=NOC(=O)c3ccccc3)ccc1n2-c1ccc(C(=O)c2ccccc2)cc1]

The photopolymerization initiator included in the photosensitive composition according to the embodiment of the present invention may further include a photopolymerization initiator (hereinafter, also referred to as other photopolymerization initiators) other than the above-described oxime compound OX.

Examples of the other photopolymerization initiators include a halogenated hydrocarbon derivative (such as a compound having a triazine skeleton and a compound having an oxadiazole skeleton), an acylphosphine compound, hexaarylbiimidazole, an oxime compound, an organic peroxide, a thio compound, a ketone compound, an aromatic onium salt, an α-hydroxyketone compound, and α-aminoketone compound. Among these, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, or an acylphosphine compound is more preferable, and from the reason that an initiator efficiency is high, an oxime compound or an α-aminoketone compound is still more preferable. In addition, as the other photopolymerization initiators, compounds described in paragraphs 0065 to 0111 of JP2014-130173A, compounds described in JP6301489B, peroxide-based photopolymerization initiators described in MATERIAL STAGE, p. 37 to 60, vol. 19, No. 3, 2019, photopolymerization initiators described in WO2018/221177A, photopolymerization initiators described in WO2018/110179A, photopolymerization initiators described in JP2019-043864A, and photopolymerization initiators described in JP2019-044030A, the contents of which are incorporated herein by reference.

Examples of a commercially available product of the α-hydroxyketone compound include Omnirad 184, Omnirad 1173, Omnirad 2959, and Omnirad 127 (all of which are manufactured by IGM Resins B.V.), Irgacure 184, Irgacure 1173, Irgacure 2959, and Irgacure 127 (all of which are manufactured by BASF SE). Examples of a commercially available product of the α-aminoketone compound include Omnirad 907, Omnirad 369, Omnirad 369E, and Omnirad 379EG (all of which are manufactured by IGM Resins B.V.), Irgacure 907, Irgacure 369, Irgacure 369E, and Irgacure 379EG (all of which are manufactured by BASF SE). Examples of a commercially available product of the acylphosphine compound include Omnirad 819 and Omnirad TPO (both of which are manufactured by IGM Resins B.V.), Irgacure 819 and Irgacure TPO (both of which are manufactured by BASF SE).

Examples of the oxime compound used as the other photopolymerization initiators include the compounds described in JP2001-233842A, the compounds described in JP2000-080068A, the compounds described in JP2006-342166A, the compounds described in J. C. S. Perkin II (1979, pp. 1653 to 1660), the compounds described in J. C. S. Perkin 11 (1979, pp. 156 to 162), the compounds described in Journal of Photopolymer Science and Technology (1995, pp. 202 to 232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, and compounds described in WO2013/167515A. Examples of a commercially available product of the oxime compound used as the other photopolymerization initiators include Irgacure OXE01, Irgacure OXE02, Ihgacure OXE03, and Irgacure OXE04 (all of which are manufactured by BASF SE), and TR-PBG-304 (manufactured by TRONLY).

As the oxime compound used as the other photopolymerization initiators, an oxime compound having a fluorene ring can also be used. Specific examples of the oxime compound having a fluorene ring include the compounds described in JP2014-137466A.

As the oxime compound used as the other photopolymerization initiators, an oxime compound having a skeleton in which at least one benzene ring of a carbazole ring is a naphthalene ring can also be used. Specific examples of such an oxime compound include the compounds described in WO2013/083505A.

As the oxime compound used as the other photopolymerization initiators, an oxime compound having a fluorine atom can also be used. Specific examples of the oxime compound having a fluorine atom include the compounds described in JP2010-262028A, the compounds 24, and 36 to 40 described in JP2014-500852A, and the compound (C-3) described in JP2013-164471A

As the oxime compound used as the other photopolymerization initiators, an oxime compound having a benzofuran skeleton can also be used. Specific examples thereof include OE-01 to OE-75 described in WO2015/036910A.

As the oxime compound used as the other photopolymerization initiators, an oxime compound in which a substituent having a hydroxy group is bonded to a carbazole skeleton can also be used. Examples of such a photopolymerization initiator include compounds described in WO2019/088055A.

A content of the photopolymerization initiator in the total solid content of the photosensitive composition is preferably 0.10% to 20% by mass. The lower limit is preferably 0.5% by mass or more and more preferably 1% by mass or more. The upper limit is preferably 10% by mass or less and more preferably 8% by mass or less.

A content of the oxime compound OX in the total solid content of the photosensitive composition is preferably 0.1% to 20% by mass. The lower limit is preferably 0.5% by mass or more and more preferably 1% by mass or more. The upper limit is preferably 10% by mass or less and more preferably 8% by mass or less.

The content of the oxime compound OX in photopolymerization initiators included in the photosensitive composition is preferably 20% to 100% by mass, more preferably 35% to 100% by mass, still more preferably 40% to 100% by mass, even more preferably 50% to 100% by mass, and particularly preferably 60% to 100% by mass.

Examples of a preferred aspect of the photopolymerization initiator included in the photosensitive composition include an aspect in which the photopolymerization initiator is substantially only the oxime compound OX. According to this aspect, the effects of the present invention are more prominently exhibited. In the present specification, the case where the photopolymerization initiator is substantially only the oxime compound OX means that the content of the oxime compound OX in the photopolymerization initiator is 99% by mass or more, preferably 99.9% by mass or more and more preferably 100% by mass.

Examples of another preferred aspect of the photopolymerization initiator included in the photosensitive composition include an aspect in which the photopolymerization initiator includes the oxime compound OX and the other photopolymerization initiators other than the oxime compound OX. According to this aspect, the entire film can be cured more uniformly, and a film with smaller surface roughness can be formed. In this aspect, as the other photopolymerization initiators, at least one selected from the oxime compound or the α-aminoketone compound is preferable. In addition, the content of the other photopolymerization initiators is preferably 10 to 200 parts by mass, more preferably 20 to 100 parts by mass, and still more preferably 30 to 80 parts by mass with respect to 100 parts by mass of the oxime compound OX.

<<Polymerizable Monomer>>

The photosensitive composition according to the embodiment of the present invention includes a polymerizable monomer. The polymerizable monomer is preferably, for example, a compound having an ethylenically unsaturated bond-containing group. Examples of the ethylenically unsaturated bond-containing group include a vinyl group, a vinylphenyl group, a (meth)allyl group, a (meth)acryloyl group, a (meth)acryloyloxy group, and a (meth)acryloylamide group, and a (meth)acryloyloxy group is preferable. The polymerizable monomer used in the present invention is preferably a radically polymerizable monomer.

The polymerizable monomer is preferably a compound including 3 or more ethylenically unsaturated bond-containing groups, more preferably a compound (3- to 15-functional polymerizable monomer) including 3 to 15 ethylenically unsaturated bond-containing groups, and still more preferably a compound (3- to 6-functional polymerizable monomer) including 3 to 6 ethylenically unsaturated bond-containing groups. Among these, as the polymerizable monomer, a compound (3-functional polymerizable monomer) having 3 ethylenically unsaturated bond-containing groups is particularly preferable. In addition, the polymerizable monomer is preferably a 3- to 15-functional (meth)acrylate compound and more preferably a 3- to 6-functional (meth)acrylate compound. Among these, as the polymerizable monomer, it is particularly preferable to use a 3-functional (meth)acrylate compound. Specific examples of the polymerizable monomer include the compounds described in paragraph Nos. 0095 to 0108 of JP2009-288705A, paragraph No. 0227 of JP2013-029760A, paragraph Nos. 0254 to 0257 of JP2008-292970A, paragraph Nos. 0034 to 0038 of JP2013-253224A, paragraph No. 0477 of JP2012-208494A, JP2017-048367A, JP6057891B, and JP6031807B, the contents of which are incorporated herein by reference.

Examples of the polymerizable monomer include dipentaerythritol tri(meth)acrylate (as a commercially available product, KAYARAD D-330 manufactured by Nippon Kayaku Co., Ltd.), dipentaerythritol tetra(meth)acrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), and a compound having a structure in which these (meth)acryloyl groups are bonded through an ethylene glycol and/or a propylene glycol residue (for example, SR454 and SR499 which are commercially available products from Sartomer Company Inc.). In addition, as the polymerizable monomer, diglycerin ethylene oxide (EO)-modified (meth)acrylate (as a commercially available product. M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd.), ARONIX TO-2349 (manufactured by TOAGOSEI CO., LTD.), NK OLIGO UA-7200 (manufactured by Shin-Nakamura Chemical Co., Ltd.), U-6LPA (urethane acrylate, manufactured by Shin-Nakamura Chemical Co., Ltd.), DPHA-40H (manufactured by Nippon Kayaku Co., Ltd.), UA-306H, UA-306T, UA-3061, AH-600, T-600, AI-600, and LINC-202UA (all of which are manufactured by KYOEISHA CHEMICAL Co., LTD.), 8UH-1006 and 8UH-1012 (both of which are manufactured by Taisei Fine Chemical Co., Ltd.), Light Acrylate POB-A0 (manufactured by KYOEISHA CHEMICAL Co., Ltd.), and the like can also be used.

In addition, examples of the polymerizable monomer include a 3-functional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the 3-functional (meth)acrylate compound include ARONIX M-309, M-310, M-321, M-350, M-360, M-313, M-315, M-306, M-305, M-303, M-452, and M-450 (all of which are manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (all of which are manufactured by Shin-Nakamura Chemical Co., Ltd.), and KAYARAD GPO-303, TMPTA, THE-330, TPA-330, and PET-30 (all of which are manufactured by Nippon Kayaku Co., Ltd.).

In addition, as the polymerizable monomer, a compound having an acid group can also be used. By using a polymerizable monomer having an acid group, a photosensitive composition layer in a non-exposed portion is easily removed during development and the generation of the development residue can be suppressed. Examples of the acid group include a carboxy group, a sulfo group, and a phosphoric acid group, and a carboxy group is preferable. Examples of a commercially available product of the polymerizable monomer having an acid group include ARONIX M-510, M-520, and ARONIX TO-2349 (all of which are manufactured by TOAGOSEI CO., LTD). An acid value of the polymerizable monomer having an acid group is preferably 0.1 to 40 mgKOH/g and more preferably 5 to 30 mgKOH/g. In a case where the acid value of the polymerizable monomer is 0.1 mgKOH/g or more, solubility in a developer is good, and in a case where the acid value of the polymerizable compound is 40 mgKOH/g or less, it is advantageous in production and handling.

In addition, as the polymerizable monomer, a compound having a caprolactone structure can also be used. Examples of a commercially available product of the polymerizable monomer having a caprolactone structure include KAYARAD DPCA-20, DPCA-30, DPCA-60, and DPCA-120 (all of which are manufactured by Nippon Kayaku Co., Ltd.).

In addition, as the polymerizable monomer, a polymerizable monomer having a fluorene skeleton can also be used. Examples of a commercially available product of the polymerizable monomer having a fluorene skeleton include OGSOL EA-0200 and EA-0300 (manufactured by Osaka Gas Chemicals Co., Ltd., a (meth)acrylate monomer having a fluorene skeleton).

In addition, as the polymerizable monomer, it is also preferable to use a compound which does not substantially include environmentally regulated substances such as toluene. Examples of a commercially available product of such a polymerizable monomer include KAYARAD DPHA LT and KAYARAD DPEA-12 LT (manufactured by Nippon Kayaku Co., Ltd.).

A molecular weight of the polymerizable monomer is preferably 100 to 2000. The upper limit is preferably 1500 or less, more preferably 1000 or less, and still more preferably 600 or less. The lower limit is preferably 150 or more, more preferably 200 or more, and still more preferably 250 or more. The molecular weight of the polymerizable monomer is particularly preferably 250 to 600.

An ethylenically unsaturated bond-containing group value (hereinafter, also referred to as a C═C value) of the polymerizable monomer is preferably 50 to 500 g/mol. The lower limit is preferably 80 g/mol or more and particularly preferably 100 g/mol or more. The upper limit is preferably 400 g/mol or less and particularly preferably 300 g/mol or less. The C═C value of the polymerizable monomer is particularly preferably 100 to 300 g/mol. The C═C value of the polymerizable monomer is a value calculated by dividing the molecular weight of the polymerizable monomer by the number of ethylenically unsaturated bond groups included in one molecule of the polymerizable monomer.

As the polymerizable monomer, a compound having an alkyleneoxy group is also preferable. The number of alkyleneoxy groups included in the polymerizable monomer having an alkyleneoxy group is preferably 2 to 15 and more preferably 3 to 12. In addition, the number of carbon atoms in the alkyleneoxy group is preferably 1 to 10, more preferably 1 to 5, still more preferably 1 to 3, particularly preferably 2 or 3, and most preferably 2. That is, the alkyleneoxy group is particularly preferably an ethyleneoxy group or a propyleneoxy group, and most preferably an ethyleneoxy group.

As the polymerizable monomer having an alkyleneoxy group and having 3 ethylenically unsaturated bond-containing groups, a compound represented by Formula (M1) is preferable.

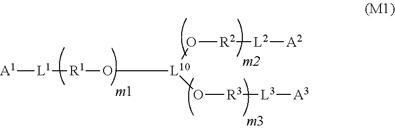

In the formula, A¹ to A³ each independently represent an ethylenically unsaturated bond-containing group, L¹ to L³ each independently represent a single bond or a divalent linking group, R¹ to R³ each independently represent an alkylene group, m1 to m3 each independently represent an integer of 0 to 10, L¹⁰ represents a trivalent linking group, and the total of m1, m2, and m3 is 1 or more.

Examples of the ethylenically unsaturated bond-containing group represented by A¹ to A³ include a vinyl group, a vinylphenyl group, a (meth)allyl group, a (meth)acryloyl group, a (meth)acryloyloxy group, and a (meth)acryloylamide group. Among these, a vinyl group, a (meth)allyl group, a (meth)acryloyl group, or a (meth)acryloyloxy group is preferable, and a (meth)acryloyloxy group is more preferable.

Examples of the divalent linking group represented by L¹ to L³ include an alkylene group, an arylene group, —O—, —CO—, —COO—, —OCO—, —NH—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10.

The number of carbon atoms in the alkylene group represented by R¹ to R³ is preferably 1 to 10, more preferably 1 to 5, still more preferably 1 to 3, particularly preferably 2 or 3, and most preferably 2. The alkylene group represented by R¹ is preferably linear or branched, and more preferably linear. Specific examples of the alkylene group represented by R¹ include an ethylene group and a linear or branched propylene group, and an ethylene group is preferable.

m1 to m3 each independently represent 0 to 10, preferably 0 to 7, more preferably 0 to 5, and still more preferably 0 to 3. In addition, the total of m1, m2, and m3 is 1 or more, preferably 2 or more and more preferably 3 or more. The upper limit is preferably 20 or less, more preferably 10 or less, and still more preferably 6 or less. In addition, the total of m1, m2, and m3 is preferably 2 to 6 and more preferably 3 to 6.

Examples of the trivalent linking group represented by L¹⁰ include an aliphatic hydrocarbon group, an aromatic hydrocarbon group, a heterocyclic group, a group consisting of a combination thereof, and a group of a combination of at least one selected from an aliphatic hydrocarbon group, an aromatic hydrocarbon group, and a heterocyclic group, and at least one selected from —O—, —CO—, —COO—, —OCO—, and —NH—, and an aliphatic hydrocarbon group is preferable. The number of carbon atoms in the aliphatic hydrocarbon group is preferably 1 to 30, more preferably 1 to 20, and still more preferably 1 to 15. The aliphatic hydrocarbon group represented by L¹⁰ may linear, branched, or cyclic, and is preferably branched. The number of carbon atoms in the aromatic hydrocarbon group is preferably 6 to 30, more preferably 6 to 20, and still more preferably 6 to 10. The heterocyclic group may be a non-aromatic heterocyclic group or an aromatic heterocyclic group. The heterocyclic group is preferably a 5-membered ring or a 6-membered ring. Examples of the kind of the heteroatom constituting the heterocyclic group include a nitrogen atom, an oxygen atom, and a sulfur atom. The number of heteroatoms constituting the heterocyclic group is preferably 1 to 3. The heterocyclic group may be a single ring or a fused ring. The aliphatic hydrocarbon group, the aromatic hydrocarbon group, and the heterocyclic group may have a substituent. Examples of the substituent include groups in the description of the substituent T described above.

As the polymerizable monomer having an alkyleneoxy group and having 3 ethylenically unsaturated bond-containing groups, a compound represented by Formula (M2) is more preferable.

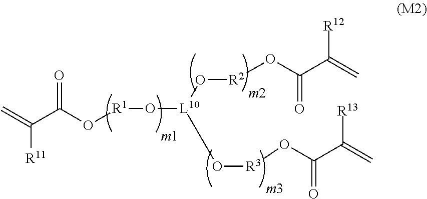

In the formula. R¹¹ to R¹³ each independently represent a hydrogen atom or a methyl group, R¹ to R³ each independently represent an alkylene group, m1 to m3 each independently represent an integer of 0 to 10, L¹⁰ represents a trivalent linking group, and the total of m1, m2, and m3 is 1 or more. R¹ to R³, L¹⁰, and m1 to m3 in Formula (M2) are the same as R¹ to R³, L¹⁰, and m1 to m3 in Formula (M1), the preferred ranges are also the same.

As the polymerizable monomer, it is preferable to use a compound having a molecular weight of 250 to 600, having a C═C value of 100 to 300 g/mol, having an alkyleneoxy group, and having 3 ethylenically unsaturated bond-containing groups (hereinafter, also referred to as a specific 3-functional monomer). Such a polymerizable monomer has moderately high fluidity, and it is possible to cure the polymerizable monomer of the exposed portion more uniformly during exposure, so that a pixel with smaller surface roughness can be formed.

Specific examples of the specific 3-functional monomer include trimethylolpropane propyleneoxide-modified triacrylate (manufactured by TOAGOSEI CO., LTD., ARONIX M-310, number of functional groups: 3, molecular weight: 471, ethylenically unsaturated bond-containing group value: 157 g/mol, compound having an alkyleneoxy group (propyleneoxy group)), and trimethylolpropane ethyleneoxide-modified triacrylate (manufactured by TOAGOSEI CO., LTD., ARONIX M-350, number of functional groups: 3, molecular weight: 429, ethylenically unsaturated bond-containing group value: 143 g/mol, compound having an alkyleneoxy group (ethyleneoxy group)).

A content of the polymerizable monomer in the total solid content of the photosensitive composition is preferably 1% to 25% by mass. The lower limit is preferably 2% by mass or more and more preferably 5% by mass or more. The upper limit is preferably 21% by mass or less and more preferably 18% by mass or less. The polymerizable monomer may be used singly or in a combination of two or more kinds thereof. In a case where two or more kinds thereof are used in combination, the total thereof is preferably within the above-described range.

In addition, a content of the compound (3-functional polymerizable monomer) having 3 ethylenically unsaturated bond-containing groups in the total amount of the polymerizable monomer is preferably 30% to 100% by mass, more preferably 50% to 100% by mass, and still more preferably 70% to 100% by mass. The polymerizable monomer included in the photosensitive composition may be substantially only the 3-functional polymerizable monomer, or may include the 3-functional polymerizable monomer and a 4- or higher functional polymerizable monomer, respectively. In a case where the polymerizable monomer is substantially only the 3-functional polymerizable monomer, local crosslinking is less likely to occur, and a film with smaller surface roughness can be formed. The case where the polymerizable monomer is substantially only the 3-functional polymerizable monomer means that the content of the 3-functional polymerizable monomer in the total amount of the polymerizable monomer included in the photosensitive composition is 99% by mass or more, preferably 99.5% by mass or more and more preferably 99.9% by mass or more, and it is still more preferable that the polymerizable monomer included in the photosensitive composition is composed of only the 3-functional polymerizable monomer. In a case where the polymerizable monomer includes the 3-functional polymerizable monomer and a 4- or higher functional polymerizable monomer, respectively, more excellent adhesiveness can be obtained. In a case where the 3-functional polymerizable monomer and the 4- or higher functional polymerizable monomer are used in combination, the amount of the 4- or higher functional polymerizable monomer is preferably 10 to 60 parts by mass, more preferably 20 to 50 parts by mass, and still more preferably 30 to 40 parts by mass with respect to 100 parts by mass of the 3-functional polymerizable monomer.

In addition, the content of the above-described specific 3-functional monomer in the total amount of the polymerizable monomer is preferably 30% to 100% by mass, more preferably 50% to 100% by mass, and still more preferably 70% to 100% by mass. The polymerizable monomer included in the photosensitive composition may be substantially only the specific 3-functional monomer, or may include the specific 3-functional monomer and a polymerizable monomer other than the specific 3-functional monomer (hereinafter, also referred to as other polymerizable monomers), respectively. In a case where the polymerizable monomer is substantially only the specific 3-functional monomer, it is possible to cure the polymerizable monomer of the exposed portion more uniformly during exposure, and a pixel with smaller surface roughness can be formed. The case where the polymerizable monomer is substantially only the specific 3-functional monomer means that the content of the specific 3-functional monomer in the total amount of the polymerizable monomer included in the photosensitive composition is 99% by mass or more, preferably 99.5% by mass or more and more preferably 99.9% by mass or more, and it is still more preferable that the polymerizable monomer included in the photosensitive composition is composed of only the specific 3-functional monomer. In a case where the polymerizable monomer includes the specific 3-functional monomer and the other polymerizable monomers, respectively, local crosslinking is less likely to occur, and a film with smaller surface roughness can be formed. Examples of the other polymerizable monomers which are preferably used in combination with the specific 3-functional monomer include a 2-functional monomer, a 3-functional monomer other than the specific 3-functional monomer, and a 4- or higher functional monomer, and a 3-functional monomer other than the specific 3-functional monomer or a 4- or higher functional monomer having a molecular weight of 250 to 600, having a C═C value of 100 to 300 g/mol, and having an alkyleneoxy group is preferable. Specifically, the specific 3-functional monomer such as trimethylolpropane triacrylate, tris(2-acryloyloxyethyl) isocyanurate, and pentaerythritol ethyleneoxide-modified tetraacrylate and the other polymerizable monomers are used in combination, the amount of the other polymerizable monomers is preferably 10 to 60 parts by mass, more preferably 20 to 50 parts by mass, and still more preferably 30 to 40 parts by mass with respect to 100 pans by mass of the specific 3-functional monomer.

<<Resin>>

The photosensitive composition according to the embodiment of the present invention contains a resin. The resin is blended in, for example, an application for dispersing the pigment in the photosensitive composition or an application as a binder. Mainly, a resin which is used for dispersing the pigment in the photosensitive composition is also referred to as a dispersant. However, such applications of the resin are merely exemplary, and the resin can also be used for other purposes in addition to such applications.

A weight-average molecular weight (Mw) of the resin is preferably 3000 to 2000000. The upper limit is preferably 1000000 or less and more preferably 500000 or less. The lower limit is preferably 4000 or more and more preferably 5000 or more.

Examples of the resin include a (meth)acrylic resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, and a styrene resin. These resins may be used singly or as a mixture of two or more kinds thereof.

The photosensitive composition according to the embodiment of the present invention also preferably includes a resin having an acid group. Examples of the acid group include a carboxyl group, a phosphoric acid group, a sulfo group, and a phenolic hydroxy group. Among these acid groups, one kind may be used singly, or two or more kinds may be used in combination. The resin having an acid group can also be used as a dispersant. In a case where the photosensitive composition according to the embodiment of the present invention contains a resin having an acid group, a desired pattern can be formed by an alkali development. An acid value of the resin having an acid group is preferably 30 to 500 mgKOH/g. The lower limit is preferably 50 mgKOH/g or more and more preferably 70 mgKOH/g or more. The upper limit is preferably 400 mgKOH/g or less, more preferably 200 mgKOH/g or less, still more preferably 150 mgKOH/g or less, and most preferably 120 mgKOH/g or less.

The photosensitive composition according to the embodiment of the present invention also preferably includes a resin having a basic group. The resin having a basic group is preferably a resin including a repeating unit having a basic group in the side chain, more preferably a copolymer having a repeating unit having a basic group in the side chain and a repeating unit not having a basic group, and still more preferably a block copolymer having a repeating unit having a basic group in the side chain and a repeating unit not having a basic group. The resin having a basic group can also be used as a dispersant. An amine value of the resin having a basic group is preferably 5 to 300 mgKOH/g. The lower limit is preferably 10 mgKOH/g or more and more preferably 20 mgKOH/g or more. The upper limit is preferably 200 mgKOH/g or less and more preferably 100 mgKOH/g or less. Examples of the basic group included in the resin having a basic group include a group represented by Formula (a-1) and a group represented by Formula (a-2).

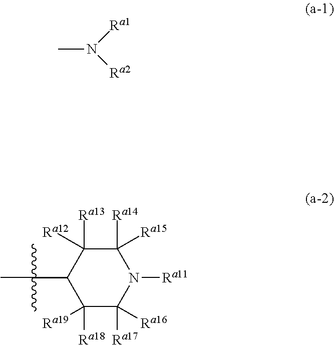

In Formula (a-1), R^{a1} and R^{a2} each independently represent a hydrogen atom, an alkyl group, or an aryl group, and R^{a1} and R^{a2} may be bonded to each other to form a ring;

in Formula (a-2), R^{a11} represents a hydrogen atom, a hydroxy group, an alkyl group, an alkoxy group, an aryl group, an aryloxy group, an acyl group, or an oxyradical, and R^{a12} to R^{a19} each independently represent a hydrogen atom, an alkyl group, or an aryl group.

The alkyl group represented by R^{a1}, R^{a2}, R^{a11} R^{a19} preferably has 1 to 30 carbon atoms, more preferably has 1 to 15 carbon atoms, still more preferably has 1 to 8 carbon atoms, and particularly preferably has 1 to 5 carbon atoms. The alkyl group may be any of linear, branched, and cyclic forms, and is preferably linear or branched and more preferably linear. The alkyl group may have a substituent. Examples of the substituent include groups selected from the group of substituents T described above.

The aryl group represented by R^{a1}, R^{a2}, R^{a11} to R^{a19} preferably has 6 to 30 carbon atoms, more preferably has 6 to 20 carbon atoms, and still more preferably has 6 to 12 carbon atoms. The aryl group may have a substituent. Examples of the substituent include groups selected from the group of substituents T described above.

The alkoxy group represented by R^{a11} preferably has 1 to 30 carbon atoms, more preferably has 1 to 15 carbon atoms, still more preferably has 1 to 8 carbon atoms, and particularly preferably has 1 to 5 carbon atoms. The alkoxy group may have a substituent. Examples of the substituent include groups selected from the group of substituents T described above.

The aryloxy group represented by R^{a11} preferably has 6 to 30 carbon atoms, more preferably has 6 to 20 carbon atoms, and still more preferably has 6 to 12 carbon atoms. The aryloxy group may have a substituent. Examples of the substituent include groups selected from the group of substituents T described above.

The acyl group represented by R^{a11} preferably has 2 to 30 carbon atoms, more preferably has 2 to 20 carbon atoms, and still more preferably has 2 to 12 carbon atoms. The acyl group may have a substituent. Examples of the substituent include groups selected from the group of substituents T described above.

Examples of a commercially available product of the resin having a basic group include DISPERBYK-161, 162, 163, 164, 166, 167, 168, 174, 182, 183, 184, 185, 2000, 2001, 2050, 2150, 2163, 2164, and BYK-LPN 6919 (all of which are manufactured by BYK Chemie Japan), SOLSPERSE 11200, 13240, 13650, 13940, 24000, 26000, 28000, 32000, 32500, 32550, 32600, 33000, 34750, 35100, 35200, 37500, 38500, 39000, 53095, 56000, and 7100 (all of which are manufactured by Lubrizol Japan Ltd.), and Efka PX 4300, 4330, 4046, 4060, and 4080 (all of which are manufactured by BASF SE). In addition, as the resin having a basic group, a block copolymer (B) described in paragraph Nos. 0063 to 0112 of JP2014-219665A or a block copolymer A1 described in paragraph Nos. 0046 to 0076 of JP2018-156021A, the contents of which are incorporated herein by reference.

It is also preferable that the photosensitive composition according to the embodiment of the present invention includes the resin having an acid group and the resin having a basic group, respectively. According to this aspect, the storage stability of the photosensitive composition can be further improved. In a case where the resin having an acid group and the resin having a basic group are used in combination, a content of the resin having a basic group is preferably 20 to 500 parts by mass, more preferably 30 to 300 parts by mass, and still more preferably 50 to 200 parts by mass with respect to 100 parts by mass of the resin having an acid group.

The resin also preferably includes a resin including a repeating unit derived from a compound represented by Formula (ED) and/or a compound represented by Formula (ED2) (hereinafter, these compounds will also be referred to as an “ether dimer”).

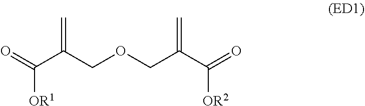

In Formula (ED1), R¹ and R² each independently represent a hydrogen atom or a hydrocarbon group having 1 to 25 carbon atoms, which may have a substituent.

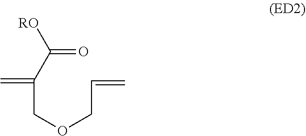

In Formula (ED2), R represents a hydrogen atom or an organic group having 1 to 30 carbon atoms. Specific examples of Formula (ED2) can be found in the description of JP2010-168539A.

Specific examples of the ether dimer can be found in paragraph No. 0317 of JP2013-029760A, the contents of which are incorporated herein by reference.

The resin also preferably includes a resin including a repeating unit having an ethylenically unsaturated bond-containing group. Examples of the ethylenically unsaturated bond-containing group include a vinyl group, a vinylphenyl group, a (meth)allyl group, a (meth)acryloyl group, a (meth)acryloyloxy group, and a (meth)acryloylamide group.

The resin also preferably includes a resin including a repeating unit derived from a compound represented by Formula (X).

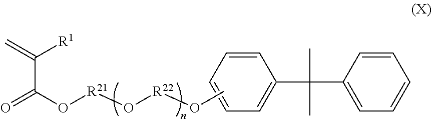

In the formula, R¹ represents a hydrogen atom or a methyl group, R²¹ and R²² each independently represent an alkylene group, and n represents an integer of 0 to 15. The number of carbon atoms in the alkylene group represented by R²¹ and R²² is preferably 1 to 10, more preferably 1 to 5, still more preferably 1 to 3, and particularly preferably 2 or 3. n represents an integer of 0 to 15, and is preferably an integer of 0 or 5, more preferably an integer of 0 to 4, and still more preferably an integer of 0 to 3.

Examples of the compound represented by Formula (X) include ethylene oxide- or propylene oxide-modified (meth)acrylate of para-cumylphenol. Examples of a commercially available product thereof include ARONIX M-110 (manufactured by TOAGOSEI CO., LTD.).

As the resin, it is also preferable to include a resin (hereinafter, also referred to as a resin Ac) having an aromatic carboxyl group. According to this aspect, it is easy to form a pixel in which the color unevenness is further suppressed. The resin Ac may include the aromatic carboxyl group in the main chain of the repeating unit, or in the side chain of the repeating unit. It is preferable that the aromatic carboxyl group is included in the main chain of the repeating unit. In the present specification, the aromatic carboxyl group is a group having a structure in which one or more carboxyl groups are bonded to an aromatic ring. In the aromatic carboxyl group, the number of carboxyl groups bonded to an aromatic ring is preferably 1 to 4 and more preferably 1 or 2.

The resin Ac is preferably a resin including at least one repeating unit selected from a repeating unit represented by Formula (Ac-1) and a repeating unit represented by Formula (Ac-2), and more preferably a resin including a repeating unit represented by Formula (Ac-2). In a case where the resin having an aromatic carboxyl group is a resin having the repeating unit represented by Formula (Ac-2), this resin is preferably used as a dispersant.

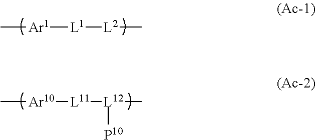

In Formula (Ac-1). Ar¹ represents a group including an aromatic carboxyl group, L¹ represents —COO— or —CONH—, and L² represents a divalent linking group.

In Formula (Ac-2), Ar¹⁰ represents a group including an aromatic carboxyl group, L¹¹ represents —COO— or —CONH—. L¹² represents a trivalent linking group, and P¹⁰ represents a polymer chain.

In Formula (Ac-1), examples of the group including an aromatic carboxyl group, represented by Ar¹, include a structure derived from an aromatic tricarboxylic acid anhydride and a structure derived from an aromatic tetracarboxylic acid anhydride. Examples of the aromatic tricarboxylic acid anhydride and the aromatic tetracarboxylic acid anhydride include compounds having the following structures.

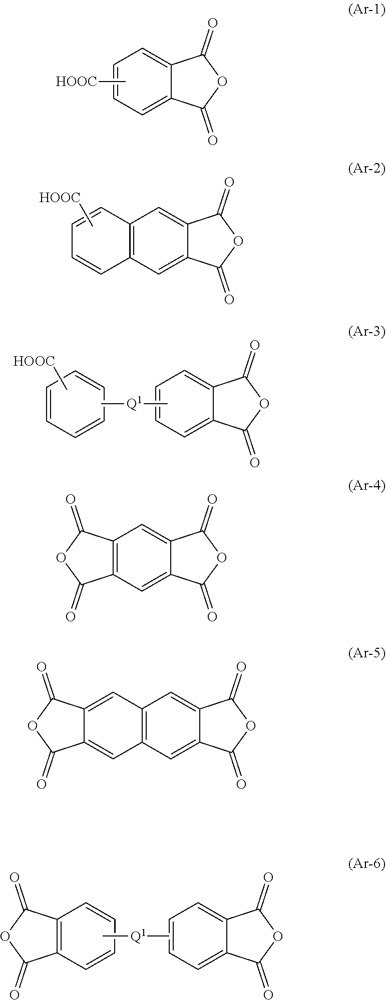

In the formulae, Q¹ represents a single bond, —O—, —CO—, —COOCH₂CH₂OCO—, —SO₂—, —C(CF₃)₂—, a group represented by Formula (Q-1), or a group represented by Formula (Q-2).

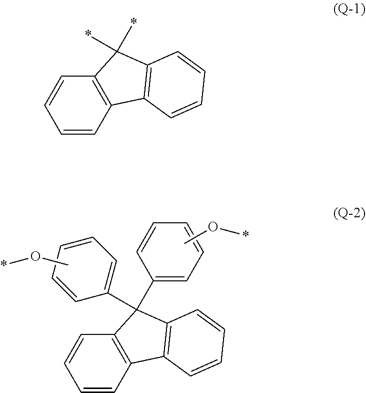

Specific examples of the group including an aromatic carboxyl group represented by Ar¹ include a group represented by Formula (Ar-11), a group represented by Formula (Ar-12), and a group represented by Formula (Ar-13).

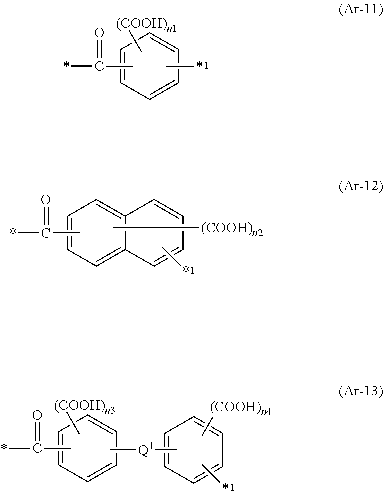

In Formula (Ar-11), n1 represents an integer of 1 to 4, and is preferably 1 or 2 and more preferably 2.

In Formula (Ar-12), n2 represents an integer of 1 to 8, and is preferably an integer of 1 or 4, more preferably 1 or 2, and still more preferably 2.

In Formula (Ar-13), n3 and n4 each independently represent an integer of 0 to 4, and are preferably an integer of 0 or 2, more preferably 1 or 2, and still more preferably 1. However, at least one of n3 or n4 is an integer of 1 or more.

In Formula (Ar-13), Q¹ represents a single bond. —C—, —CO—, —COOCH₂CH₂OCO—, —SO₂—, —C(CF₃)₂—, the above-described group represented by Formula (Q-1), or the above-described group represented by Formula (Q-2).

In Formulae (Ar-11) to (Ar-13), *1 represents a bonding position with L¹.

In Formula (Ac-1), L¹ represents —COO— or —CONH—, preferably —COO—.

In Formula (Ac-1), examples of the divalent linking group represented by L include an alkylene group, an arylene group, —O—, —CO—, —COO—, —OCO—, —NH—, —S—, and a group formed by a combination of two or more of these groups. The number of carbon atoms in the alkylene group preferably is 1 to 30, more preferably 1 to 20, and still more preferably 1 to 15. The alkylene group may be linear, branched, or cyclic. The number of carbon atoms in the arylene group is preferably 6 to 30, more preferably 6 to 20, and still more preferably 6 to 10. The alkylene group and the arylene group may have a substituent. Examples of the substituent include a hydroxy group. The divalent linking group represented by L² is preferably a group represented by -L^{2a}-O—. Examples of L^{2a} include an alkylene group; an arylene group; a group formed by a combination of an alkylene group and an arylene group; and a group formed by a combination of at least one selected from an alkylene group or an arylene group, and at least one selected from —C—, —CO—, —COO—, —OCO—, —NH—, or —S—, and an alkylene group is preferable. The number of carbon atoms in the alkylene group preferably is 1 to 30, more preferably 1 to 20, and still more preferably 1 to 15. The alkylene group may be linear, branched, or cyclic. The alkylene group and the arylene group may have a substituent. Examples of the substituent include a hydroxy group.

In Formula (Ac-2), the group including an aromatic carboxyl group, represented by Ar¹⁰, has the same meaning as Ar¹ in Formula (Ac-1), and the preferred range is also the same.

In Formula (Ac-2), L¹¹ represents —COO— or —CONH—, preferably —COO—.

In Formula (Ac-2), examples of the trivalent linking group represented by L¹² include a hydrocarbon group, —O—, —CO—, —COO—, —OCO—, —NH—, —S—, and a group formed by a combination of two or more of these groups. Examples of the hydrocarbon group include an aliphatic hydrocarbon group and an aromatic hydrocarbon group. The number of carbon atoms in the aliphatic hydrocarbon group is preferably 1 to 30, more preferably 1 to 20, and still more preferably 1 to 15. The aliphatic hydrocarbon group may be linear, branched, or cyclic. The number of carbon atoms in the aromatic hydrocarbon group is preferably 6 to 30, more preferably 6 to 20, and still more preferably 6 to 10. The hydrocarbon group may have a substituent. Examples of the substituent include a hydroxy group. The trivalent linking group represented by L¹² is preferably a group represented by Formula (L12-1), and more preferably a group represented by Formula (L12-2).

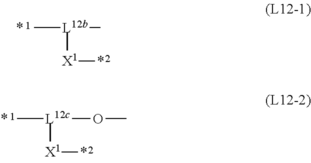

In Formula (L12-1), L^{12b} represents a trivalent linking group, X¹ represents S. *1 represents a bonding position with L¹¹ in Formula (Ac-2), and *2 represents a bonding position with P¹⁰ in Formula (Ac-2). Examples of the trivalent linking group represented by L^{12b} include a hydrocarbon group; and a group formed by a combination of a hydrocarbon group and at least one selected from —O—, —CO—, —COO—, —OCO—, —NH—, or —S—, and a hydrocarbon group or a group in which a hydrocarbon group and —O— are combined is preferable.

In Formula (L12-2), L^{12c} represents a trivalent linking group, X¹ represents S, *1 represents a bonding position with L¹¹ in Formula (Ac-2), and *2 represents a bonding position with P¹⁰ in Formula (Ac-2). Examples of the trivalent linking group represented by L^{12c} include a hydrocarbon group; and a group formed by a combination of a hydrocarbon group and at least one selected from —O—, —CO—, —COO—, —OCO—, —NH—, or —S—, and a hydrocarbon group is preferable.

In Formula (Ac-2), P¹⁰ represents a polymer chain. It is preferable that the polymer chain represented by P¹⁰ has at least one repeating unit selected from a poly(meth)acrylic repeating unit, a polyether repeating unit, a polyester repeating unit, or a polyol repeating unit. A weight-average molecular weight of the polymer chain P¹⁰ is preferably 500 to 20000. The lower limit is preferably 1000 or more. The upper limit is preferably 1000 or less, more preferably 5000 or less, and still more preferably 3000 or less. In a case where the weight-average molecular weight of P¹⁰ is within the above-described range, dispersibility of the pigment in the composition is good.

The polymer chain represented by P¹⁰ may include a crosslinkable group. Examples of the crosslinkable group include an ethylenically unsaturated bond-containing group, a cyclic ether group, and a blocked isocyanate group, and an ethylenically unsaturated bond-containing group is preferable. Examples of the ethylenically unsaturated bond-containing group include a vinyl group, a vinylphenyl group, a (meth)allyl group, a (meth)acryloyl group, a (meth)acryloyloxy group, and a (meth)acryloylamide group. Among these, a (meth)allyl group, a (meth)acryloyl group, or a (meth)acryloyloxy group is preferable, and a (meth)acryloyloxy group is more preferable. Examples of the cyclic ether group include an epoxy group and an oxetanyl group. The blocked isocyanate group in the present invention is a group capable of generating an isocyanate group by heat, and preferred examples thereof include a group in which an isocyanate group is protected by reacting a blocking agent and an isocyanate group. Examples of the blocking agent include oxime compounds, lactam compounds, phenol compounds, alcohol compounds, amine compounds, active methylene compounds, pyrazole compounds, mercaptan compounds, imidazole compounds, and imide compounds. Examples of the blocking agent include compounds described in paragraph Nos. 0115 to 0117 of JP2017-067930A, the contents of which are incorporated herein by reference. In addition, the blocked isocyanate group is preferably a group capable of generating an isocyanate group by heat of 90° C. to 260° C.

In Formula (Ac-2), the polymer chain represented by P¹⁰ is preferably a polymer chain including a repeating unit represented by Formulae (P-1) to (P-5), and more preferably a polymer chain including a repeating unit represented by (P-5).

In Formula (Ac-2), the polymer chain represented by P¹⁰ is preferably a polymer chain including a repeating unit represented by Formulae (P-1) to (P-5), and more preferably a polymer chain including a repeating unit represented by (P-5).

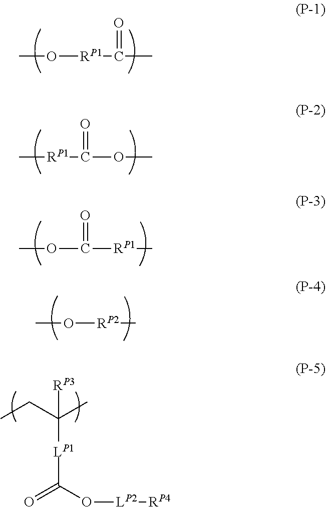

In the formulae, R^{P1} and R¹² each represent an alkylene group. As the alkylene group represented by R^{P1} and R^{P2}, a linear or branched alkylene group having 1 to 20 carbon atoms is preferable, a linear or branched alkylene group having 2 to 16 carbon atoms is more preferable, and a linear or branched alkylene group having 3 to 12 carbon atoms is still more preferable.

In the formulae, R^{P3} represents a hydrogen atom or a methyl group.

In the formulae, L^{P1} represents a single bond or an arylene group and L^{P2} represents a single bond or a divalent linking group. L^{P1} is preferably a single bond. Examples of the divalent linking group represented by L^{P2} include an alkylene group (preferably an alkylene group having 1 to 12 carbon atoms), an arylene group (preferably an arylene group having 6 to 20 carbon atoms), —NH—, —SO—, —SO₂—, —CO—, —C—, —COO—, —OCO—, —S—, —NHCO—, —CONH—, and a group formed by a combination of two or more these groups.

R^{P4} represents a hydrogen atom or a substituent. Examples of the substituent include a hydroxy group, a carboxyl group, an alkyl group, an aryl group, a heteroaryl group, an alkoxy group, an aryloxy group, a heteroaryloxy group, an alkylthioether group, an arylthioether group, a heteroarylthioether group, an ethylenically unsaturated bond-containing group, a cyclic ether group, and a blocked isocyanate group.

In addition, the polymer chain represented by P¹⁰ is more preferably a polymer chain having a repeating unit including an ethylenically unsaturated bond-containing group in the side chain. In addition, a proportion of the repeating unit including an ethylenically unsaturated bond-containing group in the side chain in all repeating units constituting P¹⁰ is preferably 5% by mass or more, more preferably 10% by mass or more, and still more preferably 20% by mass or more. The upper limit may be 100% by mass, and is preferably 90% by mass or less and still more preferably 60% by mass or less.

In addition, it is also preferable that the polymer chain represented by P¹⁰ has a repeating unit including an acid group. Examples of the acid group include a carboxyl group, a phosphoric acid group, a sulfo group, and a phenolic hydroxy group. According to this aspect, the dispersibility of the coloring material such as the pigment in the composition can be further improved. Further, the developability can be further improved, and the generation of development residue can be further suppressed. A proportion of the repeating unit including an acid group is preferably 1% to 30% by mass, more preferably 2% to 20% by mass, and still more preferably 3% to 10% by mass.

A weight-average molecular weight of the resin Ac is preferably 3000 to 35000. The upper limit is preferably 2500) or less, more preferably 20000 or less, and still more preferably 15000 or less. The lower limit is preferably 4000 or more, more preferably 6000 or more, and still more preferably 7000 or more.

An acid value of the resin Ac is preferably 5 to 200 mgKOH/g. The upper limit is preferably 150 mgKOH/g or less, more preferably 100 mgKOH/g or less, and still more preferably 80 mgKOH/g or less. The lower limit is preferably 10 mgKOH/g or more, more preferably 15 mgKOH/g or more, and still more preferably 20 mgKOH/g or more.

The resin preferably includes a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. In addition, the basic dispersant (basic resin) represents a resin in which the amount of the basic group is larger than the amount of the acid group.

The acidic dispersant (acidic resin) is preferably a resin in which the amount of the acid group is 70 mol % or more in a case where the total amount of the acid group and the basic group is 100 mol %. The acid group included in the acidic dispersant (acidic resin) is preferably a carboxyl group. An acid value of the acidic dispersant (acidic resin) is preferably 5 to 200 mgKOH/g. The upper limit is preferably 150 mgKOH/g or less, more preferably 100 mgKOH/g or less, and still more preferably 80 mgKOH/g or less. The lower limit is preferably 10 mgKOH/g or more, more preferably 15 mgKOH/b or more, and still more preferably 20 mgKOH/g or more.

The basic dispersant (basic resin) is preferably a resin in which the amount of the basic group is 60 mol % or more in a case where the total amount of the acid group and the basic group is 100 mol %. The basic group included in the basic dispersant is preferably an amino group. An amine value of the basic dispersant (basic resin) is preferably 5 to 100 mgKOH/g. The upper limit is preferably 80 mgKOH/g or less, more preferably 60 mgKOH/g or less, and still more preferably 45 mgKOH/g or less. The lower limit is preferably 10 mgKOH/g or more, more preferably 15 mgKOH/g or more, and still more preferably 20 mgKOH/g or more.

It is also preferable that the resin used as a dispersant is a graft resin. With regard to details of the graft resin, reference can be made to the description in paragraph Nos. 0025 to 0094 of JP2012-255128A, the contents of which are incorporated herein by reference.

It is also preferable that the resin used as a dispersant is a resin (resin Ac) having an aromatic carboxyl group. Examples of the resin having an aromatic carboxyl group include those described above.

It is also preferable that the resin used as a dispersant is a polyimine-based dispersant including a nitrogen atom in at least one of the main chain or the side chain. As the polyimine-based dispersant, a resin having a main chain which has a partial structure having a functional group of pKa 14 or less, and a side chain which has 40 to 10000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraph Nos. 0102 to 0166 of JP2012-255128A, the contents of which are incorporated herein by reference.

It is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A.

It is also preferable that the resin used as a dispersant are a resin including a repeating unit having an ethylenically unsaturated bond-containing group in the side chain. A content of the repeating unit having an ethylenically unsaturated bond-containing group in the side chain is preferably 10 mol % or more, more preferably 10 to 80 mol %, and still more preferably 20 to 70 mol % with respect to the total repeating units of the resin. In addition, as the dispersant, a resin described in JP2018-087939A can also be used.

A commercially available product is also available as the dispersant, and specific examples thereof include DISPERBYK series manufactured by BYK Chemie Japan, Solsperse series manufactured by Lubrizol Japan Ltd., Efka series manufactured by BASF SE, and AJISPER series manufactured by Ajinomoto Fine-Techno Co., Inc. In addition, products described in paragraph No. 0129 of JP2012-137564A and products described in paragraph No. 0235 of JP20t7-194662A can also be used as the dispersant.

In addition, as the resin used as a dispersant, block copolymers (EB-1) to (EB-9) described in paragraph Nos. 0219 to 0221 of JP6432077B can also be used.

A content of the resin in the total solid content of the photosensitive composition is preferably 1% to 80% by mass. The lower limit is preferably 5% by mass or more, more preferably 10% by mass or more, still more preferably 15% by mass or more, and particularly preferably 20% by mass or more. The upper limit is preferably 70% by mass or less, more preferably 60% by mass or less, still more preferably 50% by mass or less, and particularly preferably 40% by mass or less. The photosensitive composition according to the embodiment of the present invention may include one kind of resin or two or more kinds of resins. In a case of including two or more kinds of resins, it is preferable that the total amount thereof is within the above-described range.

<<Pigment Derivative>>

The photosensitive composition according to the embodiment of the present invention preferably contains a pigment derivative. Examples of the pigment derivative include a compound having a structure in which an acid group or a basic group is bonded to a coloring agent skeleton. Examples of the coloring agent skeleton constituting the pigment derivative include a quinoline coloring agent skeleton, a benzoimidazolone coloring agent skeleton, a benzoisoindole coloring agent skeleton, a benzothiazole coloring agent skeleton, an iminium coloring agent skeleton, a squarylium coloring agent skeleton, a croconium coloring agent skeleton, an oxonol coloring agent skeleton, a pyrrolopyrrole coloring agent skeleton, a diketopyrrolopyrrole coloring agent skeleton, an azo coloring agent skeleton, an azomethine coloring agent skeleton, a phthalocyanine coloring agent skeleton, a naphthalocyanine coloring agent skeleton, an anthraquinone coloring agent skeleton, a dianthraquinone coloring agent skeleton, a quinacridone coloring agent skeleton, a dioxazine coloring agent skeleton, a perinone coloring agent skeleton, a perylene coloring agent skeleton, a thiazine indigo coloring agent skeleton, a thioindigo coloring agent skeleton, an isoindrin coloring agent skeleton, a isoindolinone coloring agent skeleton, a quinophthalone coloring agent skeleton, an iminium coloring agent skeleton, a dithiol coloring agent skeleton, a triarylmethane coloring agent skeleton, and a pyrromethene coloring agent skeleton. Among these, a phthalocyanine pigment skeleton, a diketopyrrolopyrrole pigment skeleton, a benzoisoindole pigment skeleton, an anthraquinone pigment skeleton, a dianthraquinone pigment skeleton, a thiazineindigo pigment skeleton, an azo pigment skeleton, a quinophthalone pigment skeleton, or a quinacridone pigment skeleton is preferable, and a phthalocyanine pigment skeleton or a diketopyrrolopyrrole pigment skeleton is more preferable. That is, the pigment derivative is preferably a phthalocyanine compound or a diketopyrrolopyrrole compound. Examples of the acid group include a sulfo group, a carboxyl group, a phosphoric acid group, and a salt thereof. Examples of an atom or atomic group constituting the salts include alkali metal ions (Li⁺, Na⁺, K⁺, and the like), alkaline earth metal ions (Ca²⁺, Mg²⁺, and the like), an ammonium ion, an imidazolium ion, a pyridinium ion, and a phosphonium ion. Examples of the basic group included in the pigment derivative include an amino group, a pyridinyl group, or a salt thereof, a salt of an ammonium group, and a phthalimidomethyl group. Examples of an atom or atomic group constituting the salts include a hydroxide ion, a halogen ion, a carboxylate ion, a sulfonate ion, and a phenoxide ion.

As the pigment derivative, a pigment derivative having excellent visible transparency (hereinafter, also referred to as a transparent pigment derivative) can be contained. The maximum value (εmax) of a molar absorption coefficient of the transparent pigment derivative in a wavelength range of 400 to 700 nm is preferably 3000 L·mol⁻¹·cm⁻¹ or less, more preferably 1000 L·mol⁻¹·cm⁻¹ or less, and still more preferably 100 L·mol⁻¹·cm⁻¹ or less. The lower limit of εmax is, for example, 1 L·mol⁻¹·cm⁻¹ or more and may be 10 L·mol⁻¹·cm⁻¹ or more.

Specific examples of the pigment derivative include compounds described in Example described later and compounds described in JP1981-118462A (JP-S56-118462A), JP1988-264674A (JP-S63-264674A), JP1989-217077A (JP-H01-217077A). JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraph Nos. 0086 to 0098 of WO2011/024896A, paragraph Nos. 0063 to 0094 of WO2012/102399A, paragraph No. 0082 of WO2017/038252A, paragraph No. 0171 of JP2015-151530A, paragraph Nos. 0162 to 0183 of JP2011-252065A, JP2003-081972A, JP5299151B, JP2015-172732A, JP2014-199308A, JP2014-085562A, JP2014-035351A, and JP2008-081565A.

In a case of containing a pigment derivative, a content of the pigment derivative is preferably 1 to 30 parts by mass, more preferably 1 to 20 parts by mass, still more preferably 2 to 10 parts by mass, and particularly preferably 3 to 8 parts by mass with respect to 100 parts by mass of the pigment. The pigment derivative may be used singly or in a combination of two or more kinds thereof. In a case where two or more kinds thereof are used in combination, the total amount thereof is preferably within the above-described range.

<<Solvent>>

The photosensitive composition according to the embodiment of the present invention preferably contains a solvent. Examples of the solvent include an organic solvent. Basically, the type of the solvent is not particularly limited as long as it satisfies solubility of the respective components or coating properties of the photosensitive composition. Examples of the organic solvent include an ester-based solvent, a ketone-based solvent, an alcohol-based solvent, an amide-based solvent, an ether-based solvent, and a hydrocarbon-based solvent. The details of the organic solvent can be found in paragraph No. 0223 of WO2015/166779A, the content of which is incorporated herein by reference. In addition, an ester-based solvent in which a cyclic alkyl group is substituted or a ketone-based solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass parts per billion (ppb) or less. Optionally, an organic solvent having a metal content at a mass parts per trillion (ppt) level may be used. For example, such an organic solvent is available from Toyo Gosei Co., Ltd. (The Chemical Daily, Nov. 13, 2015).

Examples of a method for removing impurities such as a metal from the organic solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The organic solvent may include an isomer (a compound having the same number of atoms and a different structure). In addition, only one kind of isomers may be included, or a plurality of isomers may be included.

The organic solvent preferably has the content of peroxides of 0.8 mmol/L or less, and more preferably, the organic solvent does not substantially include peroxides.

A content of the solvent in the photosensitive composition is preferably 10% to 95% by mass, more preferably 20% to 90% by mass, and still more preferably 30% to 90% by mass.

In addition, from the viewpoint of environmental regulation, it is preferable that the photosensitive composition according to the embodiment of the present invention does not substantially contain environmentally regulated substances. In the present invention, the description “does not substantially contain environmentally regulated substances” means that the content of the environmentally regulated substances in the photosensitive composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of CHemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the photosensitive composition, and may be incorporated into the photosensitive composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, photosensitive composition produced by mixing these compounds, or the like.

<<Compound Having Cyclic Ether Group>>

The photosensitive composition according to the embodiment of the present invention can contain a compound having a cyclic ether group. Examples of the cyclic ether group include an epoxy group and an oxetanyl group. It is preferable that the compound having a cyclic ether group is a compound having an epoxy group (hereinafter, also referred to as an “epoxy compound”). As the epoxy compound, the compounds described in paragraph Nos. 0034 to 0036 of JP2013-011869A, paragraph Nos. 0147 to 0156 of JP2014-043556A, and paragraph Nos. 0085 to 0092 of JP2014-089408A, and the compounds described in JP2017-179172A can also be used. The contents of the publications are incorporated herein by reference.

The epoxy compound may be a low-molecular-weight compound (for example, having a molecular weight of less than 2000, and further, a molecular weight of less than 1000) or a high-molecular-weight compound (macromolecule) (for example, having a molecular weight of 1000 or more, and in a case of a polymer, having a weight-average molecular weight of 1000 or more). A weight-average molecular weight of the epoxy compound is preferably 200 to 100000 and more preferably 500 to 50000. The upper limit of the weight-average molecular weight is preferably 10000 or less, more preferably 5000 or less, and still more preferably 3000 or less.

As the epoxy compound, an epoxy resin can be preferably used. Examples of the epoxy resin include an epoxy resin which is a glycidyl etherified product of a phenol compound, an epoxy resin which is a glycidyl etherified product of various novolac resins, an alicyclic epoxy resin, an aliphatic epoxy resin, a heterocyclic epoxy resin, a glycidyl ester-based epoxy resin, a glycidyl amine-based epoxy resin, an epoxy resin obtained by glycidylating halogenated phenols, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3300 g/eq, more preferably 310 to 1700 g/eq, and still more preferably 310 to 1000 g/eq.

Examples of a commercially available product of the compound having a cyclic ether group include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-10105, G-2050M, G-01100, and G-01758 (all of which are manufactured by NOF Corporation, an epoxy group-containing polymer).

A content of the compound having a cyclic ether group in the total solid content of the photosensitive composition is preferably 0.1% to 20% by mass. The lower limit is, for example, preferably 0.5% by mass or more and more preferably 1% by mass or more. The upper limit is, for example, preferably 15% by mass or less and still more preferably 10% by mass or less. The compound having a cyclic ether group may be used singly or in a combination of two or more kinds thereof. In a case of using two or more kinds thereof, the total amount thereof is preferably within the above-described range.

<<Curing Accelerator>>

The photosensitive composition according to the embodiment of the present invention may contain a curing accelerator. Examples of the curing accelerator include a thiol compound, a methylol compound, an amine compound, a phosphonium salt compound, an amidine salt compound, an amide compound, a base generator, an isocyanate compound, an alkoxysilane compound, and an onium salt compound. Specific examples of the curing accelerator include compounds described in paragraph Nos. 0094 to 0097 of WO2018/056189A, compounds described in paragraph Nos. 0246 to 0253 of JP2015-034963A, compounds described in paragraph Nos. 0186 to 0251 of JP2013-041165A, ionic compounds described in JP2014-055114A, compounds described in paragraph Nos. 0071 to 008 of JP2012-150180A, alkoxysilane compounds having an epoxy group described in JP2011-253054A, compounds described in paragraph Nos. 0085 to 0092 of JP5765059B, and carboxyl group-containing epoxy curing agent described in JP2017-036379A. In a case of containing a curing accelerator, a content of the curing accelerator in the total solid content of the photosensitive composition is preferably 0.3% to 8.9% by mass and more preferably 0.8% to 6.4% by mass.

<<Ultraviolet Absorber>>

The photosensitive composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. Examples of such a compound include compounds described in paragraph Nos. 0038 to 0052 of JP2009-217221A, paragraph Nos. 0052 to 0072 of JP2012-208374A, paragraph Nos. 0317 to 0334 of JP2013-068814A, and paragraph Nos. 0061 to 0080 of JP2016-162946A, the contents of which are incorporated herein by reference. Specific examples of the ultraviolet absorber include a compound having the following structures. Examples of a commercially available product of the ultraviolet absorber include UV-503 (manufactured by Daito Chemical Co., Ltd). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraph Nos. 0049 to 0059 of JP6268967B can also be used.

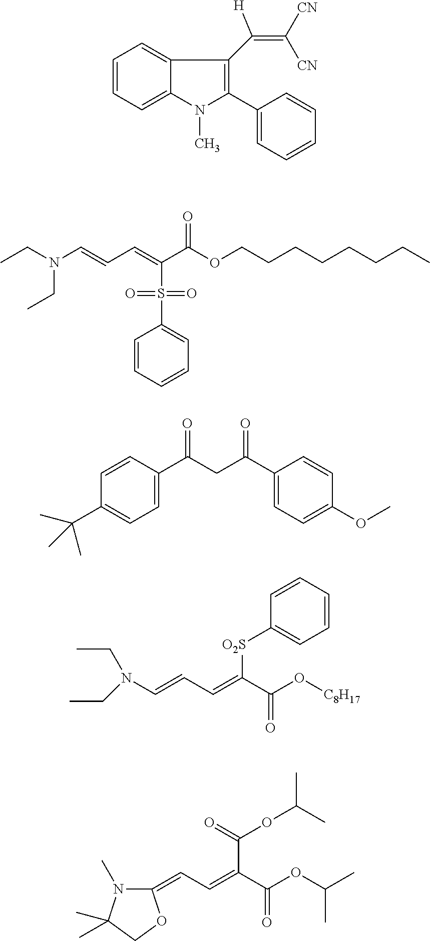

In a case of containing an ultraviolet absorber, a content of the ultraviolet absorber in the total solid content of the photosensitive composition is preferably 0.01% to 10% by mass and more preferably 0.01% to 5% by mass. In the present invention, the ultraviolet absorber may be used singly or in a combination of two or more kinds thereof. In a case of using two or more kinds thereof, the total amount thereof is preferably within the above-described range.

<<Polymerization Inhibitor>>

The photosensitive composition according to the embodiment of the present invention can contain a polymerization inhibitor. Examples of the polymerization inhibitor include hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, p-methoxyphenol is preferable. In a case of containing a polymerization inhibitor, a content of the polymerization inhibitor in the total solid content of the photosensitive composition is preferably 0.0001% to 5% by mass.

The polymerization inhibitor may be used singly or in a combination of two or more kinds thereof. In a case of two or more kinds thereof, the total amount thereof is preferably within the above-described range.

<<Silane Coupling Agent>>

The photosensitive composition according to the embodiment of the present invention can contain a silane coupling agent. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include N-β-aminoethyl-γ-aminopropyl methyldimethoxysilane (trade name: KBM-602, manufactured by Shin-Etsu Chemical Co., Ltd.), N-β-aminoethyl-γ-aminopropyl trimethoxysilane (trade name: KBM-603, manufactured by Shin-Etsu Chemical Co., Ltd.). N-β-aminoethyl-γ-aminopropyl triethoxysilane (trade name: KBE-602, manufactured by Shin-Etsu Chemical Co., Ltd.), γ-aminopropyl trimethoxysilane (trade name: KBM-903, manufactured by Shin-Etsu Chemical Co., Ltd.), γ-aminopropyl triethoxysilane (trade name: KBE-903, manufactured by Shin-Etsu Chemical Co., Ltd.), 3-methacryloxypropylmethyl dimethoxysilane (trade name: KBM-502, manufactured by Shin-Etsu Chemical Co., Ltd.), and 3-methacryloxypropyl trimethoxysilane (trade name: KBM-503, manufactured by Shin-Etsu Chemical Co., Ltd.). In addition, specific examples of the silane coupling agent include the compounds described in paragraph Nos. 0018 to 0036 of JP2009-288703A and the compounds described in paragraph Nos. 0056 to 0066 of JP2009-242604A, the contents of which are incorporated herein by reference. In a case of containing a silane coupling agent, a content of the silane coupling agent in the total solid content of the photosensitive composition is preferably 0.01% to 15.0% by mass and more preferably 0.05% to 10.0% by mass. The silane coupling agent may be used singly or in a combination of two or more kinds thereof. In a case of two or more kinds thereof, the total amount thereof is preferably within the above-described range.

<<Surfactant>>

The photosensitive composition according to the embodiment of the present invention can contain a surfactant. As the surfactant, various surfactants such as a fluorine-based surfactant, a nonionic surfactant, a cationic surfactant, an anionic surfactant, and a silicone-based surfactant can be used. Examples of the surfactant include surfactants described in paragraph Nos. 0238 to 0245 of WO2015/166779A, the contents of which are incorporated herein by reference.

It is preferable that the surfactant is a fluorine-based surfactant. By containing a fluorine-based surfactant in the photosensitive composition, liquid characteristics (particularly, fluidity) are further improved, and liquid saving properties can be further improved. In addition, it is possible to form a film with a small thickness unevenness.

A fluorine content in the fluorine-based surfactant is suitably 3% to 40% by mass, and more preferably 5% to 30% by mass and particularly preferably 7% to 25% by mass. The fluorine-based surfactant in which the fluorine content is within the above-described range is effective in terms of the evenness of the thickness of the coating film or liquid saving properties and the solubility of the surfactant in the photosensitive composition is also good.

Examples of the fluorine-based surfactant include surfactants described in paragraph Nos. 0060 to 0064 of JP2014-041318A (paragraph Nos. 0060 to 0064 of the corresponding WO2014/017669A) and the like, and surfactants described in paragraph Nos. 0117 to 0132 of JP2011-132503A, the contents of which are incorporated herein by reference. Examples of a commercially available product of the fluorine-based surfactant include: MEGAFACE F171, F172, F173, F176, F177, F141, F142, F143, F144, R30, F437, F475, F479, F482, F554, F780, EXP, and MFS-330 (all of which are manufactured by DIC Corporation); FLUORAD FC430, FC431, and FC171 (all of which are manufactured by Sumitomo 3M Ltd.), SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine-based surfactant, an acrylic compound, which has a molecular structure having a functional group containing a fluorine atom and in which, by applying heat to the molecular structure, the functional group containing a fluorine atom is broken to volatilize a fluorine atom, can also be suitably used. Examples of such a fluorine-based surfactant include MEGAFACE DS series manufactured by DIC Corporation (The Chemical Daily, Feb. 22, 2016; Nikkei Business Daily, Feb. 23, 2016) such as MEGAFACE DS-21.

In addition, it is also preferable that a polymer of a fluorine atom-containing vinyl ether compound having a fluorinated alkyl group or a fluorinated alkylene ether group, and a hydrophilic vinyl ether compound is used as the fluorine-based surfactant. Examples of such a fluorine-based surfactant include fluorine-based surfactants described in JP2016-216602A, the contents of which are incorporated herein by reference.

A block polymer can also be used as the fluorine-based surfactant. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraph Nos. 0016 to 0037 of JP2010-032698A, or the following compounds are also exemplified as the fluorine-based surfactant used in the present invention.

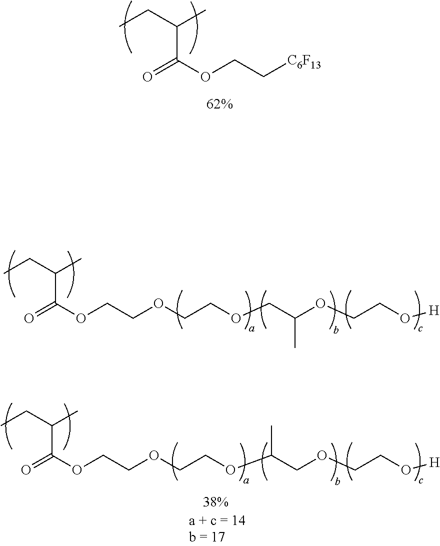

A weight-average molecular weight of the compound is preferably 3000) to 50000 and, for example, 14000. In the compound. “%” representing the proportion of a repeating unit is mol %.

In addition, as the fluorine-based surfactant, a fluorine-containing polymer having an ethylenically unsaturated bond-containing group in the side chain can be used. Specific examples thereof include compounds described in paragraph Nos. 0050 to 0090 and paragraph Nos. 0289 to 0295 of JP2010-1649A, and MEGAFACE RS-101, RS-102, RS-718K, and RS-72-K manufactured by DIC Corporation. In addition, as the fluorine-based surfactant, compounds described in paragraph Nos. 0015 to 0158 of JP2015-117327A can also be used.

Examples of the nonionic surfactant include glycerol, trimethylolpropane, trimethylolethane, an ethoxylate and propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF SE), TETRONIC 304, 701, 704, 901, 904, and 150R1 (manufactured by BASF SE). SOLSPERSE 20000 (manufactured by Lubrizol Japan Ltd.), NCW-101, NCW-1001, and NCW-1002 (all of which are manufactured by FUJIFILM Wako Pure Chemical Corporation), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicone-based surfactant include TORAY SILICONE DC3PA, TORAY SILICONE SH7PA, TORAY SILICONE DC11PA, TORAY SILICONE SH121PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP-341, KF-6001, and KF-6002 (all of which are manufactured by Shin-Etsu Chemical Co., Ltd.), and BYK307, BYK323, and BYK330 (all of which are manufactured by BYK Chemie).

In a case of containing a surfactant, a content of the surfactant in the total solid content of the photosensitive composition is preferably 0.001% to 5.0% by mass and more preferably 0.005% to 3.0% by mass. The surfactant may be used singly or in a combination of two or more kinds thereof. In a case of two or more kinds thereof, the total amount thereof is preferably within the above-described range.

<<Antioxidant>>

The photosensitive composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitably used. A content of the antioxidant in the total solid content of the photosensitive composition is preferably 0.01% to 20% by mass and more preferably 0.3% to 15% by mass. In a case of containing the antioxidant, the antioxidant may be used singly or in a combination of two or more kinds thereof. In a case of using two or more kinds thereof, the total amount thereof is preferably within the above-described range.

<<Other Components>>

Optionally, the photosensitive composition according to the embodiment of the present invention may further contain a sensitizer, a curing accelerator, a filler, a thermal curing accelerator, a plasticizer, and other auxiliary agents (for example, conductive particles, a filler, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraph No. 0183 of JP2012-003225A (corresponding to paragraph No. 0237 of US2013/0034812A) and paragraph Nos. 0101 to 0104 and 0107 to 0109 of JP2008-250074A, the contents of which are incorporated herein by reference. In addition, as desired, the photosensitive composition according to the embodiment of the present invention may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include compounds described in WO2014/021023A, WO2017/030005A, and JP2017-008219A. Examples of a commercially available product of the potential antioxidant include ADEKA ARKLS GPA-5001 (manufactured by ADEKA Corporation). In addition, as described in JP2018-155881A, C. I. Pigment Yellow 129 may be added for the purpose of improving weather fastness.

In order to adjust the refractive index of a film to be obtained, the photosensitive composition according to the embodiment of the present invention may contain a metal oxide. Examples of the metal oxide include TiO₂, ZrO₂, AlO₃, and SiO₂. The primary particle diameter of the metal oxide is preferably 1 to 100 nm, more preferably 3 to 70 nm, and still more preferably 5 to 50 nm. The metal oxide may have a core-shell structure. In addition, in this case, the core portion may be hollow.

The photosensitive composition according to the embodiment of the present invention may include a light-resistance improver. Examples of the light-resistance improver include the compounds described in paragraph Nos. 0036 and 0037 of JP2017-198787A, the compounds described in paragraph Nos. 0029 to 0034 of JP2017-146350A, the compounds described in paragraph Nos. 0036 and 0037, and 0049 to 0052 of JP2017-129774A, the compounds described in paragraph Nos. 0031 to 0034 and 0058 and 0059 of JP2017-129674A, the compounds described in paragraph Nos. 0036 and 0037, and 0051 to 0054 of JP2017-122803A, the compounds described in paragraph Nos. 0025 to 0039 of WO2017/164127A, the compounds described in paragraph Nos. 0034 to 0047 of JP2017-186546A, the compounds described in paragraph Nos. 0019 to 0041 of JP2015-025116A, the compounds described in paragraph Nos. 0101 to 0125 of JP2012-145604A, the compounds described in paragraph Nos. 0018 to 0021 of JP2012-103475A, the compounds described in paragraph Nos. 0015 to 0018 of JP2011-257591A, the compounds described in paragraph Nos. 0017 to 0021 of JP2011-191483A, the compounds described in paragraph Nos. 0108 to 0116 of JP2011-145668A, and the compounds described in paragraph Nos. 0103 to 0153 of JP2011-253174A.

A moisture content in the photosensitive composition according to the embodiment of the present invention is usually 3% by mass or less, preferably 0.01% to 1.5% by mass and more preferably in a range of 0.1% to 1.0% by mass. The moisture content can be measured by a Karl Fischer method.

The photosensitive composition according to the embodiment of the present invention can be used after viscosity is adjusted for the purposes of adjusting the state of a film surface (flatness or the like), adjusting a film thickness, or the like. The value of the viscosity can be appropriately selected as desired, and is, for example, preferably 0.3 mPa·s to 50 mPa·s, and more preferably 0.5 mPa·s to 20 mPa·s at 25° C. As for a method for measuring the viscosity, the viscosity can be measured, for example, with a temperature being adjusted to 25° C., using a cone plate-type viscometer.

A storage container for the photosensitive composition according to the embodiment of the present invention is not particularly limited, and a known storage container can be used. In addition, as the storage container, it is also preferable to use a multilayer bottle having an interior wall constituted with six layers from six kinds of resins or a bottle having a 7-layer structure from 6 kinds of resins for the purpose of suppressing infiltration of impurities into raw materials or compositions. Examples of such a container include the containers described in JP2015-123351A.

<Method for Preparing Photosensitive Composition>

The photosensitive composition according to the embodiment of the present invention can be prepared by mixing the above-described components with each other. In the preparation of the photosensitive composition, all the components may be dissolved and/or dispersed at the same time in a solvent to prepare the photosensitive composition, or the respective components may be appropriately left in two or more solutions or dispersion liquids and mixed to prepare the photosensitive composition upon use (during coating), as desired.

In addition, in the preparation of the photosensitive composition, a process for dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph No. 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

It is preferable that, in the preparation of the photosensitive composition, the photosensitive composition is filtered through a filter for the purpose of removing foreign matters, reducing defects, or the like. As the filter, any filters that have been used in the related art for filtration use and the like may be used without particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including a high-density polypropylene) and nylon are preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Toyo Roshi Kaisha., Ltd., Nihon Entegris K.K. (formerly Nippon Microlith Co., Ltd.), Kitz Micro Filter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd. In a case of using a filter, different filters (for example, a first filter, a second filter, and the like) may be combined. In this case, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed.

<Film>

A film according to an embodiment of the present invention is a film obtained from the above-described photosensitive composition according to the embodiment of the present invention. The film according to the embodiment of the present invention can be used for an optical filter such as a color filter or an infrared transmitting filter.

A thickness of the film according to the embodiment of the present invention can be adjusted according to the purpose. For example, the film thickness is preferably 5 μm or less, more preferably 1 μm or less, and still more preferably 0.6 μm or less. The lower limit of the film thickness is preferably 0.1 μm or more, more preferably 0.2 μm or more, and still more preferably 0.3 μm or more.

In a case where the film according to the embodiment of the present invention is used as a color filter, the film according to the embodiment of the present invention preferably has a hue of green, red, blue, cyan, magenta, or yellow. In addition, the film according to the embodiment of the present invention can be preferably used as a colored pixel of a color filter. Examples of the colored pixel include a red pixel, a blue pixel, a green pixel, a yellow pixel, a cyan pixel, and a magenta pixel.

In a case where the film according to the embodiment of the present invention is used as an infrared transmitting filter, it is preferable that the film according to the embodiment of the present invention has, for example, any one of the following spectral characteristics (1) to (4).

(1): maximum value of a light transmittance of the film in a thickness direction in a wavelength range of 400 to 640 nm is 20% or less (preferably 15% or less and more preferably 10% or less) and the minimum value of a light transmittance of the film in the thickness direction in a wavelength range of 800 to 1300 nm is 70% or more (preferably 75% or more and more preferably 80% or more). A film having such spectral characteristics can shield light having a wavelength range of 400 to 640 nm, and can transmit light having a wavelength exceeding 700 nm.

(2): film in which the maximum value of a light transmittance of the film in a thickness direction in a wavelength range of 400 to 750 nm is 20% or less (preferably 15% or less and more preferably 10% or less) and the minimum value of a light transmittance of the film in the thickness direction in a wavelength range of 900 to 1300 nm is 70% or more (preferably 75% or more and more preferably 80% or more). A film having such spectral characteristics can shield light having a wavelength range of 400 to 750 nm, and can transmit light having a wavelength exceeding 850 nm.

(3): film in which the maximum value of a light transmittance of the film in a thickness direction in a wavelength range of 400 to 830 nm is 20% or less (preferably 15% or less and more preferably 10% or less) and the minimum value of a light transmittance of the film in the thickness direction in a wavelength range of 1000 to 1300 nm is 70% or more (preferably 75% or more and more preferably 80% or more). A film having such spectral characteristics can shield light having a wavelength range of 400 to 830 nm, and can transmit light having a wavelength exceeding 940 nm.

(4): film in which the maximum value of a light transmittance of the film in a thickness direction in a wavelength range of 400 to 950 nm is 20% or less (preferably 15% or less and more preferably 10% or less) and the minimum value of a light transmittance of the film in the thickness direction in a wavelength range of 1100 to 1300 nm is 70% or more (preferably 75% or more and more preferably 80% or more). A film having such spectral characteristics can shield light having a wavelength range of 400 to 950 nm, and can transmit light having a wavelength exceeding 1040 nm.

<Method for Forming Pixel>

Next, a method for forming a pixel will be described. The method for forming a pixel preferably includes a step of applying the above-described photosensitive composition according to the embodiment of the present invention to a support to form a photosensitive composition layer, a step of exposing the photosensitive composition layer in a patterned manner, and a step of removing a non-exposed portion of the photosensitive composition layer after exposure by development. Hereinafter, the respective steps will be described.

In the step of forming a photosensitive composition layer, the photosensitive composition is applied to a support to form the photosensitive composition layer. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, a base layer may be provided on the silicon substrate so as to improve adhesiveness to an upper layer, prevent the diffusion of materials, or planarize the surface of the substrate. A surface contact angle of the base layer is preferably 20° to 70° in a case of being measured with diiodomethane. In addition, the surface contact angle of the base layer is preferably 30° to 80° in a case of being measured with water. In a case where the surface contact angle of the base layer is within the above-described range, coating property of the photosensitive composition is good. The surface contact angle of the base layer can be adjusted by, for example, adding a surfactant.

As a method of applying the photosensitive composition, a known method can be used. Examples thereof include a dropping method (drop casting); a slit coating method; a spray method; a roll coating method; a spin coating method; a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprinting method. A method for applying the ink jet is not particularly limited, and examples thereof include a method described in “Extension of Use of Ink Jet—Infinite Possibilities in Patent—” (February, 2005, S. B. Research Co., Ltd.) (particularly pp. 115 to 133) and methods described in JP2003-262716A, JP2003-185831A, JP2003-261827A, JP2012-126830A, and JP2006-169325A. In addition, with regard to the method for applying the photosensitive composition, reference can be made to the description in WO2017/030174A and WO2017/018419A, the contents of which are incorporated herein by reference.

The photosensitive composition layer formed on the support may be dried (pre-baked). In a case of producing a film by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 to 300 seconds, more preferably 40 to 250 seconds, and still more preferably 80 to 220 seconds. The pre-baking can be performed using a hot plate, an oven, or the like.

Next, the photosensitive composition layer is exposed in a patterned manner (exposing step). For example, the photosensitive composition layer can be exposed in a patterned manner using a stepper exposure device or a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the photosensitive composition layer may be irradiated with light continuously to expose the photosensitive composition layer, or the photosensitive composition layer may be irradiated with light in a pulse to expose the photosensitive composition layer (pulse exposure). The pulse exposure refers to an exposing method in which light irradiation and resting are repeatedly performed in a short cycle (for example, millisecond-level or less).

The irradiation amount (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, a non-exposed portion of the photosensitive composition layer after exposure is removed by development (developing step). The removal of the non-exposed portion of the photosensitive composition layer by development can be carried out using a developer. Thus, the photosensitive composition layer of the non-exposed portion is eluted into the developer, and as a result, only a photocured portion remains. The temperature of the developer is preferably, for example, 20° C. to 30° C. The development time is preferably 20 to 180 seconds. In addition, in order to improve residue removing properties, a step of removing the developer by shaking off per 60 seconds and supplying a fresh developer may be repeated multiple times.

Examples of the developer include an organic solvent and an alkali developer, and an alkali developer is preferably used. As the alkali developer, an alkaline aqueous solution (alkali developer) in which an alkaline agent is diluted with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo-[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the alkaline aqueous solution is preferably 0.001% to 10% by mass and more preferably 0.01% to 1% by mass. In addition, the developer may further contain a surfactant. From the viewpoint of transportation, storage, and the like, the developer may be first produced as a concentrated solution and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the photosensitive composition layer after development while rotating the support on which the photosensitive composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film (pixel) after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR 10-2017-0122130A.

<Optical Filter>

An optical filter according to an embodiment of the present invention has the above-described film according to the embodiment of the present invention. Examples of the type of the optical filter include a color filter and an infrared transmitting filter, and a color filter is preferable. As the color filter, it is preferable to have the film according to the embodiment of the present invention as a colored pixel of the color filter.

Examples of one aspect of the color filter include a color filter which has at least a red pixel, a green pixel, and a blue pixel and in which at least one colored pixel of a red pixel, a green pixel, or a blue pixel is constituted of the film according to the embodiment of the present invention.

Examples of another aspect of the color filter include a color filter which has at least a cyan pixel, a magenta pixel, and a yellow pixel and in which at least one colored pixel of a cyan pixel, a magenta pixel, or a yellow pixel is constituted of the film according to the embodiment of the present invention.

The color filter can be used for a solid-state imaging element such as a charge coupled device (CCD) and a complementary metal-oxide semiconductor (CMOS), an image display device, or the like.

In the optical filter, a thickness of the film according to the embodiment of the present invention can be appropriately adjusted depending on the purposes. The film thickness is preferably 5 μm or less, more preferably 1 μm or less, and still more preferably 0.6 μm or less. The lower limit of the film thickness is preferably 0.1 μm or more, more preferably 0.2 μm or more, and still more preferably 0.3 μm or more.

A width of the pixel included in the optical filter is preferably 0.4 to 10.0 μm. The lower limit is preferably 0.4 μm or more, more preferably 0.5 μm or more, and still more preferably 0.6 μm or more. The upper limit is preferably 5.0 μm or less, more preferably 2.0 μm or less, still more preferably 1.0 μm or less, and even more preferably 0.8 μm or less. In addition, a Young's modulus of the pixel is preferably 0.5 to 20 GPa and more preferably 2.5 to 15 GPa.

Each pixel included in the optical filter preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments. Inc. In addition, the contact angle of water on the pixel can be appropriately set to a preferred value and is typically in the range of 50° to 110°. The contact angle can be measured, for example, using a contact angle meter CV-DT-A Model (manufactured by Kyowa Interface Science Co., Ltd.). In addition, it is preferable that the volume resistivity value of the pixel is high. Specifically, the volume resistivity value of the pixel is preferably 10⁹ f-cm or more and more preferably 10¹¹ Ω·cm or more. The upper limit is not specified, but is, for example, preferably 10¹⁴ Ω·cm or less. The volume resistivity value of the pixel can be measured, for example, using an ultra-high resistance meter 5410 (manufactured by Advantest Corporation).

In the optical filter, a protective layer may be provided on the surface of the film (pixel) according to the embodiment of the present invention. By providing the protective layer, various functions such as oxygen shielding, low reflection, hydrophilicity/hydrophobicity, and shielding of light (ultraviolet rays, near infrared rays, and the like) having a specific wavelength can be imparted. The thickness of the protective layer is preferably 0.01 to 10 μm and more preferably 0.1 to 5 μm. Examples of a method for forming the protective layer include a method of forming the protective layer by applying a resin composition dissolved in an organic solvent, a chemical vapor deposition method, and a method of attaching a molded resin with an adhesive material. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polyacrylonitrile resin, a cellulose resin, Si, C. W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an ink jet method can be used. As the organic solvent included in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic fine particles, an absorber of light (for example, ultraviolet rays, near infrared rays, and the like) having a specific wavelength, a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of light having a specific wavelength, a known absorber can be used. The content of these additives can be appropriately adjusted, but is preferably 0.1% to 70% by mass and still more preferably 1% to 60% by mass with respect to the total mass of the protective layer.

In addition, as the protective layer, the protective layers described in paragraph Nos. 0073 to 0092 of JP2017-151176A can also be used.

The optical filter may have a structure in which each pixel is embedded in a space partitioned in, for example, a lattice form by a partition wall.

<Solid-State Imaging Element>

A solid-state imaging element according to an embodiment of the present invention has the film according to the embodiment of the present invention. The configuration of the solid-state imaging element is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes: have a device-protective film formed of silicon nitride or the like, which is formed to coat the entire surface of the light-shielding film and the light receiving section of the photodiodes, on the light-shielding film; and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice shape by a partition wall. The partition wall in this case preferably has a low refractive index for each colored pixel. Examples of an imaging device having such a structure include the devices described in JP2012-227478A, JP2014-179577A, and WO2018/043654A. An imaging device including the solid-state imaging element according to the embodiment of the present invention can also be used as a vehicle camera or a surveillance camera, in addition to a digital camera or electronic apparatus (mobile phones or the like) having an imaging function.

<Image Display Device>

An image display device according to an embodiment of the present invention has the film according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device to which the present invention can be applied is not particularly limited, and can be applied to, for example, liquid crystal display devices employing various systems described in the “Liquid Crystal Display Technology for Next Generation”.

### EXAMPLES

Hereinafter, the present invention will be described in more detail with reference to the examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention is not limited to the specific examples shown below.

<Production of Dispersion Liquid>

Raw materials described in the following table were mixed, and then 230 parts by mass of zirconia beads having a diameter of 0.3 mm were added thereto to perform a dispersion treatment for 5 hours using a paint shaker. The beads were separated by filtration, and a dispersion liquid was produced. The numerical value of the blending amount of each material in the tables below is parts by mass. A value of the blending amount of the resin (dispersant) is the value of the blending amount in the resin solution having a solid content of 20% by mass.

TABLE 1

| | | | | | | | Pigment | | | | | | Coloring | Concen- |
|---|---|---|---|---|---|---|---|---|---|---|---|---|---|---|
| | Coloring material | | | | | | derivative | | Resin | | Solvent | | material | tration |
| | | Part | | Part | | Part | | Part | | Part | | Part | concen- | of solid |
| Dispersion | | by | | by | | by | | by | | by | | by | tration | contents |
| liquid | Type | mass | Type | mass | Type | mass | Type | mass | Type | mass | Type | mass | (% by mass) | (% by mass) |
| Dispersion | PR254 | 14 | | | | | Derivative 4 | 1 | B-3 | 25 | K-1 | 60 | 14 | 20 |
| liquid R1 | | | | | | | | | | | | | | |
| Dispersion | PR264 | 14 | | | | | Derivative 4 | 1 | B-3 | 25 | K-1 | 60 | 14 | 20 |
| liquid R2 | | | | | | | | | | | | | | |
| Dispersion | PR269 | 14 | | | | | Derivative 4 | 1 | B-3 | 25 | K-1 | 60 | 14 | 20 |
| liquid R3 | | | | | | | | | | | | | | |
| Dispersion | PR272 | 14 | | | | | Derivative 4 | 1 | B-3 | 25 | K-1 | 60 | 14 | 20 |
| liquid R4 | | | | | | | | | | | | | | |
| Dispersion | PR254 | 10 | PY139 | 4 | | | Derivative 4 | 1 | B-3 | 25 | K-1 | 60 | 14 | 20 |
| liquid R5 | | | | | | | | | | | | | | |
| Dispersion | PR264 | 10 | PY139 | 4 | | | Derivative 4 | 1 | B-3 | 25 | K-1 | 60 | 14 | 20 |
| liquid R6 | | | | | | | | | | | | | | |
| Dispersion | PR269 | 10 | PY139 | 4 | | | Derivative 4 | 1 | B-3 | 25 | K-1 | 60 | 14 | 20 |
| liquid R7 | | | | | | | | | | | | | | |
| Dispersion | PR272 | 10 | PY139 | 4 | | | Derivative 4 | 1 | B-3 | 25 | K-1 | 60 | 14 | 20 |
| liquid R8 | | | | | | | | | | | | | | |
| Dispersion | PR269 | 10 | PY139 | 2 | PO71 | 2 | Derivative 4 | 1 | B-3 | 25 | K-1 | 60 | 14 | 20 |
| liquid R9 | | | | | | | | | | | | | | |
| Dispersion | PR254 | 5 | PR [symbol] 72 | 6 | PY139 | 4 | Derivative 4 | 1 | B-3 | 25 | K-1 | 60 | 14 | 20 |
| liquid R10 | | | | | | | | | | | | | | |
| Dispersion | PR254 | 10 | PY139 | 4 | | | Derivative 1 | 1 | B-3 | 25 | K-1 | 60 | 14 | 20 |
| liquid R11 | | | | | | | | | | | | | | |
| Dispersion | PR254 | 10 | PY139 | 4 | | | Derivative 2 | 1 | B-3 | 25 | K-1 | 60 | 14 | 20 |
| liquid R12 | | | | | | | | | | | | | | |
| Dispersion | PR254 | 10 | PY139 | 4 | | | Derivative 3 | 1 | B-3 | 25 | K-1 | 60 | 14 | 20 |
| liquid R13 | | | | | | | | | | | | | | |
| Dispersion | PR254 | 10 | PY139 | 4 | | | Derivative 6 | 1 | B-3 | 25 | K-1 | 60 | 14 | 20 |
| liquid R14 | | | | | | | | | | | | | | |
| Dispersion | PR254 | 10 | PY139 | 4 | | | Derivative 4 | 1 | A-1 | 25 | K-1 | 60 | 14 | 20 |
| liquid R15 | | | | | | | | | | | | | | |
| Dispersion | PR254 | 10 | PY139 | 4 | | | Derivative 4 | 1 | A-2 | 25 | K-1 | 60 | 14 | 20 |
| liquid R16 | | | | | | | | | | | | | | |
| Dispersion | PR254 | 10 | PY139 | 4 | | | Derivative 4 | 1 | B-1 | 25 | K-1 | 60 | 14 | 20 |
| liquid R17 | | | | | | | | | | | | | | |
| Dispersion | PR254 | 10 | PY139 | 4 | | | Derivative 4 | 1 | B-2 | 25 | K-1 | 60 | 14 | 20 |
| liquid R18 | | | | | | | | | | | | | | |
| Dispersion | PR254 | 10 | PY139 | 4 | | | Derivative 4 | 1 | B-3 | 25 | K-1 | 60 | 14 | 20 |
| liquid R19 | | | | | | | | | | | | | | |
| Dispersion | PR254 | 10 | PY139 | 4 | | | Derivative 4 | 1 | B-4 | 25 | K-1 | 60 | 14 | 20 |
| liquid R20 | | | | | | | | | | | | | | |
| Dispersion | PR254 | 10 | PY139 | 4 | | | Derivative 4 | 1 | B-5 | 25 | K-1 | 60 | 14 | [symbol] 0 |
| liquid R21 | | | | | | | | | | | | | | |
| Dispersion | PR254 | 10 | PY139 | 4 | | | Derivative 4 | 1 | B-6 | 25 | K-1 | 60 | 14 | 20 |
| liquid R22 | | | | | | | | | | | | | | |
| Dispersion | PR254 | 10 | PY139 | 4 | | | Derivative 4 | 1 | B-7 | 25 | K-1 | 60 | 14 | 20 |
| liquid R23 | | | | | | | | | | | | | | |

[symbol]

indicates data missing or illegible when filed

TABLE 2

| | | | | | | | Pigment | | | | | | Coloring | Concen- |
|---|---|---|---|---|---|---|---|---|---|---|---|---|---|---|
| | Coloring material | | | | | | derivative | | Resin | | Solvent | | material | tration |
| | | Part | | Part | | Part | | Part | | Part | | Part | concen- | of solid |
| Dispersion | | by | | by | | by | | by | | by | | by | tration | contents |
| liquid | Type | mass | Type | mass | Type | mass | Type | mass | Type | mass | Type | mass | (% by mass) | (% by mass) |
| Dispersion | PG7 | 10 | PY185 | 4 | | | Derivative 2 | 1 | B-3 | 25 | K-1 | 60 | 14 | 20 |
| liquid G1 | | | | | | | | | | | | | | |
| Dispersion | PG36 | 10 | PY185 | 4 | | | Derivative 2 | 1 | B-3 | 25 | K-1 | 60 | 14 | 20 |
| liquid G2 | | | | | | | | | | | | | | |
| Dispersion | PG58 | 10 | PY185 | 4 | | | Derivative 2 | 1 | B-3 | 25 | K-1 | 60 | 14 | 20 |
| liquid G3 | | | | | | | | | | | | | | |
| Dispersion | PG62 | 10 | PY185 | 4 | | | Derivative 2 | 1 | B-3 | 25 | K-1 | 60 | 14 | 20 |
| liquid G4 | | | | | | | | | | | | | | |
| Dispersion | PG63 | 10 | PY185 | 4 | | | Derivative 2 | 1 | B-3 | 25 | K-1 | 60 | 14 | 20 |
| liquid G5 | | | | | | | | | | | | | | |
| Dispersion | PG58 | 8 | PY150 | 6 | | | Derivative 2 | 1 | B-3 | 25 | K-1 | 60 | 14 | 20 |
| liquid G6 | | | | | | | | | | | | | | |
| Dispersion | PG58 | 8 | PY139 | 6 | | | Derivative 2 | 1 | B-3 | 25 | K-1 | 60 | 14 | 20 |
| liquid G7 | | | | | | | | | | | | | | |
| Dispersion | PG58 | 8 | PY215 | 6 | | | Derivative 2 | 1 | B-3 | 25 | K-1 | 60 | 14 | 20 |
| liquid G8 | | | | | | | | | | | | | | |
| Dispersion | PG36 | 8 | PY150 | 4 | PY129 | 2 | Derivative 2 | 1 | B-3 | 25 | K-1 | 60 | 14 | 20 |
| liquid G9 | | | | | | | | | | | | | | |
| Dispersion | PG36 | 10 | PY185 | 2 | PY129 | 2 | Derivative 2 | 1 | B-3 | 25 | K-1 | 60 | 14 | 20 |
| liquid G10 | | | | | | | | | | | | | | |
| Dispersion | PG58 | 8 | PY150 | 6 | | | Derivative 1 | 1 | B-3 | 25 | K-1 | 60 | 14 | 20 |
| liquid G11 | | | | | | | | | | | | | | |
| Dispersion | PG58 | 8 | PY150 | 6 | | | Derivative 3 | 1 | B-3 | 25 | K-1 | 60 | 14 | 20 |
| liquid G12 | | | | | | | | | | | | | | |
| Dispersion | PG58 | 8 | PY150 | 6 | | | Derivative 4 | 1 | B-3 | 25 | K-1 | 60 | 14 | 20 |
| liquid G13 | | | | | | | | | | | | | | |
| Dispersion | PG58 | 8 | PY150 | 6 | | | Derivative 6 | 1 | B-3 | 25 | K-1 | 60 | 14 | 20 |
| liquid G14 | | | | | | | | | | | | | | |
| Dispersion | PG58 | 8 | PY150 | 6 | | | Derivative 2 | 1 | A-1 | 25 | K-1 | 60 | 14 | 20 |
| liquid G15 | | | | | | | | | | | | | | |
| Dispersion | PG58 | 8 | PY150 | 6 | | | Derivative 2 | 1 | A-2 | 25 | K-1 | 60 | 14 | 20 |
| liquid G16 | | | | | | | | | | | | | | |
| Dispersion | PG58 | 8 | PY150 | 6 | | | Derivative 2 | 1 | B-1 | 25 | K-1 | 60 | 14 | 20 |
| liquid G17 | | | | | | | | | | | | | | |
| Dispersion | PG58 | 8 | PY150 | 6 | | | Derivative 2 | 1 | B-2 | 25 | K-1 | 60 | 14 | 20 |
| liquid G18 | | | | | | | | | | | | | | |
| Dispersion | PG58 | 8 | PY150 | 6 | | | Derivative 2 | 1 | B-3 | 25 | K-1 | 60 | 14 | 20 |
| liquid G19 | | | | | | | | | | | | | | |
| Dispersion | PG58 | 8 | PY150 | 6 | | | Derivative 2 | 1 | B-4 | 25 | K-1 | 60 | 14 | 20 |
| liquid G20 | | | | | | | | | | | | | | |
| Dispersion | PG58 | 8 | PY150 | 6 | | | Derivative 2 | 1 | B-5 | 25 | K-1 | 60 | 14 | 20 |
| liquid G21 | | | | | | | | | | | | | | |
| Dispersion | PG58 | 8 | PY150 | 6 | | | Derivative 2 | 1 | B-6 | 25 | K-1 | 60 | 14 | 20 |
| liquid G22 | | | | | | | | | | | | | | |
| Dispersion | PG58 | 8 | PY150 | 6 | | | Derivative 2 | 1 | B-7 | 25 | K-1 | 60 | 14 | 20 |
| liquid G23 | | | | | | | | | | | | | | |

TABLE 3

| | | | | | | | Pigment | | | | | | Coloring | Concen- |
|---|---|---|---|---|---|---|---|---|---|---|---|---|---|---|
| | Coloring material | | | | | | derivative | | Resin | | Solvent | | material | tration |
| | | Part | | Part | | Part | | Part | | Part | | Part | concen- | of solid |
| Dispersion | | by | | by | | by | | by | | by | | by | tration | contents |
| liquid | Type | mass | Type | mass | Type | mass | Type | mass | Type | mass | Type | mass | (% by mass) | (% by mass) |
| Dispersion | PB15:6 | 14 | | | | | Derivative 6 | 1 | B-3 | 25 | K-1 | 60 | 14 | 20 |
| liquid B1 | | | | | | | | | | | | | | |
| Dispersion | PB60 | 14 | | | | | Derivative 6 | 1 | B-3 | 25 | K-1 | 60 | 14 | 20 |
| liquid B2 | | | | | | | | | | | | | | |
| Dispersion | PB15:6 | 10 | PV23 | 4 | | | Derivative 7 | 1 | B-3 | 25 | K-1 | 60 | 14 | 20 |
| liquid B3 | | | | | | | | | | | | | | |
| Dispersion | PB15:6 | 9 | PV23 | 5 | | | Derivative 7 | 1 | B-3 | 25 | K-1 | 60 | 14 | 20 |
| liquid B4 | | | | | | | | | | | | | | |
| Dispersion | PB15:6 | 10 | PV29 | 4 | | | Derivative 6 | 1 | B-3 | 25 | K-1 | 60 | 14 | 20 |
| liquid B5 | | | | | | | | | | | | | | |
| Dispersion | PB15:6 | 10 | AR289 | 4 | | | Derivative 6 | 1 | B-3 | 25 | K-1 | 60 | 14 | 20 |
| liquid B6 | | | | | | | | | | | | | | |
| Dispersion | PB15:6 | 9 | Dye 1 | 5 | | | Derivative 6 | 1 | B-3 | 25 | K-1 | 60 | 14 | 20 |
| liquid B7 | | | | | | | | | | | | | | |
| Dispersion | PB15:6 | 9 | Dye 2 | 5 | | | Derivative 6 | 1 | B-3 | 25 | K-1 | 60 | 14 | 20 |
| liquid B8 | | | | | | | | | | | | | | |
| Dispersion | PB15:6 | 9 | Dye 3 | 5 | | | Derivative 6 | 1 | B-3 | 25 | K-1 | 60 | 14 | 20 |
| liquid B9 | | | | | | | | | | | | | | |
| Dispersion | PB15:6 | 9 | PV23 | 3 | Dye 1 | 2 | Derivative 7 | 1 | B-3 | 25 | K-1 | 60 | 14 | 20 |
| liquid B10 | | | | | | | | | | | | | | |
| Dispersion | PB15:6 | 10 | PV23 | 4 | | | Derivative 7 | 1 | A-1 | 25 | K-1 | 60 | 14 | 20 |
| liquid B11 | | | | | | | | | | | | | | |
| Dispersion | PB15:6 | 10 | PV23 | 4 | | | Derivative 7 | 1 | A-2 | 25 | K-1 | 60 | 14 | 20 |
| liquid B12 | | | | | | | | | | | | | | |
| Dispersion | PB15:6 | 10 | PV23 | 4 | | | Derivative 7 | 1 | B-1 | 25 | K-1 | 60 | 14 | 20 |
| liquid B13 | | | | | | | | | | | | | | |
| Dispersion | PB15:6 | 10 | PV23 | 4 | | | Derivative 7 | 1 | B-2 | 25 | K-1 | 60 | 14 | 20 |
| liquid B14 | | | | | | | | | | | | | | |
| Dispersion | PB15:6 | 10 | PV23 | 4 | | | Derivative 7 | 1 | B-3 | 25 | K-1 | 60 | 14 | 20 |
| liquid B15 | | | | | | | | | | | | | | |
| Dispersion | PB15:6 | 10 | PV23 | 4 | | | Derivative 7 | 1 | B-4 | 25 | K-1 | 60 | 14 | 20 |
| liquid B16 | | | | | | | | | | | | | | |
| Dispersion | PB15:6 | 10 | PV23 | 4 | | | Derivative 7 | 1 | B-5 | 25 | K-1 | 60 | 14 | 20 |
| liquid B17 | | | | | | | | | | | | | | |
| Dispersion | PB15:6 | 10 | PV23 | 4 | | | Derivative 7 | 1 | B-6 | 25 | K-1 | 60 | 14 | 20 |
| liquid B18 | | | | | | | | | | | | | | |
| Dispersion | PB15:6 | 10 | PV23 | 4 | | | Derivative 7 | 1 | B-7 | 25 | K-1 | 60 | 14 | 20 |
| liquid B19 | | | | | | | | | | | | | | |

TABLE 4

| | | | | | Pigment | | | | | | Coloring | Concentration |
|---|---|---|---|---|---|---|---|---|---|---|---|---|
| | Coloring material | | | | derivative | | Resin | | Solvent | | material | of solid |
| Dispersion | | Part by | | Part by | | Part by | | Part by | | Part by | concentration | contents |
| liquid | Type | mass | Type | mass | Type | mass | Type | mass | Type | mass | (% by mass) | (% by mass) |
| Dispersion | PG7 | 14 | | | Derivative 6 | 1 | B-3 | 25 | K-1 | 60 | 14 | 20 |
| liquid C1 | | | | | | | | | | | | |
| Dispersion | PG7 | 10 | PG36 | 4 | Derivative 6 | 1 | B-3 | 26 | K-1 | 60 | 14 | 20 |
| liquid C2 | | | | | | | | | | | | |
| Dispersion | A1 | 14 | | | Derivative 6 | 1 | B-3 | 25 | K-1 | 60 | 14 | 20 |
| liquid C3 | phthalocyanine | | | | | | | | | | | |
| Dispersion | PG62 | 14 | | | Derivative 6 | 1 | B-3 | 25 | K-1 | 60 | 14 | 20 |
| liquid C4 | | | | | | | | | | | | |
| Dispersion | PG62 | 14 | | | Derivative 6 | 1 | A-1 | 25 | K-1 | 60 | 14 | 20 |
| liquid C5 | | | | | | | | | | | | |
| Dispersion | PG62 | 14 | | | Derivative 6 | 1 | A-2 | 25 | K-1 | 60 | 14 | 20 |
| liquid C6 | | | | | | | | | | | | |
| Dispersion | PG62 | 14 | | | Derivative 6 | 1 | B-1 | 25 | K-1 | 60 | 14 | 20 |
| liquid C7 | | | | | | | | | | | | |
| Dispersion | PG62 | 14 | | | Derivative 6 | 1 | B-2 | 25 | K-1 | 60 | 14 | 20 |
| liquid C8 | | | | | | | | | | | | |
| Dispersion | PG62 | 14 | | | Derivative 6 | 1 | B-3 | 26 | K-1 | 60 | 14 | 20 |
| liquid C9 | | | | | | | | | | | | |
| Dispersion | PG62 | 14 | | | Derivative 6 | 1 | B-4 | 25 | K-1 | 60 | 14 | 20 |
| liquid C10 | | | | | | | | | | | | |
| Dispersion | PG62 | 14 | | | Derivative 6 | 1 | B-5 | 25 | K-1 | 60 | 14 | 20 |
| liquid C11 | | | | | | | | | | | | |
| Dispersion | PG62 | 14 | | | Derivative 6 | 1 | B-6 | 26 | K-1 | 60 | 14 | 20 |
| liquid C12 | | | | | | | | | | | | |
| Dispersion | PG62 | 14 | | | Derivative 6 | 1 | B-7 | 25 | K-1 | 60 | 14 | 20 |
| liquid C13 | | | | | | | | | | | | |

TABLE 5

| | | | | | Pigment | | | | | | Coloring | Concentration |
|---|---|---|---|---|---|---|---|---|---|---|---|---|
| | Coloring material | | | | derivative | | Resin | | Solvent | | material | of solid |
| Dispersion | | Part by | | Part by | | Part by | | Part by | | Part by | concentration | contents |
| liquid | Type | mass | Type | mass | Type | mass | Type | mass | Type | mass | (% by mass) | (% by mass) |
| Dispersion | PR122 | 14 | | | Derivative 1 | 1 | B-3 | 25 | K-1 | 60 | 14 | 20 |
| liquid M1 | | | | | | | | | | | | |
| Dispersion | PR177 | 14 | | | Derivative 1 | 1 | B-3 | 25 | K-1 | 60 | 14 | 20 |
| liquid M2 | | | | | | | | | | | | |
| Dispersion | AR289 | 14 | | | Derivative 1 | 1 | B-3 | 25 | K-1 | 60 | 14 | 20 |
| liquid M3 | | | | | | | | | | | | |
| Dispersion | PR122 | 7 | AR289 | 7 | Derivative 1 | 1 | B-3 | 25 | K-1 | 60 | 14 | 20 |
| liquid M4 | | | | | | | | | | | | |
| Dispersion | PR122 | 7 | Dye 1 | 7 | Derivative 1 | 1 | B-3 | 25 | K-1 | 60 | 14 | 20 |
| liquid M5 | | | | | | | | | | | | |
| Dispersion | PR122 | 7 | Dye 2 | 7 | Derivative 1 | 1 | B-3 | 25 | K-1 | 60 | 14 | 20 |
| liquid M6 | | | | | | | | | | | | |
| Dispersion | PR122 | 7 | Dye 3 | 7 | Derivative 1 | 1 | B-3 | 25 | K-1 | 60 | 14 | 20 |
| liquid M7 | | | | | | | | | | | | |
| Dispersion | PR122 | 7 | Dye 1 | 7 | Derivative 1 | 1 | A-1 | 26 | K-1 | 60 | 14 | 20 |
| liquid M8 | | | | | | | | | | | | |
| Dispersion | PR122 | 7 | Dye 1 | 7 | Derivative 1 | 1 | A-2 | 25 | K-1 | 60 | 14 | 20 |
| liquid M9 | | | | | | | | | | | | |
| Dispersion | PR122 | 7 | Dye 1 | 7 | Derivative 1 | 1 | B-1 | 26 | K-1 | 60 | 14 | 20 |
| liquid M10 | | | | | | | | | | | | |
| Dispersion | PR122 | 7 | Dye 1 | 7 | Derivative 1 | 1 | B-2 | 25 | K-1 | 60 | 14 | 20 |
| liquid M11 | | | | | | | | | | | | |
| Dispersion | PR122 | 7 | Dye 1 | 7 | Derivative 1 | 1 | B-3 | 25 | K-1 | 60 | 14 | 20 |
| liquid M12 | | | | | | | | | | | | |
| Dispersion | PR122 | 7 | Dye 1 | 7 | Derivative 1 | 1 | B-4 | 25 | K-1 | 60 | 14 | 20 |
| liquid M13 | | | | | | | | | | | | |
| Dispersion | PR122 | 7 | Dye 1 | 7 | Derivative 1 | 1 | B-5 | 25 | K-1 | 60 | 14 | 20 |
| liquid M14 | | | | | | | | | | | | |
| Dispersion | PR122 | 7 | Dye 1 | 7 | Derivative 1 | 1 | B-6 | 25 | K-1 | 60 | 14 | 20 |
| liquid M15 | | | | | | | | | | | | |
| Dispersion | PR122 | 7 | Dye 1 | 7 | Derivative 1 | 1 | B-7 | 25 | K-1 | 60 | 14 | 20 |
| liquid M16 | | | | | | | | | | | | |

TABLE 6

| | Coloring | | Pigment | | | | | | Coloring | Concentration |
|---|---|---|---|---|---|---|---|---|---|---|
| | material | | derivative | | Resin | | Solvent | | material | of solid |
| Dispersion | | Part by | | Part by | | Part by | | Part by | concentration | contents |
| liquid | Type | mass | Type | mass | Type | mass | Type | mass | (% by mass) | (% by mass) |
| Dispersion | PY150 | 14 | Derivative 3 | 1 | B-3 | 2 [symbol] | K-1 | 60 | 14 | 20 |
| liquid Y1 | | | | | | | | | | |
| Dispersion | PY185 | 14 | Derivative 2 | 1 | B-3 | 25 | K-1 | 60 | 14 | 20 |
| liquid Y2 | | | | | | | | | | |
| Dispersion | PY139 | 14 | Derivative 2 | 1 | B-3 | 25 | K-1 | 60 | 14 | 20 |
| liquid Y3 | | | | | | | | | | |
| Dispersion | PY215 | 14 | Derivative 1 | 1 | B-3 | 25 | K-1 | 60 | 14 | 20 |
| liquid Y4 | | | | | | | | | | |
| Dispersion | Yellow1 | 14 | Derivative 2 | 1 | B-3 | 25 | K-1 | 60 | 14 | 20 |
| liquid Y5 | | | | | | | | | | |
| Dispersion | Yellow2 | 14 | Derivative 2 | 1 | B-3 | 2 [symbol] | K-1 | 60 | 14 | 20 |
| liquid Y6 | | | | | | | | | | |
| Dispersion | Yellow3 | 14 | Derivative 2 | 1 | B-3 | 25 | K-1 | 60 | 14 | 20 |
| liquid Y7 | | | | | | | | | | |
| Dispersion | PY150 | 14 | Derivative 3 | 1 | A-1 | 25 | K-1 | 60 | 14 | 20 |
| liquid Y8 | | | | | | | | | | |
| Dispersion | PY150 | 14 | Derivative 3 | 1 | A-2 | 25 | K-1 | 60 | 14 | 20 |
| liquid Y9 | | | | | | | | | | |
| Dispersion | PY150 | 14 | Derivative 3 | 1 | B-1 | 25 | K-1 | 60 | 14 | 20 |
| liquid Y10 | | | | | | | | | | |
| Dispersion | PY150 | 14 | Derivative 3 | 1 | B-2 | 25 | K-1 | 60 | 14 | 20 |
| liquid Y11 | | | | | | | | | | |
| Dispersion | PY150 | 14 | Derivative 3 | 1 | B-3 | 25 | K-1 | 60 | 14 | 20 |
| liquid Y12 | | | | | | | | | | |
| Dispersion | PY150 | 14 | Derivative 3 | 1 | B-4 | 25 | K-1 | 60 | 14 | 20 |
| liquid Y13 | | | | | | | | | | |
| Dispersion | PY150 | 14 | Derivative 3 | 1 | B-5 | 25 | K-1 | 60 | 14 | 20 |
| liquid Y14 | | | | | | | | | | |
| Dispersion | PY150 | 14 | Derivative 3 | 1 | B-6 | 25 | K-1 | 60 | 14 | 20 |
| liquid Y15 | | | | | | | | | | |
| Dispersion | PY150 | 14 | Derivative 3 | 1 | B-7 | 25 | K-1 | 60 | 14 | 20 |
| liquid Y16 | | | | | | | | | | |

[symbol]

indicates data missing or illegible when filed

The raw materials described by abbreviations shown in the above tables are as follows.

(Coloring Material)

PR122: C. I. Pigment Red 122

PR177: C. I. Pigment Red 177

PR254: C. I. Pigment Red 254

PR264: C. I. Pigment Red 264

PR269: C. I. Pigment Red 269

PR272: C. I. Pigment Red 272

PY129: C. I. Pigment Yellow 129

PY139: C. I. Pigment Yellow 139

PY150: C. I. Pigment Yellow 150

PY185: C. I. Pigment Yellow 185

PY215: C. I. Pigment Yellow 215

PO71: C. I. Pigment Orange 71

PG7: C. I. Pigment Green 7

PG36: C. I. Pigment Green 36

PG58: C. I. Pigment Green 5M

PG62: C. I. Pigment Green 62

PG63: C. I. Pigment Green 63

PB15:6: C. I. Pigment Blue 15:6

PB60: C. I. Pigment Blue 60

PV23: C. I. Pigment Violet 23

PV29: C. I. Pigment Violet 29

Al phthalocyanine: compound having the following structure

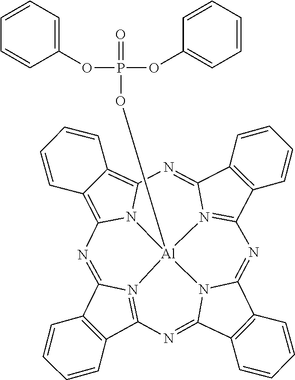

AR289: C. I. Acid Red 289

Dye 1: compound having the following structure (xanthene dye; in the following structural formula, iPr is an isopropyl group)

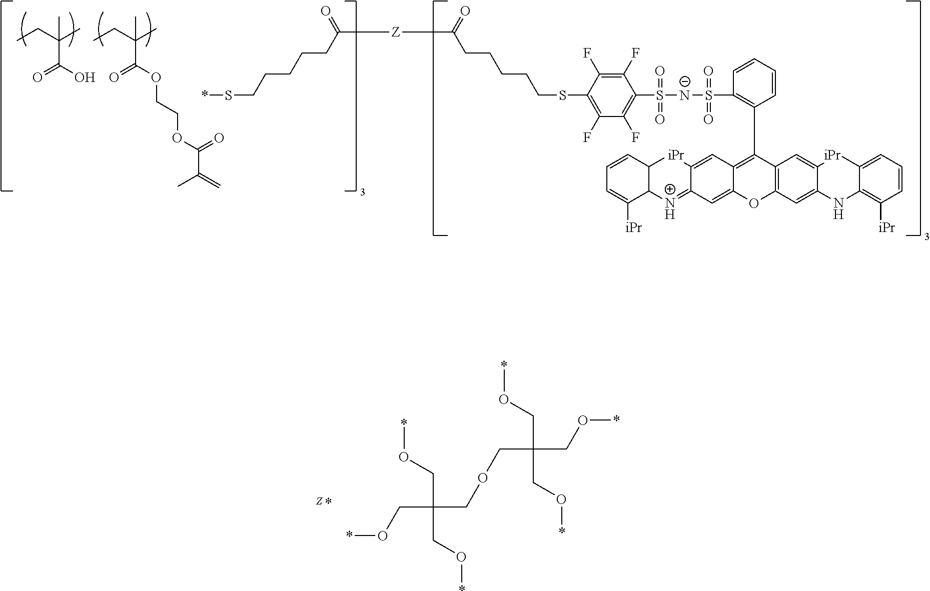

Dye 2: salt-forming compound of a polymer having the following structure (weight-average molecular weight: 7000) and C. I. Acid Red 52 (xanthene dye)

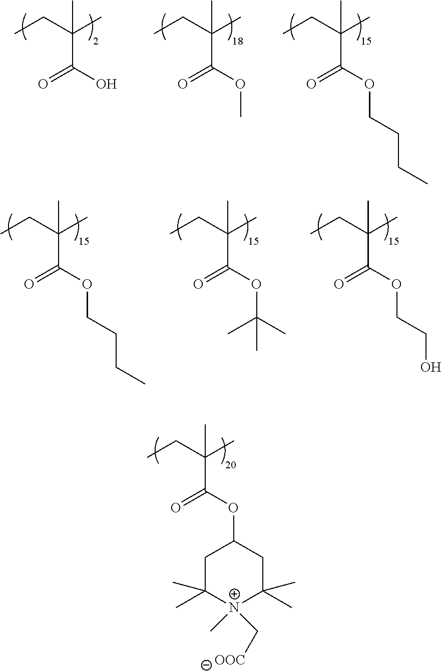

Dye 3: compound having the following structure (xanthene dye)

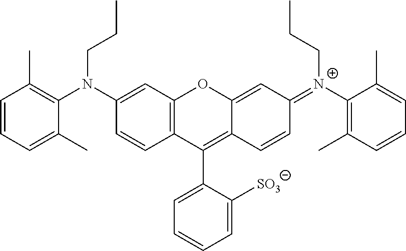

Yellow1: compound having the following structure

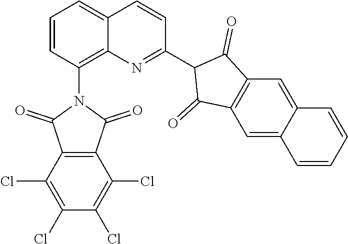 [SMILES: O=C1c2cc3ccccc3cc2C(=O)C1c1ccc2cccc(N3C(=O)c4c(Cl)c(Cl)c(Cl)c(Cl)c4C3=O)c2n1]

Yellow2: compound having the following structure

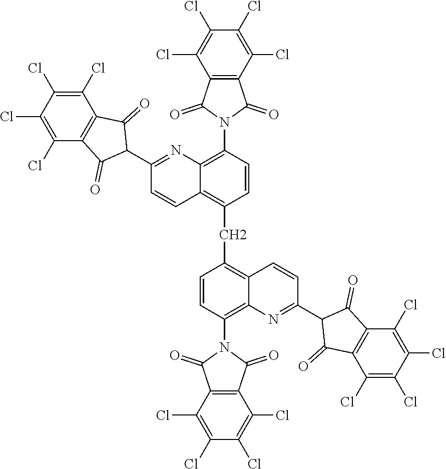 [SMILES: O=C1c2c(Cl)c(Cl)c(Cl)c(Cl)c2C(=O)C1c1ccc2c(Cc3ccc(N4C(=O)c5c(Cl)c(Cl)c(Cl)c(Cl)c5C4=O)c4nc(C5C(=O)c6c(Cl)c(Cl)c(Cl)c(Cl)c6C5=O)ccc34)ccc(N3C(=O)c4c(Cl)c(Cl)c(Cl)c(Cl)c4C3=O)c2n1]

Yellow3: compound having the following structure

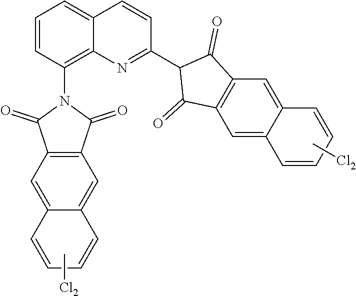

(Pigment Derivative)

Derivative 1: compound having the following structure

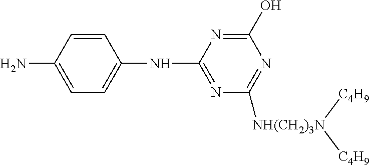

Derivative 2: compound having the following structure

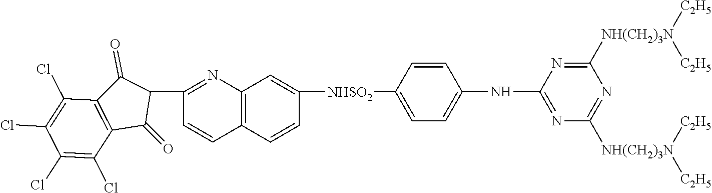

Derivative 3: compound having the following structure

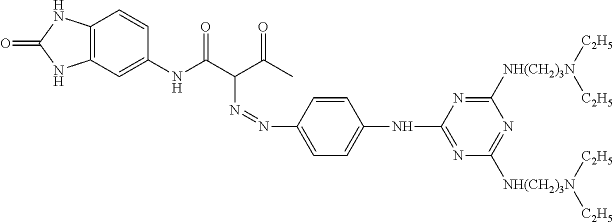

Derivative 4: compound having the following structure

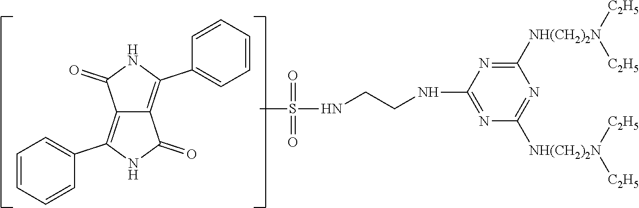

Derivative 5: compound having the following structure

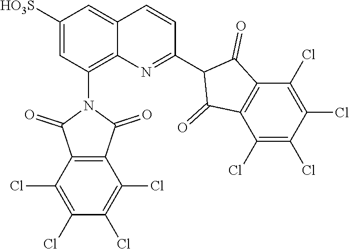 [SMILES: O=C1c2c(Cl)c(Cl)c(Cl)c(Cl)c2C(=O)C1c1ccc2cc(S(=O)(=O)O)cc(N3C(=O)c4c(Cl)c(Cl)c(Cl)c(Cl)c4C3=O)c2n1]

Derivative 6: compound having the following structure

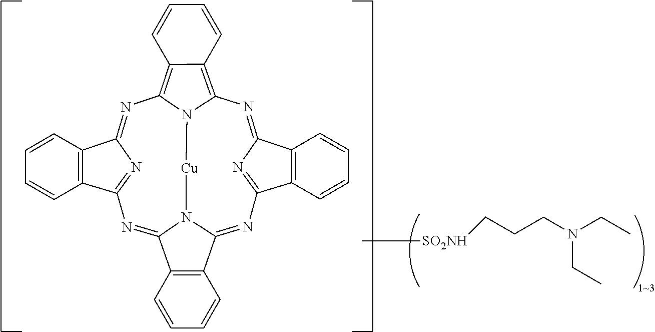

Derivative 7: mixture of compounds having the following structures (mass ratio of upper compound to lower compound=30:70)

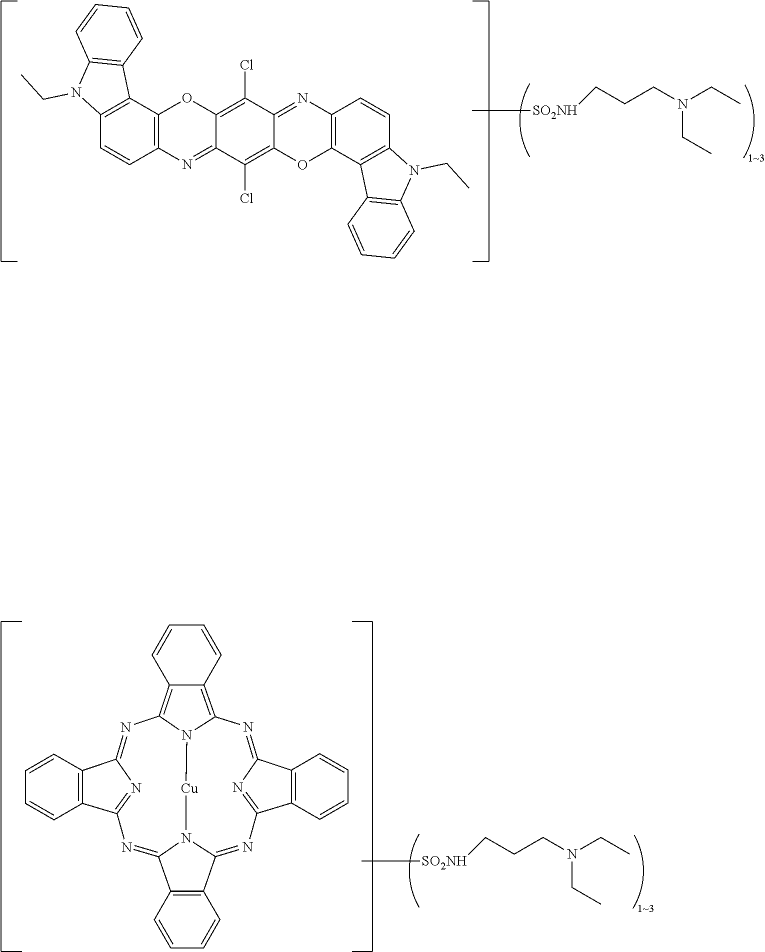

<Resin>

A-1: 20% by mass propylene glycol monomethyl ether acetate (PGMEA) solution of a resin having the following structure (the numerical value described together with the main chain indicates a molar ratio, and the numerical value described together with the side chain indicates the number of repeating units; weight-average molecular weight=24000, acid value: 47 mgKOH/g

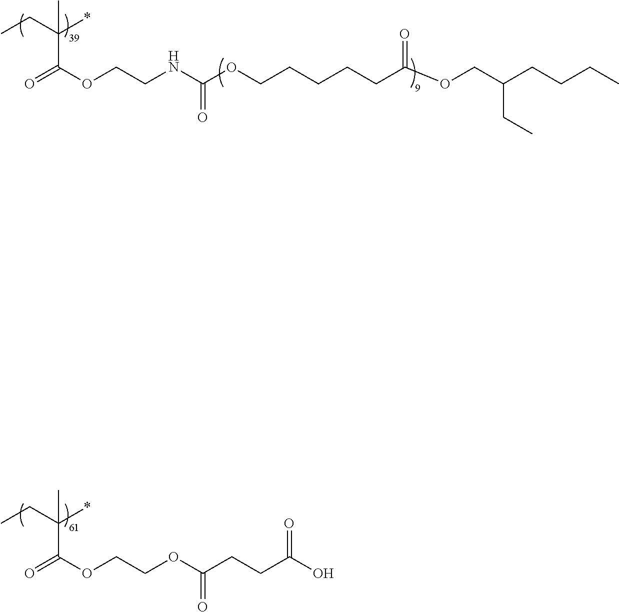

A-2: 20% by mass PGMEA solution of a resin having the following structure (the numerical value described together with the main chain indicates a molar ratio, and the numerical value described together with the side chain indicates the number of repeating units: weight-average molecular weight=16000, acid value: 67 mgKOH/g)

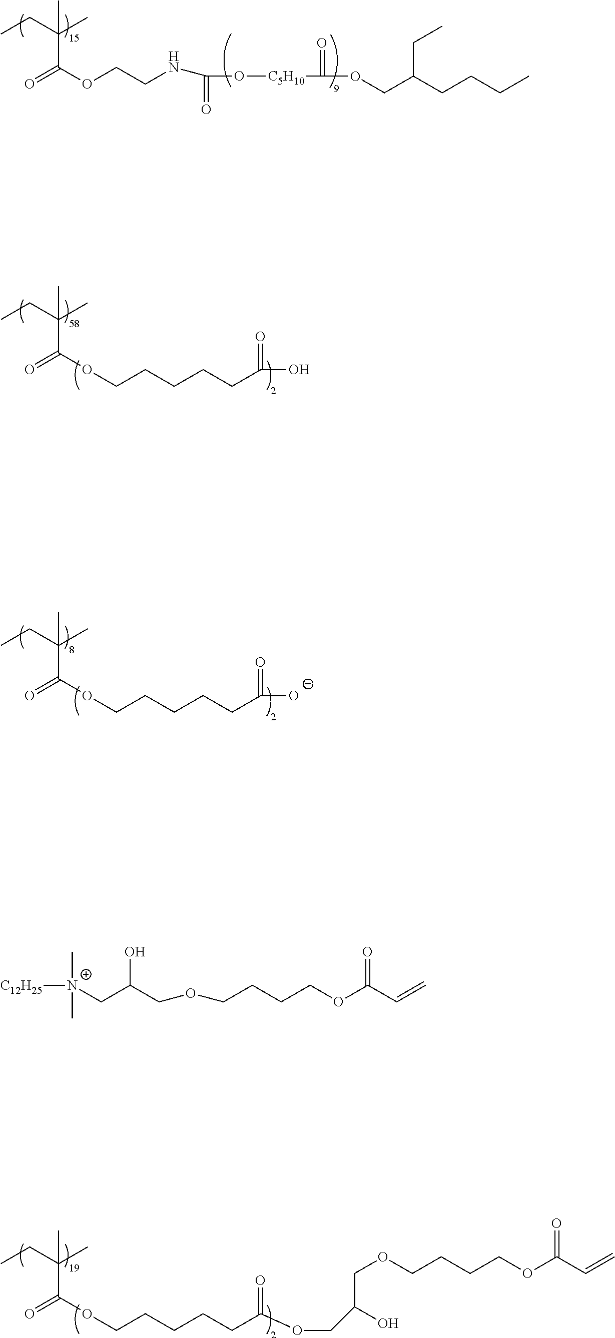

B-1: resin solution of a resin B-1 synthesized by the following method (concentration of solid contents: 20% by mass)

50 parts by mass of methyl methacrylate, 50 parts by mass of n-butyl methacrylate, and 45.4 parts by mass of propylene glycol monomethyl ether acetate (PGMEA) were charged into a reaction container, and the atmosphere gas was replaced with nitrogen gas. The inside of the reaction container was heated to 70° C., 6 parts by mass of 3-mercapto-1,2-propanediol was added thereto, 0.12 parts by mass of azobisisobutyronitrile (AIBN) was further added thereto, and the mixture was reacted for 12 hours. It was confirmed by solid content measurement that 95% thereof was reacted. Next, 9.7 parts by mass of pyromellitic acid anhydride, 70.3 parts by mass of PGMEA, and 0.20 parts by mass of 1.8-diazabicyclo-[5.4.0]-7-undecene (DBU) as a catalyst were added thereto, and the mixture was reacted at 120° C. for 7 hours. It was confirmed by acid value measurement that 98% or more of the acid anhydride was half-esterified, and the reaction was terminated. PGMEA was added thereto to adjust non-volatile content (concentration of solid contents) to be 200% by mass, thereby obtaining a resin solution of a resin B-1 having the following structure, in which an acid value was 43 mgKOH/g and a weight-average molecular weight was 9000.

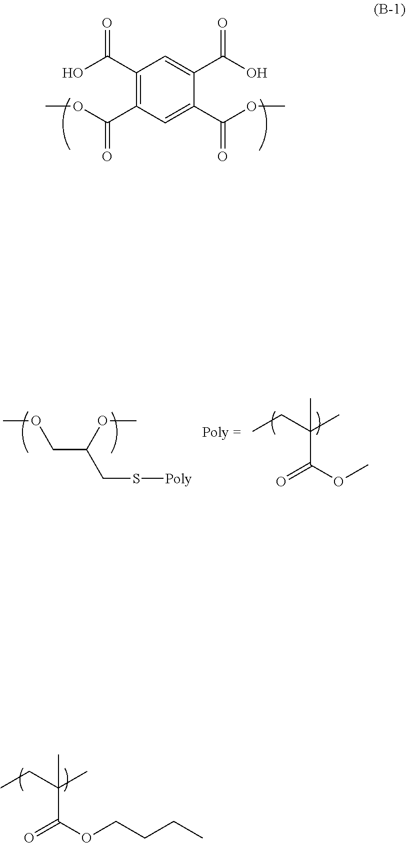

B-2: resin solution of a resin B-2 synthesized by the following method (concentration of solid contents: 20% by mass)

50 parts by mass of methyl methacrylate, 30 parts by mass of n-butyl methacrylate, 20 parts by mass of t-butyl methacrylate, and 45.4 parts by mass of PGMEA were charged into a reaction container, and the atmosphere gas was replaced with nitrogen gas. The inside of the reaction container was heated to 70° C., 6 parts by mass of 3-mercapto-1,2-propanediol was added thereto, 0.12 parts by mass of azobisisobutyronitrile (AIBN) was further added thereto, and the mixture was reacted for 12 hours. It was confirmed by solid content measurement that 95% thereof was reacted. Next, 9.7 parts by mass of pyromellitic acid anhydride, 70.3 parts by mass of PGMEA, and 0.20 parts by mass of 1,8-diazabicyclo-[5.4.0]-7-undecene (DBU) as a catalyst were added thereto, and the mixture was reacted at 120° C. for 7 hours. It was confirmed by acid value measurement that 98% or more of the acid anhydride was half-esterified, and the reaction was terminated. PGMEA was added thereto to adjust non-volatile content (concentration of solid contents) to be 20% by mass, thereby obtaining a resin solution of a resin B-2 having the following structure, in which an acid value was 43 mgKOH/g and a weight-average molecular weight was 9000.

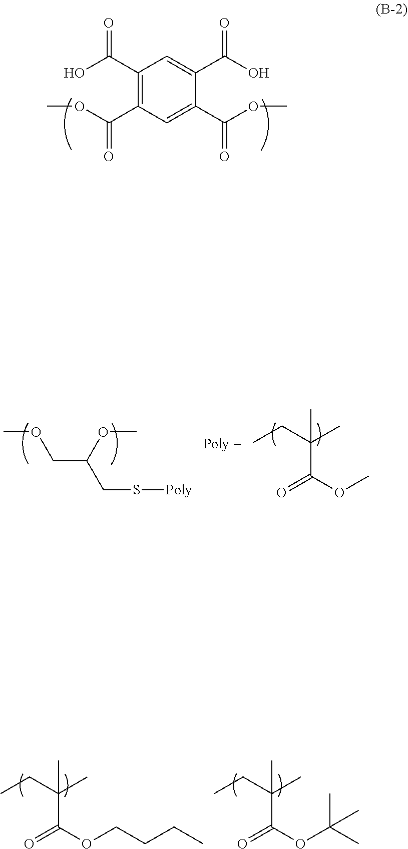

B-3: resin solution of a resin B-3 synthesized by the following method (concentration of solid contents: 20% by mass)

A resin solution of a resin B-3 having the following structure, in which an acid value was 43 mgKOH/g and a weight-average molecular weight was 9000, was obtained in the same manner as in the synthesis of the resin B-2, except that 20 parts by mass of t-butyl methacrylate was changed to 20 parts by mass of (3-ethyloxetan-3-yl)methyl methacrylate.

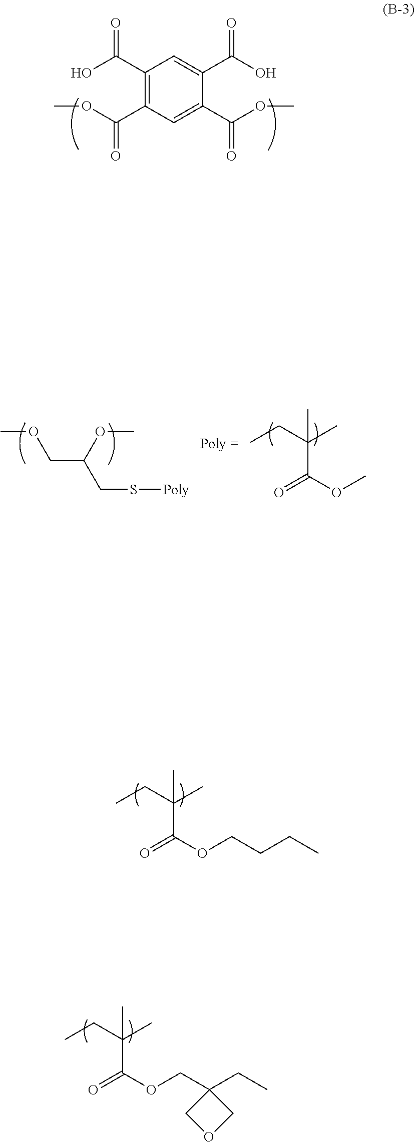

B-4: resin solution of a resin B-4 synthesized by the following method (concentration of solid contents: 20% by mass)

A resin solution of a resin B-4 having the following structure, in which an acid value was 43 mgKOH/g and a weight-average molecular weight (Mw) was 9000, was obtained in the same manner as in the synthesis of the resin B-2, except that 20 parts by mass of t-butyl methacrylate was changed to 20 parts by mass of “Karenz MOI-BM” manufactured by SHOWA DENKO K.K.

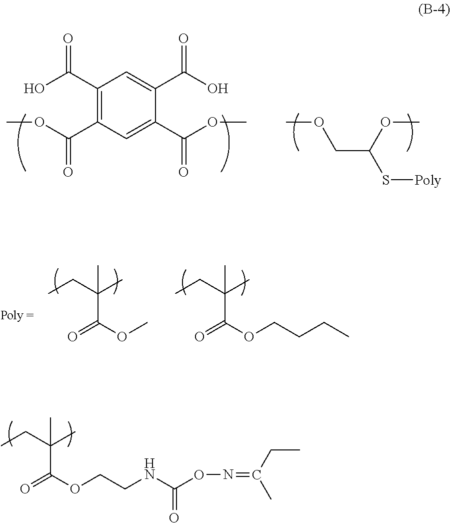

B-5: resin solution of a resin B-5 synthesized by the following method (concentration of solid contents: 20% by mass)

6.0 parts by mass of 3-mercapto-1,2-propanediol, 9.5 parts by mass of pyromellitic acid anhydride, 62 parts by mass of PGMEA, and 0.2 parts by mass of 1.8-diazabicyclo-[5.4.0]-7-undecene were charged into a reaction container, and the atmosphere gas was replaced with nitrogen gas. The inside of the reaction container was heated to 100° C., and the mixture was reacted for 7 hours. After confirming by acid value measurement that 98% or more of the acid anhydride was half-esterified, the temperature in the system was lowered to 70° C. 53.5 parts by mass of PGMEA solution in which 65 parts by mass of methyl methacrylate, 5.0 parts by mass of ethyl acrylate, 15 parts by mass of t-butyl acrylate, 5.0 parts by mass of methacrylic acid, 10 parts by mass of hydroxyethyl methacrylate, and 0.1 parts by mass of 2,2′-azobisisobutyronitrile were dissolved was added thereto, and the mixture was reacted for 10 hours. It was confirmed by solid content measurement that the polymerization had proceeded by 95%, and the reaction was terminated. PGMEA was added thereto to adjust non-volatile content (concentration of solid contents) to be 20% by mass, thereby obtaining a resin solution of a resin B-5 having the following structure, in which an acid value was 70.5 mgKOH/g and a weight-average molecular weight was 10000.

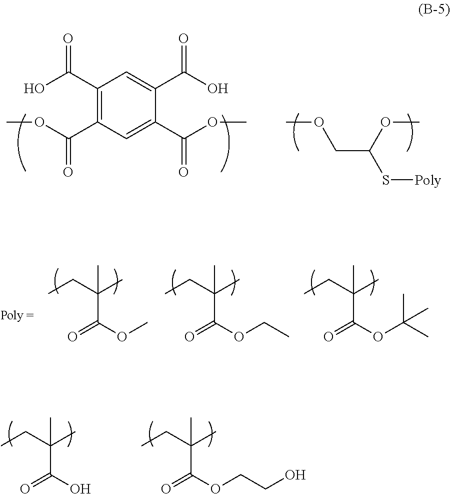

B-6: resin solution of a resin B-6 synthesized by the following method (concentration of solid contents: 20% by mass)

108 parts by mass of 1-thioglycerol, 174 parts by mass of pyromellitic acid anhydride, 650 parts by mass of methoxypropyl acetate, and 0.2 parts by mass of monobutyltin oxide as a catalyst were charged into a reaction container, the atmosphere gas was replaced with nitrogen gas, and the mixture was reacted at 120° C. for 5 hours (first step). It was confirmed by acid value measurement that 95% or more of the acid anhydride was half-esterified. Next, 160 parts by mass of the compound obtained in the first step expressed in terms of solid contents, 200 parts by mass of 2-hydroxypropyl methacrylate, 200 parts by mass of ethyl acrylate, 150 parts by mass of t-butyl acrylate, 200 parts by mass of 2-methoxyethyl acrylate, 200 parts by mass of methyl acrylate, 50 parts by mass of methacrylic acid, and 663 parts by mass of PGMEA were charged to a reaction container, the inside of the reaction container was heated to 80° C. 1.2 parts by mass of 2,2′-azobis(2,4-dimethylvaleronitrile) was added thereto, and the mixture was reacted for 12 hours (second step). It was confirmed by solid content measurement that 95% thereof was reacted. Finally, 500 parts by mass of PGMEA solution of 50% by mass of the compound obtained in the second step, 27.0 parts by mass of 2-methacryloyloxyethyl isocyanate (MOI), 0.1 parts by mass of hydroquinone were charged to a reaction container, the reaction was performed until the disappearance of the peak of 2270 cm⁻¹ based on the isocyanate group was confirmed (third step). After confirming the disappearance of the peak, the reaction solution was cooled, and PGMEA was added thereto to adjust non-volatile content (concentration of solid contents) to be 20% by mass, thereby obtaining a resin solution of a resin B-6 having the following structure, in which an acid value was 68 mgKOH/g and a weight-average molecular weight was 13000.

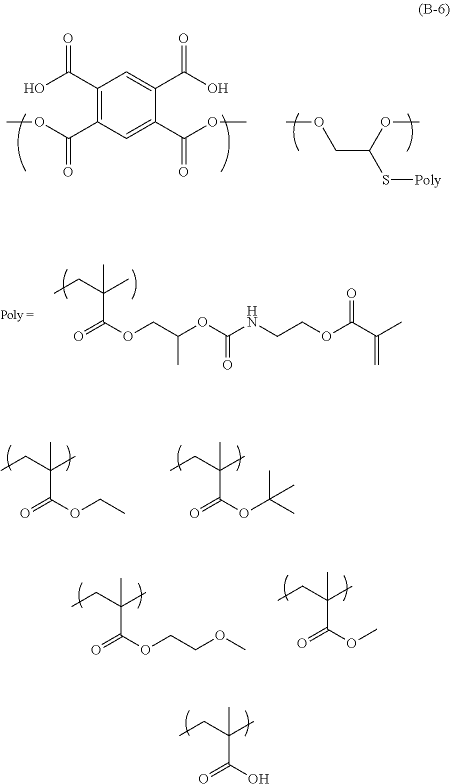

B-7: resin solution of a resin B-7 synthesized by the following method (concentration of solid contents: 20% by mass)

40 parts by mass of methyl methacrylate, 60 parts by mass of n-butyl methacrylate, and 45.4 parts by mass of PGMEA were charged into a reaction container, and the atmosphere gas was replaced with nitrogen gas. The inside of the reaction container was heated to 70° C., 8 parts by mass of 3-mercapto-1,2-propanediol was added thereto, 0.12 parts by mass of azobisisobutyronitrile (AIBN) was further added thereto, and the mixture was reacted for 12 hours. It was confirmed by solid content measurement that 95% thereof was reacted. Next, 13 pars by mass of pyromellitic acid anhydride, 70.3 parts by mass of PGMEA, and 0.20 parts by mass of 1,8-diazabicyclo-[5.4.0]-7-undecene (DBU) as a catalyst were added thereto, and the mixture was reacted at 120° C. for 7 hours. It was confirmed by acid value measurement that 98% or more of the acid anhydride was half-esterified, and the reaction was terminated. PGMEA was added thereto to adjust non-volatile content (concentration of solid contents) to be 20% by mass, thereby obtaining a resin solution of a resin B-7 having the following structure, in which an acid value was 55 mgKOH/g and a weight-average molecular weight was 10000.

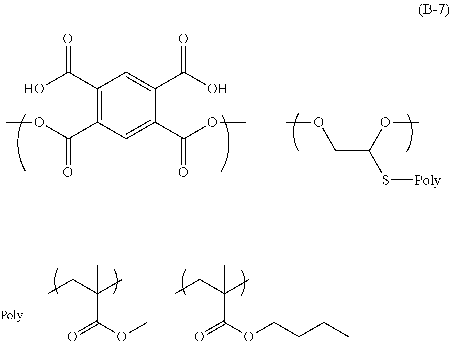

(Solvent)

K-1: propylene glycol monomethyl ether acetate (PGMEA)

<Production of Photosensitive Composition>

Raw materials described in the following tables were mixed to prepare a photosensitive composition. A value of the blending amount of the resin is the value of the blending amount in the resin solution having a solid content of 20% by mass. In the following tables, the content of the photopolymerization initiator in the total solid content of the photosensitive composition is shown in the column of “Photopolymerization initiator amount”. In addition, regarding the polymerizable monomer and the photopolymerization initiator included in the photosensitive composition, the value obtained by dividing the mass of the polymerizable monomer by the mass of the photopolymerization initiator is shown in the column of “M/l ratio”. In addition, regarding the coloring material and the polymerizable monomer included in the photosensitive composition, the value obtained by dividing the mass of the polymerizable monomer by the mass of the coloring material is shown in the column of “M/P ratio”.

TABLE 7

| | Dispersion | | | | Polymerizable | | Photopolymerization | | | | |
|---|---|---|---|---|---|---|---|---|---|---|---|
| | liquid | | Resin | | monomer | | initiator | | Additive | | |
| | | Part by | | Part by | | Part by | | Part by | | Part by | Surfactant |
| | Type | mass | Type | mass | Type | mass | Type | mass | Type | mass | Type |
| Example R1 | Dispersion | 68 | A-3 | 7.0 | M-3 | 2. [symbol] | G-1 | 0.8 | | | I-1 |
| | liquid R1 | | | | | | | | | | |
| Example R2 | Dispersion | 65 | A-3 | [symbol] .0 | M-3 | 2.5 | G-1 | 0.8 | | | I-1 |
| | liquid R2 | | | | | | | | | | |
| Example R3 | Dispersion | 65 | A-3 | 7.0 | M-3 | 2.5 | G-1 | 0.8 | | | I-1 |
| | liquid R3 | | | | | | | | | | |
| Example R4 | Dispersion | 68 | A-3 | 7.0 | M-4 | 2.3 | G-1 | 0.8 | | | I-1 |
| | liquid R4 | | | | | | | | | | |
| Example R5 | Dispersion | 65 | A-3 | [symbol] .0 | M-3 | 2.5 | G-1 | 0.8 | | | I-1 |
| | liquid R5 | | | | | | | | | | |
| Example R6 | Dispersion | 65 | A-3 | 7.0 | M-3 | 2.5 | G-1 | 0.8 | | | I-1 |
| | liquid R6 | | | | | | | | | | |
| Example R7 | Dispersion | 68 | A-3 | [symbol] .0 | M-3 | 2.3 | G-1 | 0. [symbol] | | | I-1 |
| | liquid R7 | | | | | | | | | | |
| Example R8 | Dispersion | 65 | A-3 | [symbol] .0 | M-3 | 2.5 | G-1 | 0.8 | | | I-1 |
| | liquid R8 | | | | | | | | | | |
| Example R9 | Dispersion | 65 | A-3 | 7.0 | M-3 | 2.5 | G-1 | 0.8 | | | I-1 |
| | liquid R9 | | | | | | | | | | |
| Example R10 | Dispersion | 68 | A-3 | [symbol] .0 | M-3 | 2.3 | G-1 | 0. [symbol] | | | I-1 |
| | liquid R10 | | | | | | | | | | |
| Example R11 | Dispersion | 65 | A-3 | [symbol] .0 | M-3 | 2.5 | G-1 | 0.8 | | | I-1 |
| | liquid R11 | | | | | | | | | | |
| Example R12 | Dispersion | 6 [symbol] | A-3 | 7.0 | M-3 | 2.5 | G-1 | 0.8 | | | I-1 |
| | liquid R12 | | | | | | | | | | |
| Example R13 | Dispersion | 68 | A-3 | [symbol] .0 | M-3 | 2.3 | G-1 | 0. [symbol] | | | I-1 |
| | liquid R13 | | | | | | | | | | |
| Example R14 | Dispersion | 65 | A-3 | [symbol] .0 | M-3 | 2.5 | G-1 | 0.8 | | | I-1 |
| | liquid R14 | | | | | | | | | | |
| Example R15 | Dispersion | 65 | A-3 | 7.0 | M-3 | 2.5 | G-1 | 0.8 | | | I-1 |
| | liquid R15 | | | | | | | | | | |
| Example R16 | Dispersion | 65 | A-3 | [symbol] .0 | M-3 | 2. [symbol] | G-1 | 0.8 | | | I-1 |
| | liquid R16 | | | | | | | | | | |
| Example R17 | Dispersion | 68 | A-3 | [symbol] .0 | M-3 | 2.3 | G-1 | 0.8 | | | I-1 |
| | liquid R17 | | | | | | | | | | |
| Example R18 | Dispersion | 65 | A-3 | 7.0 | M-3 | 2.5 | G-1 | 0.8 | | | I-1 |
| | liquid R18 | | | | | | | | | | |
| Example R19 | Dispersion | 65 | A-3 | [symbol] .0 | M-3 | [symbol] . [symbol] | G-1 | 0. [symbol] | | | I-1 |
| | liquid R19 | | | | | | | | | | |
| Example R20 | Dispersion | 68 | A-3 | [symbol] .0 | M-3 | 2.3 | G-1 | 0. [symbol] | | | I-1 |
| | liquid R20 | | | | | | | | | | |
| Example R21 | Dispersion | 65 | A-3 | 7.0 | M-3 | 2.5 | G-1 | 0.8 | | | I-1 |
| | liquid R21 | | | | | | | | | | |
| Example R22 | Dispersion | 65 | A-3 | [symbol] .0 | M-3 | 2.3 | G-1 | 0. [symbol] | | | I-1 |
| | liquid R22 | | | | | | | | | | |
| Example R23 | Dispersion | 68 | A-3 | [symbol] .0 | M-3 | 2.3 | G-1 | 0.8 | | | I-1 |
| | liquid R23 | | | | | | | | | | |
| Example R24 | Dispersion | 65 | A-3 | 7. [symbol] | M-3 | 2. [symbol] | G-1 | 0. [symbol] | | | I-1 |
| | liquid R5 | | | | | | | | | | |
| Example R25 | Dispersion | 6 [symbol] | A-3 | 7.5 | M-3 | 2.5 | G-1 | 0.6 | | | I-1 |
| | liquid R5 | | | | | | | | | | |
| Example R26 | Dispersion | 68 | A-3 | [symbol] .0 | M-3 | 2.6 | G-1 | 0.2 | | | I-1 |
| | liquid R5 | | | | | | | | | | |
| Example R27 | Dispersion | 65 | A-3 | 7.0 | M-3 | 2.4 | G-1 | 0.9 | | | I-1 |
| | liquid R5 | | | | | | | | | | |
| Example R28 | Dispersion | 65 | A-3 | 7.0 | M-3 | 2.2 | G-1 | [symbol] | | | I-1 |
| | liquid R5 | | | | | | | | | | |
| Example R29 | Dispersion | 68 | A-3 | [symbol] .0 | M-3 | 2. [symbol] | G-1 | [symbol] | | | I-1 |
| | liquid R5 | | | | | | | | | | |
| Example R30 | Dispersion | 65 | A-3 | 7.0 | M-3 | 1.8 | G-1 | [symbol] | | | I-1 |
| | liquid R5 | | | | | | | | | | |

| | | Polymerization | | | | | Photopolymerization | | Coloring |
|---|---|---|---|---|---|---|---|---|---|
| | Surfactant | inhibitor | | Solvent | | | initiator | | material |
| | Part by | | Part by | | Part by | M/I | amount | M/P | concentration |
| | mass | Type | mass | Type | mass | ratio | (% by mass) | ratio | (% by mass) |
| Example R1 | 5.0 | J-1 | 0.01 | K-1 | 19.7 | 3.1 | 4.5 | [symbol] .27 | [symbol] |
| Example R2 | 5.0 | J-1 | 0.01 | K-1 | 19.7 | 3.1 | 4.5 | [symbol] .2 [symbol] | [symbol] |
| Example R3 | 5.0 | J-1 | 0.01 | K-1 | 19.7 | 3.1 | 4.5 | [symbol] .27 | [symbol] |
| Example R4 | [symbol] . [symbol] | J-1 | 0.01 | K-1 | 19.7 | 3.1 | 4.5 | [symbol] .27 | [symbol] |
| Example R5 | 5.0 | J-1 | 0.01 | K-1 | 19.7 | [symbol] . [symbol] | 4.5 | [symbol] .27 | [symbol] |
| Example R6 | 5.0 | J-1 | 0.01 | K-1 | 19.7 | 3.1 | 4.5 | [symbol] .27 | [symbol] |
| Example R7 | [symbol] . [symbol] | J-1 | 0.01 | K-1 | 19.7 | 3.1 | 4.5 | [symbol] .27 | [symbol] |
| Example R8 | 5.0 | J-1 | 0.01 | K-1 | 19.7 | [symbol] . [symbol] | 4.5 | [symbol] .27 | [symbol] |
| Example R9 | 5.0 | J-1 | 0.01 | K-1 | 19.7 | 3.1 | 4.5 | [symbol] .27 | [symbol] |
| Example R10 | [symbol] . [symbol] | J-1 | 0.01 | K-1 | 19.7 | 3.1 | 4.5 | [symbol] .27 | [symbol] |
| Example R11 | 5. [symbol] | J-1 | 0.01 | K-1 | 19.7 | [symbol] . [symbol] | 4.5 | [symbol] .27 | [symbol] |
| Example R12 | 5. [symbol] | J-1 | 0.01 | K-1 | 19.7 | 3.1 | 4.5 | [symbol] .27 | [symbol] |
| Example R13 | [symbol] . [symbol] | J-1 | 0.01 | K-1 | 19. [symbol] | 3.1 | 4.5 | [symbol] .27 | [symbol] |
| Example R14 | [symbol] .0 | J-1 | 0.01 | K-1 | 19.7 | [symbol] | [symbol] | [symbol] .27 | [symbol] |
| Example R15 | 5.0 | J-1 | 0.01 | K-1 | 19.7 | 3. [symbol] | [symbol] | [symbol] .27 | [symbol] |
| Example R16 | [symbol] . [symbol] | J-1 | 0.01 | K-1 | 19.7 | [symbol] | 4.5 | [symbol] .27 | [symbol] |
| Example R17 | [symbol] . [symbol] | J-1 | 0.01 | K-1 | 1 [symbol] . [symbol] | 3. [symbol] | 4.5 | [symbol] .27 | [symbol] |
| Example R18 | [symbol] . [symbol] | J-1 | 0.01 | K-1 | 19.7 | [symbol] | [symbol] | [symbol] .27 | [symbol] |
| Example R19 | [symbol] .0 | J-1 | 0.01 | K-1 | 19.7 | 3. [symbol] | 4.5 | [symbol] .27 | [symbol] |
| Example R20 | 5.0 | J-1 | 0.01 | K-1 | [symbol] | 3.1 | 4.5 | [symbol] .27 | [symbol] |
| Example R21 | 5.0 | J-1 | 0.01 | K-1 | 19.7 | [symbol] | 4.3 | [symbol] .27 | [symbol] |
| Example R22 | [symbol] .0 | J-1 | 0.01 | K-1 | 19.7 | 3.1 | 4.5 | [symbol] .27 | [symbol] |
| Example R23 | 5.0 | J-1 | 0.01 | K-1 | 19.7 | 3.1 | 4.5 | [symbol] .27 | [symbol] |
| Example R24 | 5.0 | J-1 | 0.01 | K-1 | 19.3 | 5.4 | 2.8 | [symbol] .30 | [symbol] |
| Example R25 | [symbol] .0 | J-1 | 0.01 | K-1 | 19.3 | 4.3 | 3.4 | [symbol] .29 | [symbol] |
| Example R26 | 5.0 | J-1 | 0.01 | K-1 | 19.7 | 3. [symbol] | [symbol] | [symbol] .39 | [symbol] |
| Example R27 | 5.0 | J-1 | 0.01 | K-1 | 19.7 | 2.7 | 5.1 | [symbol] .25 | [symbol] |
| Example R28 | [symbol] .0 | J-1 | 0.01 | K-1 | 19.7 | [symbol] | 6.2 | [symbol] .34 | [symbol] |
| Example R29 | 5.0 | J-1 | 0.01 | K-1 | 19.7 | 1.5 | [symbol] | [symbol] | [symbol] |
| Example R30 | 5.0 | J-1 | 0.01 | K-1 | 19.7 | 1.3 | 8.4 | [symbol] .20 | [symbol] |

[symbol]

indicates data missing or illegible when filed

TABLE 8

| | Dispersion | | | | Polymerizable | | Photopolymerization | | | | |
|---|---|---|---|---|---|---|---|---|---|---|---|
| | liquid | | Resin | | monomer | | initiator | | Additive | | |
| | | Part by | | Part by | | Part by | | Part by | | Part by | Surfactant |
| | Type | mass | Type | mass | Type | mass | Type | mass | Type | mass | Type |
| Example R31 | Dispersion | 65 | A-3 | [symbol] | M- [symbol] | [symbol] .7 | G- [symbol] | 0.6 | | | I-1 |
| | liquid R5 | | | | | | | | | | |
| Example R32 | Dispersion | 65 | A- [symbol] | 7.3 | M-3 | 2. [symbol] | G-2 | 0.6 | | | I-1 |
| | liquid R [symbol] | | | | | | | | | | |
| Example R33 | Dispersion | 65 | A-3 | [symbol] | M-3 | 2.6 | G-2 | 0.7 | | | I-1 |
| | liquid R5 | | | | | | | | | | |
| Example R34 | Dispersion | 6 [symbol] | A-3 | [symbol] | M-3 | 2.4 | G- [symbol] | 0. [symbol] | | | I-1 |
| | liquid R [symbol] | | | | | | | | | | |
| Example R35 | Dispersion | 65 | A-3 | 7.0 | M-3 | 2.2 | G-2 | [symbol] .1 | | | I-1 |
| | liquid R5 | | | | | | | | | | |
| Example R36 | Dispersion | 65 | A- [symbol] | [symbol] | M- [symbol] | 2. [symbol] | G-2 | [symbol] . [symbol] | | | I-1 |
| | liquid R5 | | | | | | | | | | |
| Example R37 | Dispersion | 6 [symbol] | A-3 | 7. [symbol] | M-3 | [symbol] .8 | G-2 | [symbol] .5 | | | I-1 |
| | liquid R [symbol] | | | | | | | | | | |
| Example R38 | Dispersion | [symbol] | A-3 | [symbol] | M-1 | [symbol] .5 | G- [symbol] | 0.8 | | | I-1 |
| | liquid R5 | | | | | | | | | | |
| Example R39 | Dispersion | 6 [symbol] | A-3 | [symbol] | M-2 | [symbol] | G- [symbol] | 0. [symbol] | | | I-1 |
| | liquid R [symbol] | | | | | | | | | | |
| Example R40 | Dispersion | [symbol] | A-3 | 7.0 | M-4 | 2.5 | G- [symbol] | 0.8 | | | I-1 |
| | liquid R [symbol] | | | | | | | | | | |
| Example R41 | Dispersion | 65 | A-3 | [symbol] | M-6 | 2.5 | G- [symbol] | 0.8 | | | I-1 |
| | liquid R5 | | | | | | | | | | |
| Example R42 | Dispersion | 6 [symbol] | A-3 | [symbol] | M- [symbol] | [symbol] | G- [symbol] | 0. [symbol] | | | I-1 |
| | liquid [symbol] | | | | | | | | | | |
| Example R43 | Dispersion | 65 | A-3 | [symbol] | M- [symbol] | 2.5 | G- [symbol] | 0.8 | | | I-1 |
| | liquid [symbol] 5 | | | | | | | | | | |
| Example R44 | Dispersion | 65 | A- [symbol] | [symbol] | M- [symbol] | [symbol] | G- [symbol] | 0.8 | | | I-1 |
| | liquid R5 | | | | | | | | | | |
| Example R45 | Dispersion | 63 | A-3 | 7. [symbol] | M-3 | 2. [symbol] | G-3 | 0. [symbol] | | | I-1 |
| | liquid [symbol] | | | | | | | | | | |
| Example R46 | Dispersion | 6 [symbol] | A-3 | 7. [symbol] | M-3 | 2.5 | G-4 | 0.8 | | | I-1 |
| | liquid R5 | | | | | | | | | | |
| Example R47 | Dispersion | 63 | A-3 | 7. [symbol] | M-3 | 2. [symbol] | G- [symbol] | 0.4 | | | I-1 |
| | liquid R5 | | | | | | G- [symbol] | 0.4 | | | |
| Example R48 | Dispersion | 63 | A-3 | 7. [symbol] | M-3 | 2. [symbol] | G- [symbol] | 0.4 | | | I-1 |
| | liquid R3 | | | | | | G-c [symbol] | 0.4 | | | |
| Example R49 | Dispersion | 63 | A-3 | 7. [symbol] | M-3 | 2. [symbol] | G-1 | 0.4 | | | I-1 |
| | liquid R3 | | | | | | G-c2 | 0.4 | | | |
| Example R50 | Dispersion | 63 | A-3 | 7. [symbol] | M-3 | 2. [symbol] | G-1 | 0.4 | | | I-1 |
| | liquid R [symbol] | | | | | | G-c3 | 0.4 | | | |
| Example R51 | Dispersion | 63 | A-3 | 7. [symbol] | M-3 | 1.25 | G- [symbol] | 0.8 | | | I-1 |
| | liquid R [symbol] | | | | M-4 | 1.35 | | | | | |
| Example R52 | Dispersion | 65 | A-3 | 7. [symbol] | M-3 | 1.25 | G- [symbol] | 0.8 | | | I-1 |
| | liquid R [symbol] | | | | M-7 | 1.25 | | | | | |
| Example R53 | Dispersion | 65 | A-3 | 7. [symbol] | M-3 | 1.25 | G- [symbol] | 0. [symbol] | | | I-1 |
| | liquid R [symbol] | | | | M-8 | 1.25 | | | | | |
| Example R54 | Dispersion | 65 | A-3 | 7. [symbol] | M-1 | 1.25 | G- [symbol] | 0.8 | | | I-1 |
| | liquid R [symbol] | | | | M-3 | 1.25 | | | | | |
| Example R1 | Dispersion | 63 | A-3 | 7. [symbol] | M-3 | [symbol] | G-C [symbol] | 0. [symbol] | | | I-1 |
| | liquid R5 | | | | | | | | | | |
| Example R2 | Dispersion | 65 | A- [symbol] | 7. [symbol] | M- [symbol] | 2.6 | G-C [symbol] | 0.7 | | | I-1 |
| | liquid R5 | | | | | | | | | | |
| Example R3 | Dispersion | 6 [symbol] | A- [symbol] | 7. [symbol] | M-3 | 2.6 | G-c1 | 0.3 [symbol] | | | I-1 |
| | liquid R [symbol] | | | | | | G-c2 | 0.3 [symbol] | | | |
| Example R4 | Dispersion | [symbol] | A-3 | 7. [symbol] | M-3 | 3.8 | G-2 | 0. [symbol] | | | I-1 |
| | liquid R5 | | | | | | | | | | |
| Example R5 | Dispersion | [symbol] | A- [symbol] | 16.0 | M- [symbol] | 0.4 | G- [symbol] | 1.1 | | | I-1 |
| | liquid R5 | | | | | | | | | | |

| | | Polymerization | | | | | | | Coloring |
|---|---|---|---|---|---|---|---|---|---|
| | Surfactant | inhibitor | | Solvent | | | Photopolymerization | | material |
| | Part by | | Part by | | Part by | M/I | initiator amount | M/P | concentration |
| | mass | Type | mass | Type | mass | ratio | (% by mass) | ratio | (% by mass) |
| Example R31 | 5.0 | J-1 | 0.01 | K-1 | 19.3 | 5.4 | 2.8 | 0.30 | 51 |
| Example R32 | [symbol] .0 | J-1 | 0.01 | K-1 | 19.3 | 4. [symbol] | 3.4 | 0.29 | 51 |
| Example R33 | 5.0 | J-1 | 0.01 | K-1 | 19.7 | 3.7 | 3. [symbol] | 0.29 | 51 |
| Example R34 | [symbol] .0 | J-1 | 0.01 | K-1 | 19.7 | 2. [symbol] | [symbol] .1 | 0.26 | 51 |
| Example R35 | [symbol] .0 | J-1 | 0.01 | K-1 | 19.7 | [symbol] . [symbol] | [symbol] . [symbol] | 0.24 | 51 |
| Example R36 | 5. [symbol] | J-1 | 0.01 | K-1 | 19.7 | 1. [symbol] | [symbol] . [symbol] | 0. [symbol] 2 | 51 |
| Example R37 | 5.0 | J-1 | 0.01 | K-1 | 19.7 | 1.2 | 8.4 | 0.2 [symbol] | 51 |
| Example R38 | 5. [symbol] | J-1 | 0.01 | K-1 | 1 [symbol] . [symbol] | [symbol] . [symbol] | 4.3 | 0.27 | 51 |
| Example R39 | 5.0 | J-1 | 0.01 | K-1 | 19.7 | [symbol] .1 | 4.5 | 0.2 [symbol] | 51 |
| Example R40 | 5.0 | J-1 | 0.01 | K-1 | 19.7 | 3.1 | 4.5 | 0.27 | 51 |
| Example R41 | 5. [symbol] | J-1 | 0.01 | K-1 | 19.7 | 3.1 | 4.3 | 0.2 [symbol] | 51 |
| Example R42 | 5.0 | J-1 | 0.01 | K-1 | 19.7 | [symbol] .1 | 4.5 | 0.27 | 51 |
| Example R43 | 5. [symbol] | J-1 | 0.01 | K-1 | 19.7 | 3.1 | 4.3 | 0.27 | 51 |
| Example R44 | 5. [symbol] | J-1 | 0.01 | K-1 | 19.7 | 3.1 | 4.5 | 0.27 | 51 |
| Example R45 | [symbol] . [symbol] | J-1 | 0.01 | K-1 | 19.7 | 3.5 | 4.3 | 0.27 | 51 |
| Example R46 | 5.0 | J-1 | 0.01 | K-1 | 19.7 | 3.1 | 4. [symbol] | 0.27 | 51 |
| Example R47 | 5. [symbol] | J-1 | 0.01 | K-1 | 19.7 | [symbol] .1 | 4.5 | 0.27 | 51 |
| Example R48 | [symbol] . [symbol] | J-1 | 0.01 | K-1 | 19.7 | 3.1 | 4.5 | 0.27 | 51 |
| Example R49 | [symbol] .0 | J-1 | 0.01 | K-1 | 19.7 | 3.1 | 4.5 | 0.27 | 51 |
| Example R50 | [symbol] . [symbol] | J-1 | 0.01 | K-1 | 19.7 | [symbol] .1 | 4.5 | 0.27 | 51 |
| Example R51 | [symbol] .0 | J-1 | 0.01 | K-1 | 19.7 | 3.1 | 4.5 | 0.27 | 51 |
| Example R52 | 5.0 | J-1 | 0.01 | K-1 | 19.7 | 3.1 | 4.5 | 0.27 | 51 |
| Example R53 | 5.0 | J-1 | 0.01 | K-1 | 19.7 | 3.1 | 4.5 | 0.27 | 51 |
| Example R54 | 5.0 | J-1 | 0.01 | K-1 | 19.7 | 3.1 | 4.5 | 0.27 | 51 |
| Example R1 | 5.0 | J-1 | 0.01 | K-1 | 19.7 | [symbol] . [symbol] | 3.9 | 0.29 | 51 |
| Example R2 | 5.0 | J-1 | 0.01 | K-1 | 19. [symbol] | [symbol] .7 | 3.8 | 0.29 | 49 |
| Example R3 | 5.0 | J-1 | 0.01 | K-1 | 19.7 | [symbol] .7 | [symbol] . [symbol] | 0.29 | 51 |
| Example R4 | 5.0 | J-1 | 0.01 | K-1 | 19.7 | 5.6 | 2. [symbol] | 0.31 | 51 |
| Example R5 | 5. [symbol] | J-1 | 0.01 | K-1 | 1 [symbol] .5 | [symbol] .4 | 6. [symbol] | 0.04 | 51 |

[symbol]

indicates data missing or illegible when filed

TABLE 9

| | Dispersion | | | | Polymerizable | | Photopolymerization | | | | |
|---|---|---|---|---|---|---|---|---|---|---|---|
| | liquid | | Resin | | monomer | | initiator | | Additive | | |
| | | Part by | | Part by | | Part by | | Part by | | Part by | Surfactant |
| | Type | mass | Type | mass | Type | mass | Type | mass | Type | mass | Type |
| Example G1 | Dispersion | 65 | A-3 | 7.0 | M-3 | 2.5 | G-1 | 0.8 | | | I-1 |
| | liquid G1 | | | | | | | | | | |
| Example G2 | Dispersion | 65 | A-3 | 7.0 | M-3 | 2.5 | G-1 | 0. [symbol] | | | I-1 |
| | liquid G2 | | | | | | | | | | |
| Example G3 | Dispersion | 6 [symbol] | A-3 | [symbol] .0 | M-3 | 2. [symbol] | G-1 | 0.8 | | | I-1 |
| | liquid G3 | | | | | | | | | | |
| Example G4 | Dispersion | 65 | A- [symbol] | 7.0 | M- [symbol] | 2.5 | G-1 | 0.8 | | | I-1 |
| | liquid G4 | | | | | | | | | | |
| Example G5 | Dispersion | 65 | A- [symbol] | 7.0 | M- [symbol] | 2.5 | G-1 | 0.8 | | | I-1 |
| | liquid G5 | | | | | | | | | | |
| Example G6 | Dispersion | 65 | A-3 | 7.0 | M-3 | 2.5 | G-1 | 0. [symbol] | | | I-1 |
| | liquid G6 | | | | | | | | | | |
| Example G7 | Dispersion | 65 | A-3 | 7.0 | M-3 | 2.5 | G-1 | 0.8 | | | I-1 |
| | liquid G7 | | | | | | | | | | |
| Example G8 | Dispersion | 6 [symbol] | A-3 | [symbol] .0 | M-3 | 2.5 | G-1 | 0.8 | | | I-1 |
| | liquid G8 | | | | | | | | | | |
| Example G9 | Dispersion | 6 [symbol] | A- [symbol] | 7.0 | M- [symbol] | 2.5 | G-1 | 0.8 | | | I-1 |
| | liquid G9 | | | | | | | | | | |
| Example G10 | Dispersion | 65 | A-3 | 7.0 | M-3 | 2.5 | G-1 | 0.8 | | | I-1 |
| | liquid G10 | | | | | | | | | | |
| Example G11 | Dispersion | 65 | A-3 | 7.0 | M-3 | 2.5 | G-1 | 0.8 | | | I-1 |
| | liquid G11 | | | | | | | | | | |
| Example G12 | Dispersion | 6 [symbol] | A-3 | [symbol] .0 | M-3 | 2.5 | G-1 | 0. [symbol] | | | I-1 |
| | liquid G12 | | | | | | | | | | |
| Example G13 | Dispersion | 6 [symbol] | A-3 | 7.0 | M- [symbol] | 2. [symbol] | G-1 | 0.8 | | | I-1 |
| | liquid G13 | | | | | | | | | | |
| Example G14 | Dispersion | 65 | A-3 | 7.0 | M-3 | 2.5 | G-1 | 0.8 | | | I-1 |
| | liquid G14 | | | | | | | | | | |
| Example G15 | Dispersion | 65 | A-3 | 7.0 | M- [symbol] | 2.5 | G-1 | 0.8 | | | I-1 |
| | liquid G15 | | | | | | | | | | |
| Example G16 | Dispersion | 65 | A-3 | [symbol] .0 | M-3 | 2.5 | G-1 | 0.8 | | | I-1 |
| | liquid G16 | | | | | | | | | | |
| Example G17 | Dispersion | 6 [symbol] | A-3 | 7.0 | M-3 | 2.5 | G-1 | 0.8 | | | I-1 |
| | liquid G17 | | | | | | | | | | |
| Example G18 | Dispersion | 65 | A- [symbol] | 7.0 | M- [symbol] | 2.5 | G-1 | 0.8 | | | I-1 |
| | liquid G18 | | | | | | | | | | |
| Example G19 | Dispersion | 65 | A-3 | 7.0 | M- [symbol] | 2.5 | G-1 | 0.8 | | | I-1 |
| | liquid G19 | | | | | | | | | | |
| Example G20 | Dispersion | 65 | A-3 | 7.0 | M-3 | 2.5 | G-1 | [symbol] . [symbol] | | | I-1 |
| | liquid G20 | | | | | | | | | | |
| Example G21 | Dispersion | 6 [symbol] | A-3 | 7.0 | M-3 | 2. [symbol] | G-1 | 0.8 | | | I-1 |
| | liquid G21 | | | | | | | | | | |
| Example G22 | Dispersion | 6 [symbol] | A- [symbol] | 7.0 | M-3 | 2.5 | G-1 | 0.8 | | | I-1 |
| | liquid G22 | | | | | | | | | | |
| Example G23 | Dispersion | 65 | A- [symbol] | 7.0 | M-3 | 2.5 | G-1 | 0.8 | | | I-1 |
| | liquid G23 | | | | | | | | | | |
| Example G24 | Dispersion | 65 | A-3 | 7. [symbol] | M- [symbol] | 2.7 | G-1 | 0.5 | | | I-1 |
| | liquid G6 | | | | | | | | | | |
| Example G25 | Dispersion | 65 | A-3 | 7. [symbol] | M-3 | 2.6 | G-1 | 0.6 | | | I-1 |
| | liquid G6 | | | | | | | | | | |
| Example G26 | Dispersion | 6 [symbol] | A-3 | 7. [symbol] | M-3 | 2. [symbol] | G-1 | 0.7 | | | I-1 |
| | liquid G6 | | | | | | | | | | |
| Example G27 | Dispersion | 6 [symbol] | A- [symbol] | 7. [symbol] | M-3 | 2.4 | G-1 | 0.9 | | | I-1 |
| | liquid G6 | | | | | | | | | | |
| Example G28 | Dispersion | 65 | A-3 | 7. [symbol] | M- [symbol] | 2.2 | G-1 | [symbol] .1 | | | I-1 |
| | liquid G6 | | | | | | | | | | |
| Example G29 | Dispersion | 65 | A-3 | 7. [symbol] | M-3 | 2.0 | G-1 | [symbol] . [symbol] | | | I-1 |
| | liquid G6 | | | | | | | | | | |
| Example G30 | Dispersion | 65 | A-3 | 7. [symbol] | M-3 | 1.8 | G-1 | [symbol] .5 | | | I-1 |
| | liquid G6 | | | | | | | | | | |

| | | | | Polymerization | | | | | Coloring |
|---|---|---|---|---|---|---|---|---|---|
| | Surfactant | Solvent | | inhibitor | | | Photopolymerization | | material |
| | Part by | | Part by | | Part by | M/I | initiator amount | M/P | concentration |
| | mass | Type | mass | Type | mass | ratio | (% by mass) | ratio | (% by mass) |
| Example G1 | 5. [symbol] | J-1 | 0.01 | K-1 | 19.7 | 3.1 | 4.5 | 0.27 | 51 |
| Example G2 | 5. [symbol] | J-1 | 0.01 | K-1 | 19.7 | 3.1 | 4.5 | 0.27 | 51 |
| Example G3 | 5.0 | J-1 | 0.01 | K-1 | 19.7 | 3.1 | 4.5 | 0.27 | 51 |
| Example G4 | 5.0 | J-1 | 0.01 | K-1 | 19.7 | 3.1 | 4.5 | 0.27 | 51 |
| Example G5 | 5.0 | J-1 | 0.01 | K-1 | 19.7 | 3.1 | 4.5 | 0.27 | 51 |
| Example G6 | 5. [symbol] | J-1 | 0.01 | K-1 | 19.7 | 3.1 | 4.5 | 0.27 | 51 |
| Example G7 | 5.0 | J-1 | 0.01 | K-1 | 19.7 | [symbol] .1 | 4.5 | 0.27 | 51 |
| Example G8 | 5.0 | J-1 | 0.01 | K-1 | 19.7 | 3.1 | 4.5 | 0.27 | 51 |
| Example G9 | 5.0 | J-1 | 0.01 | K-1 | 19.7 | 3.1 | 4.5 | 0. [symbol] 7 | 51 |
| Example G10 | 5.0 | J-1 | 0.01 | K-1 | 19.7 | 3.1 | 4.5 | 0.27 | 51 |
| Example G11 | 5.0 | J-1 | 0.01 | K-1 | 19.7 | [symbol] .1 | 4.5 | 0.27 | 51 |
| Example G12 | 5.0 | J-1 | 0.01 | K-1 | 19.7 | 3.1 | 4.5 | 0.27 | 51 |
| Example G13 | 5.0 | J-1 | 0.01 | K-1 | 19.7 | 3.1 | 4.5 | 0. [symbol] 7 | 51 |
| Example G14 | [symbol] .0 | J-1 | [symbol] . [symbol] 1 | K-1 | 19.7 | 3.1 | 4.5 | 0.27 | 51 |
| Example G15 | 5. [symbol] | J-1 | 0.01 | K-1 | 19.7 | 3.1 | 4.5 | 0.27 | 51 |
| Example G16 | 5. [symbol] | J-1 | 0.01 | K-1 | 19. [symbol] | 3.1 | 4.5 | 0.27 | 51 |
| Example G17 | 5.0 | J-1 | 0.01 | K-1 | 19.7 | 3.1 | 4.5 | 0.27 | 51 |
| Example G18 | 5.0 | J-1 | 0.01 | K-1 | 19.7 | 3.1 | 4.5 | 0.27 | 51 |
| Example G19 | 5.0 | J-1 | 0.01 | K-1 | 19.7 | 3.1 | 4.5 | 0.27 | 51 |
| Example G20 | 5. [symbol] | J-1 | 0.01 | K-1 | 19. [symbol] | 3.1 | 4.5 | 0.27 | 51 |
| Example G21 | 5.0 | J-1 | 0.01 | K-1 | 19.7 | 3.1 | 4.5 | 0.27 | 51 |
| Example G22 | 5.0 | J-1 | 0.01 | K-1 | 19.7 | 3.1 | 4.5 | 0.27 | 51 |
| Example G23 | 5.0 | J-1 | 0.01 | K-1 | 19.7 | 3.1 | 4. [symbol] | 0.27 | 51 |
| Example G24 | 5.0 | J-1 | 0.01 | K-1 | 19. [symbol] | 5.4 | 2.8 | 0.30 | 51 |
| Example G25 | 5.0 | J-1 | 0.01 | K-1 | 19. [symbol] | 4.3 | 3.4 | 0.29 | 51 |
| Example G26 | 5.0 | J-1 | 0.01 | K-1 | 19.7 | [symbol] . [symbol] | 3.9 | 0.29 | 51 |
| Example G27 | 5.0 | J-1 | 0.01 | K-1 | 19.7 | [symbol] .7 | 5.1 | 0. [symbol] | 51 |
| Example G28 | 5.0 | J-1 | 0.01 | K-1 | 19.7 | [symbol] .0 | 6.2 | 0. [symbol] 4 | 51 |
| Example G29 | 5. [symbol] | J-1 | 0.01 | K-1 | 19.7 | [symbol] . [symbol] | 7. [symbol] | 0.2 [symbol] | 51 |
| Example G30 | 5.0 | J-1 | 0.01 | K-1 | 19.7 | [symbol] . [symbol] | 8.4 | 0.20 | 51 |

[symbol]

indicates data missing or illegible when filed

TABLE 10

| | Dispersion | | | | Polymerizable | | Photopolymerization | | | | |
|---|---|---|---|---|---|---|---|---|---|---|---|
| | liquid | | Resin | | monomer | | initiator | | Additive | | |
| | | Part by | | Part by | | Part by | | Part by | | Part by | Surfactant |
| | Type | mass | Type | mass | Type | mass | Type | mass | Type | mass | Type |
| Example G31 | Dispersion | 65 | A-3 | 7.5 | M-3 | 2.7 | G-2 | 0.5 | | | I-1 |
| | liquid G6 | | | | | | | | | | |
| Example G32 | Dispersion | 65 | A-3 | 7.5 | M-3 | 2.6 | G-2 | 0.6 | | | I-1 |
| | liquid G6 | | | | | | | | | | |
| Example G33 | Dispersion | 65 | A-3 | 7.0 | M-3 | 2.6 | G-2 | 0.7 | | | I-1 |
| | liquid G6 | | | | | | | | | | |
| Example G34 | Dispersion | 65 | A- [symbol] | 7.0 | M-3 | 2.4 | G-2 | 0.9 | | | I-1 |
| | liquid G6 | | | | | | | | | | |
| Example G35 | Dispersion | 65 | A-3 | 7.0 | M-3 | 2.2 | G- [symbol] | 1.1 | | | I-1 |
| | liquid G6 | | | | | | | | | | |
| Example G36 | Dispersion | 65 | A-3 | 7.0 | M-3 | 2.0 | G-2 | 1.3 | | | I-1 |
| | liquid G6 | | | | | | | | | | |
| Example G37 | Dispersion | 65 | A-3 | 7.0 | M-3 | 1.8 | G-2 | 1.5 | | | I-1 |
| | liquid G6 | | | | | | | | | | |
| Example G38 | Dispersion | 65 | A-3 | 7.0 | M-1 | 2.5 | G-1 | 0.8 | | | I-1 |
| | liquid G6 | | | | | | | | | | |
| Example G39 | Dispersion | 65 | A-3 | 7.0 | M-2 | 2. [symbol] | G-1 | 0.8 | | | I-1 |
| | liquid G6 | | | | | | | | | | |
| Example G40 | Dispersion | 65 | A-3 | 7.0 | M-4 | 2. [symbol] | G-1 | 0.8 | | | I-1 |
| | liquid G6 | | | | | | | | | | |
| Example G41 | Dispersion | 65 | A-3 | 7.0 | M-5 | 2. [symbol] | G-1 | 0.8 | | | I-1 |
| | liquid G6 | | | | | | | | | | |
| Example G42 | Dispersion | 65 | A- [symbol] | 7.0 | M-6 | 2.5 | G-1 | 0.8 | | | I-1 |
| | liquid G6 | | | | | | | | | | |
| Example G43 | Dispersion | 65 | A- [symbol] | 7.0 | M-7 | 2.5 | G-1 | 0.8 | | | I-1 |
| | liquid G6 | | | | | | | | | | |
| Example G44 | Dispersion | 65 | A-3 | 7.0 | M-8 | 2.5 | G-1 | 0.8 | | | I-1 |
| | liquid G6 | | | | | | | | | | |
| Comparative | Dispersion | 65 | A-3 | 7.0 | M-3 | 2.6 | G-c1 | 0.7 | | | I-1 |
| Example G1 | liquid G6 | | | | | | | | | | |
| Comparative | Dispersion | 65 | A-3 | 7.0 | M- [symbol] | 2.6 | G-c1 | 0.7 | H-1 | 0. [symbol] | I-1 |
| Example G2 | liquid G6 | | | | | | | | | | |
| Comparative | Dispersion | 6 [symbol] | A-3 | 7.0 | M-3 | 2.6 | G-c1 | 0.35 | | | I-1 |
| Example G3 | liquid G6 | | | | | | G-c2 | 0.36 | | | |
| Comparative | Dispersion | 65 | A-3 | 7.0 | M-3 | 2.8 | G-2 | 0.5 | | | I-1 |
| Example G4 | liquid G6 | | | | | | | | | | |
| Comparative | Dispersion | 65 | A- [symbol] | 16.0 | M-3 | 0.4 | G-2 | 1.1 | | | I-1 |
| Example G5 | liquid G6 | | | | | | | | | | |

| | | Polymerization | | | | | | | Coloring |
|---|---|---|---|---|---|---|---|---|---|
| | Surfactant | inhibitor | | Solvent | | | Photopolymerization | | material |
| | Part by | | Part by | | Part by | M/i | initiator amount | M/P | concentration |
| | mass | Type | mass | Type | mass | ratio | (% by mass) | ratio | (% by mass) |
| Example G31 | 5.0 | J-1 | 0.01 | K-1 | 19.3 | 5.4 | 2.8 | 0.30 | 51 |
| Example G32 | 5.0 | J-1 | 0.01 | K-1 | 19.3 | 4.3 | 3.4 | 0.29 | 51 |
| Example G33 | 5.0 | J-1 | 0.01 | K-1 | 19.7 | 3.7 | 3.9 | 0.29 | 51 |
| Example G34 | 5.0 | J-1 | 0.01 | K-1 | 19.7 | 2.7 | [symbol] .1 | 0.26 | 51 |
| Example G35 | 5.0 | J-1 | 0.01 | K-1 | 19.7 | 2.0 | 6.2 | 0.24 | 51 |
| Example G36 | 5.0 | J-1 | 0.01 | K-1 | 19.7 | 1.5 | 7.3 | 0.22 | 51 |
| Example G37 | 5.0 | J-1 | 0.01 | K-1 | 19.7 | 1.2 | 8.4 | 0.20 | 51 |
| Example G38 | 5.0 | J-1 | 0.01 | K-1 | 19.7 | 3.1 | 4.5 | 0.27 | 51 |
| Example G39 | 5.0 | J-1 | 0.01 | K-1 | 19.7 | 3.1 | 4.5 | 0.27 | 51 |
| Example G40 | 5.0 | J-1 | 0.01 | K-1 | 19.7 | 3.1 | 4.5 | 0.27 | 51 |
| Example G41 | 5.0 | J-1 | 0.01 | K-1 | 19.7 | 3.1 | 4.5 | 0.27 | 51 |
| Example G42 | 5.0 | J-1 | 0.01 | K-1 | 19.7 | 3.1 | 4.5 | 0.27 | 51 |
| Example G43 | [symbol] .0 | J-1 | 0.01 | K-1 | 19.7 | [symbol] .1 | 4.5 | 0.27 | 51 |
| Example G44 | 5.0 | J-1 | 0.01 | K-1 | 19.7 | 3.1 | 4.5 | 0.27 | 51 |
| Comparative | 5.0 | J-1 | 0.01 | K-1 | 19.7 | 3.7 | 3.9 | 0.29 | 51 |
| Example G1 | | | | | | | | | |
| Comparative | 5.0 | J-1 | 0.01 | K-1 | 19.0 | 3.7 | [symbol] .8 | 0.29 | 49 |
| Example G2 | | | | | | | | | |
| Comparative | 5.0 | J-1 | 0.01 | K-1 | 19.7 | 3.7 | 3.9 | 0.29 | 51 |
| Example G3 | | | | | | | | | |
| Comparative | 5.0 | J-1 | 0.01 | K-1 | 19.7 | 5.6 | 2.8 | 0.31 | 51 |
| Example G4 | | | | | | | | | |
| Comparative | 5.0 | J-1 | 0.01 | K-1 | 12.5 | 0.4 | 6.2 | 0.04 | 51 |
| Example G5 | | | | | | | | | |

[symbol]

indicates data missing or illegible when filed

TABLE 11

| | Dispersion | | | | Polymerizable | | Photopolymerization | | | | |
|---|---|---|---|---|---|---|---|---|---|---|---|
| | liquid | | Resin | | monomer | | initiator | | Additive | | |
| | | Part by | | Part by | | Part by | | Part by | | Part by | Surfactant |
| | Type | mass | Type | mass | Type | mass | Type | mass | Type | mass | Type |
| Example B1 | Dispersion | 65 | A-3 | 7.0 | M-3 | 2.5 | G-1 | 0.8 | | | I-1 |
| | liquid B1 | | | | | | | | | | |
| Example B2 | Dispersion | 6 [symbol] | A-3 | 7.0 | M-3 | 2.5 | G-1 | 0.8 | | | I-1 |
| | liquid B2 | | | | | | | | | | |
| Example B3 | Dispersion | 65 | A-3 | 7.0 | M-3 | 2.5 | G-1 | 0.8 | | | I-1 |
| | liquid B3 | | | | | | | | | | |
| Example B4 | Dispersion | 65 | A-3 | 7.0 | M-3 | 2.5 | G-1 | 0.8 | | | I-1 |
| | liquid B4 | | | | | | | | | | |
| Example B5 | Dispersion | 65 | A-3 | 7.0 | M-3 | 2.5 | G-1 | 0. [symbol] | | | I-1 |
| | liquid B5 | | | | | | | | | | |
| Example B6 | Dispersion | 65 | A-3 | 7.0 | M-3 | 2.5 | G-1 | 0.8 | | | I-1 |
| | liquid B6 | | | | | | | | | | |
| Example B7 | Dispersion | 65 | A-3 | 7.0 | M-3 | 2.5 | G-1 | 0.8 | | | I-1 |
| | liquid B7 | | | | | | | | | | |
| Example B8 | Dispersion | 65 | A-3 | 7.0 | M-3 | [symbol] . [symbol] | G-1 | 0.8 | | | I-1 |
| | liquid B8 | | | | | | | | | | |
| Example B9 | Dispersion | 65 | A-3 | 7.0 | M-3 | 2.5 | G-1 | 0.8 | | | I-1 |
| | liquid B9 | | | | | | | | | | |
| Example B10 | Dispersion | 65 | A-3 | 7.0 | M-3 | 2.5 | G-1 | 0.8 | | | I-1 |
| | liquid B10 | | | | | | | | | | |
| Example B11 | Dispersion | 65 | A-3 | 7.0 | M-3 | 2.5 | G-1 | 0. [symbol] | | | I-1 |
| | liquid B11 | | | | | | | | | | |
| Example B12 | Dispersion | 65 | A-3 | 7.0 | M-3 | 2.5 | G-1 | 0.8 | | | I-1 |
| | liquid B12 | | | | | | | | | | |
| Example B13 | Dispersion | 65 | A-3 | 7.0 | M-3 | 2.5 | G-1 | 0.8 | | | I-1 |
| | liquid B13 | | | | | | | | | | |
| Example B14 | Dispersion | 65 | A-3 | 7.0 | M-3 | 2.5 | G-1 | 0.8 | | | I-1 |
| | liquid B14 | | | | | | | | | | |
| Example B15 | Dispersion | 65 | A-3 | 7.0 | M-3 | 2.5 | G-1 | 0.8 | | | I-1 |
| | liquid B15 | | | | | | | | | | |
| Example B16 | Dispersion | 65 | A-3 | 7.0 | M-3 | 2.5 | G-1 | 0.8 | | | I-1 |
| | liquid B16 | | | | | | | | | | |
| Example B17 | Dispersion | 65 | A-3 | 7.0 | M-3 | 2.5 | G-1 | 0.8 | | | I-1 |
| | liquid B17 | | | | | | | | | | |
| Example B18 | Dispersion | 65 | A-3 | 7.0 | M-3 | 2.5 | G-1 | 0.8 | | | I-1 |
| | liquid B18 | | | | | | | | | | |
| Example B19 | Dispersion | 65 | A-3 | 7.0 | M-3 | 2.5 | G-1 | 0.8 | | | I-1 |
| | liquid B19 | | | | | | | | | | |
| Example B20 | Dispersion | 65 | A-3 | 7.5 | M-3 | 2.7 | G-1 | 0.5 | | | I-1 |
| | liquid B3 | | | | | | | | | | |
| Example B21 | Dispersion | 65 | A-3 | 7.5 | M-3 | 2.6 | G-1 | 0. [symbol] | | | I-1 |
| | liquid B3 | | | | | | | | | | |
| Example B22 | Dispersion | 65 | A-3 | 7.0 | M-3 | 2.6 | G-1 | 0.7 | | | I-1 |
| | liquid B3 | | | | | | | | | | |
| Example B23 | Dispersion | 65 | A-3 | 7.0 | M-3 | 2.4 | G-1 | 0.9 | | | I-1 |
| | liquid B3 | | | | | | | | | | |
| Example B24 | Dispersion | 65 | A-3 | 7.0 | M-3 | 2.2 | G-1 | 1.1 | | | I-1 |
| | liquid B3 | | | | | | | | | | |
| Example B25 | Dispersion | 65 | A-3 | 7.0 | M-3 | 2.0 | G-1 | 1.3 | | | I-1 |
| | liquid B3 | | | | | | | | | | |
| Example B26 | Dispersion | 65 | A-3 | 7.0 | M-3 | 1.8 | G-1 | 1.5 | | | I-1 |
| | liquid B3 | | | | | | | | | | |
| Example B27 | Dispersion | 65 | A-3 | 7.5 | M-3 | 2.7 | G-2 | 0.5 | | | I-1 |
| | liquid B3 | | | | | | | | | | |
| Example B28 | Dispersion | 65 | A-3 | 7.5 | M-3 | 2.6 | G-2 | 0.6 | | | I-1 |
| | liquid B3 | | | | | | | | | | |
| Example B29 | Dispersion | 65 | A-3 | 7.0 | M-3 | 2.6 | G-2 | 0.7 | | | I-1 |
| | liquid B3 | | | | | | | | | | |
| Example B30 | Dispersion | 65 | A-3 | 7.0 | M-3 | 2.4 | G-2 | 0.9 | | | I-1 |
| | liquid B3 | | | | | | | | | | |

| | | Polymerization | | | | | | | Coloring |
|---|---|---|---|---|---|---|---|---|---|
| | Surfactant | inhibitor | | Solvent | | | Photopolymerization | | material |
| | Part by | | Part by | | Part by | M/I | initator amount | M/P | concentration |
| | mass | Type | mass | Type | mass | ration | (% by mass) | ration | (% by mass) |
| Example B1 | 5.0 | J-1 | 0.01 | K-1 | 19.7 | 3.1 | 4.5 | 0.27 | 51 |
| Example B2 | 5.0 | J-1 | 0.01 | K-1 | 19.7 | 3.1 | 4.5 | 0.27 | 51 |
| Example B3 | 5.0 | J-1 | 0.01 | K-1 | 19.7 | 3.1 | 4.5 | 0.27 | 51 |
| Example B4 | 5.0 | J-1 | 0.01 | K-1 | 19.7 | 3.1 | 4.5 | 0.27 | 51 |
| Example B5 | 5.0 | J-1 | 0.01 | K-1 | 19.7 | 3.1 | 4.5 | 0.27 | 51 |
| Example B6 | [symbol] .0 | J-1 | 0.01 | K-1 | 19.7 | 3.1 | 4.5 | 0.27 | 51 |
| Example B7 | 5.0 | J-1 | 0.01 | K-1 | 19.7 | 3.1 | 4.5 | 0.27 | 51 |
| Example B8 | 5.0 | J-1 | 0.01 | K-1 | 19.7 | 3.1 | 4.5 | 0.27 | 51 |
| Example B9 | 5.0 | J-1 | 0.01 | K-1 | 19.7 | 3.1 | 4.5 | 0.27 | 51 |
| Example B10 | 5.0 | J-1 | 0.01 | K-1 | 19.7 | 3.1 | 4.5 | 0.27 | 51 |
| Example B11 | 5.0 | J-1 | 0.01 | K-1 | 19.7 | 3.1 | 4.5 | 0.27 | 51 |
| Example B12 | [symbol] .0 | J-1 | 0.01 | K-1 | 19.7 | 3.1 | 4.5 | 0.27 | 51 |
| Example B13 | 5.0 | J-1 | 0.01 | K-1 | 19.7 | 3.1 | 4.5 | 0.27 | 51 |
| Example B14 | 5.0 | J-1 | 0.01 | K-1 | 19.7 | 3.1 | 4.5 | 0.27 | 51 |
| Example B15 | 5.0 | J-1 | 0.01 | K-1 | 19.7 | 3.1 | 4.5 | 0.27 | 51 |
| Example B16 | 5.0 | J-1 | 0.01 | K-1 | 19.7 | 3.1 | 4.5 | 0.27 | 51 |
| Example B17 | 6.0 | J-1 | 0.01 | K-1 | 19.7 | 3.1 | 4.5 | 0.27 | 51 |
| Example B18 | 5.0 | J-1 | 0.01 | K-1 | 19.7 | 3.1 | 4.5 | 0.27 | 51 |
| Example B19 | 5.0 | J-1 | 0.01 | K-1 | 19.7 | 3.1 | 4.5 | 0.27 | 51 |
| Example B20 | 5.0 | J-1 | 0.01 | K-1 | 19.3 | 5.4 | 2.8 | 0.30 | 51 |
| Example B21 | 5.0 | J-1 | 0.01 | K-1 | 19.3 | 4.3 | 3.4 | 0.29 | 51 |
| Example B22 | 5.0 | J-1 | 0.01 | K-1 | 19.7 | 3.7 | 3.9 | 0.29 | 51 |
| Example B23 | 5.0 | J-1 | 0.01 | K-1 | 19.7 | 2.7 | 5.1 | 0.26 | 51 |
| Example B24 | 5.0 | J-1 | 0.01 | K-1 | 19.7 | 2.0 | 6.2 | 0.24 | 51 |
| Example B25 | 5.0 | J-1 | 0.01 | K-1 | 19.7 | 1.5 | 7.3 | 0. [symbol] 2 | 51 |
| Example B26 | 5.0 | J-1 | 0.01 | K-1 | 19.7 | 1.2 | 8.4 | 0.20 | 51 |
| Example B27 | 5.0 | J-1 | 0.01 | K-1 | 19.3 | 5.4 | 2.8 | 0.30 | 51 |
| Example B28 | 5.0 | J-1 | 0.01 | K-1 | 19.3 | 4. [symbol] | 3.4 | 0.29 | 51 |
| Example B29 | 5.0 | J-1 | 0.01 | K-1 | 19.7 | 3.7 | 3.9 | 0.29 | 51 |
| Example B30 | 5.0 | J-1 | 0.01 | K-1 | 19.7 | 2.7 | 5.1 | 0.26 | 51 |

[symbol]

indicates data missing or illegible when filed

TABLE 12

| | Dispersion | | | | Polymerizable | | Photopolymerization | | | | |
|---|---|---|---|---|---|---|---|---|---|---|---|
| | liquid | | Resin | | monomer | | initiator | | Additive | | |
| | | Part by | | Part by | | Part by | | Part by | | Part by | Surfactant |
| | Type | mass | Type | mass | Type | mass | Type | mass | Type | mass | Type |
| Example B31 | Dispersion | 65 | A-3 | 7.0 | M-3 | 2.2 | G-2 | 1.1 | | | I-1 |
| | liquid B3 | | | | | | | | | | |
| Example B32 | Dispersion | 65 | A-3 | 7.0 | M-3 | 2.0 | G-2 | 1. [symbol] | | | I-1 |
| | liquid B3 | | | | | | | | | | |
| Example B33 | Dispersion | 65 | A- [symbol] | 7.0 | M-3 | 1.8 | G-2 | 1.5 | | | I-1 |
| | liquid B3 | | | | | | | | | | |
| Example B34 | Dispersion | 65 | A-3 | 7.0 | M-1 | 2.6 | G-1 | 0.8 | | | I-1 |
| | liquid B3 | | | | | | | | | | |
| Example B35 | Dispersion | 65 | A-3 | 7.0 | M-2 | 2.6 | G-1 | 0.8 | | | I-1 |
| | liquid B3 | | | | | | | | | | |
| Example B36 | Dispersion | 65 | A-3 | 7.0 | M-4 | 2.6 | G-1 | 0.8 | | | I-1 |
| | liquid B3 | | | | | | | | | | |
| Example B37 | Dispersion | 65 | A-3 | 7.0 | M-5 | 2.5 | G-1 | 0. [symbol] | | | I-1 |
| | liquid B3 | | | | | | | | | | |
| Example B38 | Dispersion | 65 | A-3 | 7.0 | M-6 | 2.5 | G-1 | 0. [symbol] | | | I-1 |
| | liquid B3 | | | | | | | | | | |
| Example B39 | Dispersion | 65 | A-3 | 7.0 | M-7 | [symbol] .5 | G-1 | 0.8 | | | I-1 |
| | liquid B3 | | | | | | | | | | |
| Example B40 | Dispersion | 65 | A-3 | 7.0 | M-8 | 2.5 | G-1 | 0.8 | | | I-1 |
| | liquid B3 | | | | | | | | | | |
| Comparative | Dispersion | 65 | A-3 | 7.0 | M-3 | 2.6 | G-c1 | 0.7 | | | I-1 |
| Example B1 | liquid B3 | | | | | | | | | | |
| Comparative | Dispersion | 65 | A-3 | 7.0 | M-3 | 2.6 | G-c1 | 0. [symbol] | B-1 | 0.7 | I-1 |
| Example B2 | liquid B3 | | | | | | | | | | |
| Comparative | Dispersion | 65 | A-3 | 7.0 | M-3 | 2.6 | G-c1 | 0.35 | | | I-1 |
| Example B3 | liquid B3 | | | | | | G-c2 | 0.36 | | | |
| Comparative | Dispersion | 65 | A-3 | 7.0 | M-3 | 2.8 | G-2 | 0.5 | | | I-1 |
| Example B4 | liquid B3 | | | | | | | | | | |
| Comparative | Dispersion | 65 | A-3 | [symbol] 6.0 | M-3 | 0.4 | G-2 | 1.1 | | | I-1 |
| Example B5 | liquid B3 | | | | | | | | | | |

| | | Polymerization | | | | | | | Coloring |
|---|---|---|---|---|---|---|---|---|---|
| | Surfactant | inhibitor | | Solvent | | | Photopolymerization | | material |
| | Part by | | Part by | | Part by | M/I | initator amount | M/P | concentration |
| | mass | Type | mass | Type | mass | ratio | (% by mass) | ratio | (% by mass) |
| Example B31 | 5.0 | J-1 | 0.01 | K-1 | 19.7 | 2.0 | 6.2 | 0.24 | 51 |
| Example B32 | 5.0 | J-1 | 0.01 | K-1 | 19.7 | 1.5 | 7.3 | 0.22 | 51 |
| Example B33 | 5.0 | J-1 | 0.01 | K-1 | 19.7 | 1.2 | [symbol] .4 | 0.20 | 51 |
| Example B34 | 5.0 | J-1 | 0.01 | K-1 | 19.7 | 3.1 | 4.5 | 0.27 | 51 |
| Example B35 | 5.0 | J-1 | 0.01 | K-1 | 19.7 | 3.1 | 4.5 | 0.27 | 51 |
| Example B36 | 5.0 | J-1 | 0.01 | K-1 | 19.7 | 3.1 | 4.5 | 0.27 | 51 |
| Example B37 | 5.0 | J-1 | 0.01 | K-1 | 19.7 | 3.1 | 4.5 | 0.27 | 51 |
| Example B38 | 5.0 | J-1 | 0.01 | K-1 | 19.7 | 3.1 | 4.5 | 0.27 | 51 |
| Example B39 | 5.0 | J-1 | 0.01 | K-1 | 19.7 | 3.1 | 4.5 | 0.27 | 51 |
| Example B40 | 5.0 | J-1 | 0.01 | K-1 | 19.7 | 3.1 | 4.5 | 0.27 | 51 |
| Comparative | 5.0 | J-1 | 0.01 | K-1 | 19.7 | 3.7 | 3.9 | 0.29 | 51 |
| Example B1 | | | | | | | | | |
| Comparative | 5.0 | J-1 | 0.01 | K-1 | 19.0 | 3.7 | 3.8 | 0.29 | 49 |
| Example B2 | | | | | | | | | |
| Comparative | 5.0 | J-1 | 0.01 | K-1 | 19.7 | 3.7 | 3.9 | 0.29 | 51 |
| Example B3 | | | | | | | | | |
| Comparative | 5.0 | J-1 | 0.01 | K-1 | 19.7 | 5.6 | 2.8 | 0.31 | 51 |
| Example B4 | | | | | | | | | |
| Comparative | 5.0 | J-1 | 0.01 | K-1 | 12.5 | 0.4 | 6.2 | 0.04 | 51 |
| Example B5 | | | | | | | | | |

[symbol]

indicates data missing or illegible when filed

TABLE 13

| | Dispersion | | | | Polymerizable | | Photopolymerization | | | | |
|---|---|---|---|---|---|---|---|---|---|---|---|
| | liquid | | Resin | | monomer | | initiator | | Additive | | |
| | | Part by | | Part by | | Part by | | Part by | | Part by | Surfactant |
| | Type | mass | Type | mass | Type | mass | Type | mass | Type | mass | Type |
| Example C1 | Dispersion | 65 | A-3 | 7.0 | M-3 | 2.5 | G-1 | 0.8 | | | I-1 |
| | liquid C1 | | | | | | | | | | |
| Example C2 | Dispersion | 65 | A-3 | 7.0 | M-3 | 2.5 | G-1 | 0.8 | | | I-1 |
| | liquid C2 | | | | | | | | | | |
| Example C3 | Dispersion | 65 | A-3 | 7.0 | M-3 | 2.5 | G-1 | 0.8 | | | I-1 |
| | liquid C3 | | | | | | | | | | |
| Example C4 | Dispersion | 65 | A-3 | 7.0 | M-3 | 2.5 | G-1 | 0.8 | | | I-1 |
| | liquid C4 | | | | | | | | | | |
| Example C5 | Dispersion | 65 | A-3 | 7.0 | M-3 | 2.5 | G-1 | 0.8 | | | I-1 |
| | liquid C5 | | | | | | | | | | |
| Example C6 | Dispersion | 65 | A-3 | 7.0 | M- [symbol] | 2.5 | G-1 | 0.8 | | | I-1 |
| | liquid C6 | | | | | | | | | | |
| Example C7 | Dispersion | 65 | A-3 | 7.0 | M-3 | 2.5 | G-1 | 0.8 | | | I-1 |
| | liquid C7 | | | | | | | | | | |
| Example C8 | Dispersion | 65 | A-3 | 7.0 | M-3 | 2.5 | G-1 | 0.8 | | | I-1 |
| | liquid C8 | | | | | | | | | | |
| Example C9 | Dispersion | 65 | A-3 | 7.0 | M-3 | 2.5 | G-1 | 0.8 | | | I-1 |
| | liquid C9 | | | | | | | | | | |
| Example C10 | Dispersion | 65 | A-3 | 7.0 | M-3 | 2.5 | G-1 | 0.8 | | | I-1 |
| | liquid C10 | | | | | | | | | | |
| Example C11 | Dispersion | 65 | A-3 | 7.0 | M-3 | 2.5 | G-1 | 0.8 | | | I-1 |
| | liquid C11 | | | | | | | | | | |
| Example C12 | Dispersion | 65 | A-3 | 7.0 | M-3 | 2.5 | G-1 | 0.8 | | | I-1 |
| | liquid C12 | | | | | | | | | | |
| Example C13 | Dispersion | 65 | A-3 | 7.0 | M-3 | 2.5 | G-1 | 0.8 | | | I-1 |
| | liquid C13 | | | | | | | | | | |
| Comparative | Dispersion | 65 | A-3 | 7.0 | M-3 | 2.6 | G-c1 | 0.7 | | | I-1 |
| Example C1 | liquid C4 | | | | | | | | | | |
| Comparative | Dispersion | 65 | A-3 | 7.0 | M-3 | 2.6 | G-c1 | 0.7 | H-1 | 0.7 | I-1 |
| Example C2 | liquid C4 | | | | | | | | | | |
| Comparative | Dispersion | 65 | A-3 | 7.0 | M-3 | 2.6 | G-c1 | 0.36 | H-1 | 0.7 | I-1 |
| Example C3 | liquid C4 | | | | | | G-c2 | 0.35 | | | |
| Comparative | Dispersion | 65 | A-3 | 7.0 | M-3 | 2.8 | G-2 | 0.6 | | | I-1 |
| Example C4 | liquid C4 | | | | | | | | | | |
| Comparative | Dispersion | 65 | A-3 | 7.0 | M-3 | 1.6 | G-2 | 1.7 | | | I-1 |
| Example C5 | liquid C4 | | | | | | | | | | |

| | | Polymerization | | | | | | | Coloring |
|---|---|---|---|---|---|---|---|---|---|
| | Surfactant | inhibitor | | Solvent | | | Photopolymerization | | material |
| | Part by | | Part by | | Part by | M/I | initiator amount | M/P | concentration |
| | mass | Type | mass | Type | mass | ratio | (% by mass) | ratio | (% by mass) |
| Example C1 | 5.0 | J-1 | 0.01 | K-1 | 19.7 | 3.1 | 4.5 | 0.27 | 51 |
| Example C2 | 5.0 | J-1 | 0.01 | K-1 | 19.7 | 3.1 | 4.5 | 0.27 | 51 |
| Example C3 | 5.0 | J-1 | 0.01 | K-1 | 19.7 | 3.1 | 4.5 | 0.27 | 51 |
| Example C4 | 5.0 | J-1 | 0.01 | K-1 | 19.7 | 3.1 | 4.5 | 0.27 | 51 |
| Example C5 | 5.0 | J-1 | 0.01 | K-1 | 19.7 | 3.1 | 4.5 | 0.27 | 51 |
| Example C6 | 5.0 | J-1 | 0.01 | K-1 | 19.7 | 3.1 | 4.5 | 0.27 | 51 |
| Example C7 | 5.0 | J-1 | 0.01 | K-1 | 19.7 | 3.1 | 4.5 | 0.27 | 51 |
| Example C8 | 5.0 | J-1 | 0.01 | K-1 | 19.7 | 3.1 | 4.5 | 0.27 | 51 |
| Example C9 | 5.0 | J-1 | 0.01 | K-1 | 19.7 | 3.1 | 4.5 | 0.27 | 51 |
| Example C10 | 5.0 | J-1 | 0.01 | K-1 | 19.7 | 3.1 | 4.5 | 0.27 | 51 |
| Example C11 | 5.0 | J-1 | 0.01 | K-1 | 19.7 | 3.1 | 4.5 | 0.27 | 51 |
| Example C12 | 5.0 | J-1 | 0.01 | K-1 | 19.7 | 3.1 | 4.5 | 0.27 | 51 |
| Example C13 | 5.0 | J-1 | 0.01 | K-1 | 19.7 | 3.1 | 4. [symbol] | 0.27 | 51 |
| Comparative | 5.0 | J-1 | 0.01 | K-1 | 19.7 | 3.7 | 3.9 | 0.29 | 51 |
| Example C1 | | | | | | | | | |
| Comparative | 5.0 | J-1 | 0.01 | K-1 | 19.0 | 3.7 | 3.8 | 0.29 | 49 |
| Example C2 | | | | | | | | | |
| Comparative | 5.0 | J-1 | 0.01 | K-1 | 19.7 | 3.7 | 3.9 | 0.29 | 51 |
| Example C3 | | | | | | | | | |
| Comparative | 5.0 | J-1 | 0.01 | K-1 | 19.7 | 5.6 | 2.8 | 0.31 | 51 |
| Example C4 | | | | | | | | | |
| Comparative | 5.0 | J-1 | 0.01 | K-1 | 19.7 | 0.9 | 9.6 | 0.18 | 51 |
| Example C5 | | | | | | | | | |

[symbol]

indicates data missing or illegible when filed

TABLE 14

| | Dispersion | | | | Polymerizable | | Photopolymerization | | | | |
|---|---|---|---|---|---|---|---|---|---|---|---|
| | liquid | | Resin | | monomer | | initiator | | Additive | | |
| | | Part by | | Part by | | Part by | | Part by | | Part by | Surfactant |
| | Type | mass | Type | mass | Type | mass | Type | mass | Type | mass | Type |
| Example M1 | Dispersion | 65 | A-3 | 7.0 | M-3 | 2.5 | G-1 | 0.8 | | | I-1 |
| | liquid M1 | | | | | | | | | | |
| Example M2 | Dispersion | 65 | A-3 | 7.0 | M-3 | 2.5 | G-1 | 0.8 | | | I-1 |
| | liquid M2 | | | | | | | | | | |
| Example M3 | Dispersion | 65 | A-3 | 7.0 | M-3 | 2.5 | G-1 | 0.8 | | | I-1 |
| | liquid M3 | | | | | | | | | | |
| Example M4 | Dispersion | 65 | A-3 | 7.0 | M-3 | 2.5 | G-1 | 0.8 | | | I-1 |
| | liquid M4 | | | | | | | | | | |
| Example M5 | Dispersion | 65 | A-3 | 7.0 | M-3 | 2.5 | G-1 | 0.8 | | | I-1 |
| | liquid M5 | | | | | | | | | | |
| Example M6 | Dispersion | 65 | A-3 | 7.0 | M-3 | 2.5 | G-1 | 0.8 | | | I-1 |
| | liquid M6 | | | | | | | | | | |
| Example M7 | Dispersion | 65 | A-3 | 7.0 | M-3 | 2.5 | G-1 | 0.8 | | | I-1 |
| | liquid M7 | | | | | | | | | | |
| Example M8 | Dispersion | 65 | A-3 | 7.0 | M-3 | 2.5 | G-1 | 0.8 | | | I-1 |
| | liquid M8 | | | | | | | | | | |
| Example M9 | Dispersion | 65 | A-3 | 7.0 | M-3 | 2.5 | G-1 | 0.8 | | | I-1 |
| | liquid M9 | | | | | | | | | | |
| Example M10 | Dispersion | 65 | A-3 | 7.0 | M-3 | 2.5 | G-1 | 0.8 | | | I-1 |
| | liquid M10 | | | | | | | | | | |
| Example M11 | Dispersion | 65 | A-3 | 7.0 | M-3 | 2.5 | G-1 | 0.8 | | | I-1 |
| | liquid M11 | | | | | | | | | | |
| Example M12 | Dispersion | 65 | A-3 | 7.0 | M-3 | 2.5 | G-1 | 0.8 | | | I-1 |
| | liquid M12 | | | | | | | | | | |
| Example M13 | Dispersion | 65 | A-3 | 7.0 | M-3 | 2.5 | G-1 | 0.8 | | | I-1 |
| | liquid M13 | | | | | | | | | | |
| Example M14 | Dispersion | 65 | A-3 | 7.0 | M-3 | 2.5 | G-1 | 0.8 | | | I-1 |
| | liquid M14 | | | | | | | | | | |
| Example M15 | Dispersion | 65 | A-3 | 7.0 | M-3 | 2.5 | G-1 | 0.8 | | | I-1 |
| | liquid M15 | | | | | | | | | | |
| Example M16 | Dispersion | 65 | A-3 | 7.0 | M-3 | 2.5 | G-1 | 0.8 | | | I-1 |
| | liquid M16 | | | | | | | | | | |
| Comparative | Dispersion | 65 | A-3 | 7.0 | M-3 | 2.6 | G-c1 | 0.7 | | | I-1 |
| Example M1 | liquid M [symbol] | | | | | | | | | | |
| Comparative | Dispersion | 65 | A-3 | 7.0 | M-3 | 2.6 | G-c1 | 0.7 | H-1 | 0.7 | I-1 |
| Example M2 | liquid M4 | | | | | | | | | | |
| Comparative | Dispersion | 65 | A-3 | 7.0 | M-3 | 2.6 | G-c1 | 0.35 | | | I-1 |
| Example M3 | liquid M4 | | | | | | G-c2 | 0.35 | | | |
| Comparative | Dispersion | 65 | A-3 | 7.0 | M-3 | 2.8 | G-2 | 0. [symbol] | | | I-1 |
| Example M4 | liquid M4 | | | | | | | | | | |
| Comparative | Dispersion | 65 | A-3 | 7.0 | M-3 | 1.6 | G-2 | 1.7 | | | I-1 |
| Example M5 | liquid M4 | | | | | | | | | | |

| | | Polymerization | | | | | | | Coloring |
|---|---|---|---|---|---|---|---|---|---|
| | Surfactant | inhibitor | | Solvent | | | Photopolymerization | | material |
| | Part by | | Part by | | Part by | M/I | initiator amount | M/P | concentration |
| | mass | Type | mass | Type | mass | ratio | (% by mass | ratio | (% by mass) |
| Example M1 | 5.0 | J-1 | 0.01 | K-1 | 19.7 | 3.1 | 4.5 | 0.27 | 51 |
| Example M2 | 5.0 | J-1 | 0.01 | K-1 | 19.7 | 3.1 | 4.5 | 0.27 | 51 |
| Example M3 | 5.0 | J-1 | 0.01 | K-1 | 19.7 | 3.1 | 4.5 | 0.27 | 51 |
| Example M4 | 5.0 | J-1 | 0.01 | K-1 | 19.7 | 3.1 | 4.5 | 0.27 | 51 |
| Example M5 | 5.0 | J-1 | 0.01 | K-1 | 19.7 | 3.1 | 4.5 | 0.27 | 51 |
| Example M6 | 5.0 | J-1 | 0.01 | K-1 | 19.7 | 3.1 | 4.5 | 0.27 | 51 |
| Example M7 | 5.0 | J-1 | 0.01 | K-1 | 19.7 | 3.1 | 4.5 | 0.27 | 51 |
| Example M8 | 5.0 | J-1 | 0.01 | K-1 | 19.7 | 3.1 | 4.5 | 0.27 | 51 |
| Example M9 | 5.0 | J-1 | 0.01 | K-1 | 19.7 | 3.1 | 4.5 | 0.27 | 51 |
| Example M10 | 5.0 | J-1 | 0.01 | K-1 | 19.7 | 3.1 | 4.5 | 0.27 | 51 |
| Example M11 | 5.0 | J-1 | 0.01 | K-1 | 19.7 | 3.1 | 4.5 | 0.27 | 51 |
| Example M12 | 5.0 | J-1 | 0.01 | K-1 | 19.7 | 3.1 | 4.5 | 0.27 | 51 |
| Example M13 | 5.0 | J-1 | 0.01 | K-1 | 19.7 | 3.1 | 4.5 | 0.27 | 51 |
| Example M14 | 5.0 | J-1 | 0.01 | K-1 | 19.7 | 3.1 | 4.5 | 0.27 | 51 |
| Example M15 | 5.0 | J-1 | 0.01 | K-1 | 19.7 | 3.1 | 4.5 | 0.27 | 51 |
| Example M16 | 5.0 | J-1 | 0.01 | K-1 | 19.7 | 3.1 | 4.5 | 0.27 | 51 |
| Comparative | 5.0 | J-1 | 0.01 | K-1 | 19.7 | 3.7 | 3.9 | 0.29 | 51 |
| Example M1 | | | | | | | | | |
| Comparative | 5.0 | J-1 | 0.01 | K-1 | 19.0 | 3.7 | 3.8 | 0.29 | 49 |
| Example M2 | | | | | | | | | |
| Comparative | 5.0 | J-1 | 0.01 | K-1 | 19.7 | 3.7 | 3.9 | 0.29 | 51 |
| Example M3 | | | | | | | | | |
| Comparative | 5.0 | J-1 | 0.01 | K-1 | 19.7 | 5.6 | 2.8 | 0.31 | 51 |
| Example M4 | | | | | | | | | |
| Comparative | 5.0 | J-1 | 0.01 | K-1 | 19.7 | 0.9 | 9.6 | 0.18 | 51 |
| Example M5 | | | | | | | | | |

[symbol]

indicates data missing or illegible when filed

TABLE 15

| | Dispersion | | | | Polymerizable | | Photopolymerization | | | | |
|---|---|---|---|---|---|---|---|---|---|---|---|
| | liquid | | Resin | | monomer | | initiator | | Additive | | |
| | | Part by | | Part by | | Part by | | Part by | | Part by | Surfactant |
| | Type | mass | Type | mass | Type | mass | Type | mass | Type | mass | Type |
| Example Y1 | Dispersion | 65 | A-3 | 7.0 | M-3 | 2.5 | G-1 | 0.8 | | | I-1 |
| | liquid Y1 | | | | | | | | | | |
| Example Y2 | Dispersion | 65 | A-3 | 7.0 | M-3 | 2.5 | G-1 | 0.8 | | | I-1 |
| | liquid Y2 | | | | | | | | | | |
| Example Y3 | Dispersion | 6 [symbol] | A-3 | 7.0 | M-3 | 2.5 | G-1 | 0.8 | | | I-1 |
| | liquid Y3 | | | | | | | | | | |
| Example Y4 | Dispersion | 65 | A-3 | 7.0 | M-3 | 2.5 | G-1 | 0.8 | | | I-1 |
| | liquid Y4 | | | | | | | | | | |
| Example Y5 | Dispersion | 6 [symbol] | A-3 | 7.0 | M-3 | 2.5 | G-1 | 0.8 | | | I-1 |
| | liquid Y5 | | | | | | | | | | |
| Example Y6 | Dispersion | 65 | A-3 | 7.0 | M-3 | 2.5 | G-1 | 0.8 | | | I-1 |
| | liquid Y6 | | | | | | | | | | |
| Example Y7 | Dispersion | 65 | A-3 | 7.0 | M-3 | 2.5 | G-1 | 0.8 | | | I-1 |
| | liquid Y7 | | | | | | | | | | |
| Example Y8 | Dispersion | 65 | A-3 | 7.0 | M-3 | 2.5 | G-1 | 0.8 | | | I-1 |
| | liquid Y8 | | | | | | | | | | |
| Example Y9 | Dispersion | 65 | A-3 | 7.0 | M-3 | 2.5 | G-1 | 0.8 | | | I-1 |
| | liquid Y9 | | | | | | | | | | |
| Example Y10 | Dispersion | 65 | A-3 | 7.0 | M-3 | 2.5 | G-1 | 0.8 | | | I-1 |
| | liquid Y10 | | | | | | | | | | |
| Example Y11 | Dispersion | 65 | A-3 | 7.0 | M-3 | 2.5 | G-1 | 0.8 | | | I-1 |
| | liquid Y11 | | | | | | | | | | |
| Example Y12 | Dispersion | 65 | A-3 | 7.0 | M-3 | 2.5 | G-1 | 0.8 | | | I-1 |
| | liquid Y12 | | | | | | | | | | |
| Example Y13 | Dispersion | 6 [symbol] | A-3 | 7.0 | M-3 | 2.5 | G-1 | 0.8 | | | I-1 |
| | liquid Y13 | | | | | | | | | | |
| Example Y14 | Dispersion | 65 | A-3 | 7.0 | M-3 | 2.5 | G-1 | 0.8 | | | I-1 |
| | liquid Y14 | | | | | | | | | | |
| Example Y15 | Dispersion | 65 | A-3 | 7.0 | M-3 | 2.5 | G-1 | 0.8 | | | I-1 |
| | liquid Y15 | | | | | | | | | | |
| Example Y16 | Dispersion | 65 | A-3 | 7.0 | M-3 | 2.5 | G-1 | 0.8 | | | I-1 |
| | liquid Y16 | | | | | | | | | | |
| Comparative | Dispersion | 65 | A-3 | 7.0 | M-3 | 2.6 | G-c1 | 0.7 | | | I-1 |
| Example Y1 | liquid Y4 | | | | | | | | | | |
| Comparative | Dispersion | 65 | A-3 | 7.0 | M-3 | 2.6 | G-c1 | 0.7 | H-1 | 0.7 | I-1 |
| Example Y2 | liquid Y4 | | | | | | | | | | |
| Comparative | Dispersion | 65 | A-3 | 7.0 | M-3 | 2.6 | G-c1 | 0.35 | | | I-1 |
| Example Y3 | liquid Y4 | | | | | | G-c2 | 0.35 | | | |
| Comparative | Dispersion | 65 | A-3 | 7.0 | M-3 | 2.8 | G-2 | 0.6 | | | I-1 |
| Example Y4 | liquid Y4 | | | | | | | | | | |
| Comparative | Dispersion | 65 | A-3 | 7.0 | M-3 | 1.6 | G-2 | 1.7 | | | I-1 |
| Example Y5 | liquid Y4 | | | | | | | | | | |

| | | Polymerization | | | | | | | Coloring |
|---|---|---|---|---|---|---|---|---|---|
| | Surfactant | inhibitor | | Solvent | | | Photopolymerization | | material |
| | Part by | | Part by | | Part by | M/I | initiator amount | M/P | concentration |
| | mass | Type | mass | Type | mass | ratio | (% by mass) | ratio | (% by mass) |
| Example Y1 | 5.0 | J-1 | 0.01 | K-1 | 19.7 | 3.1 | 4.5 | 0.27 | 51 |
| Example Y2 | 5.0 | J-1 | 0.01 | K-1 | 19.7 | 3.1 | 4.5 | 0.27 | 51 |
| Example Y3 | [symbol] .0 | J-1 | 0.01 | K-1 | 19.7 | 3.1 | 4.5 | 0.27 | 51 |
| Example Y4 | [symbol] .0 | J-1 | 0.01 | K-1 | 19.7 | 3.1 | 4.5 | 0.27 | 51 |
| Example Y5 | 6.0 | J-1 | 0.01 | K-1 | 19.7 | 3.1 | 4.5 | 0.27 | 51 |
| Example Y6 | 6.0 | J-1 | 0.01 | K-1 | 19.7 | 3.1 | 4.5 | 0.27 | 51 |
| Example Y7 | 5.0 | J-1 | 0.01 | K-1 | 19.7 | 3.1 | 4.5 | 0.27 | 51 |
| Example Y8 | 5.0 | J-1 | 0.01 | K-1 | 19.7 | 3.1 | 4.5 | 0.27 | 51 |
| Example Y9 | 5.0 | J-1 | 0.01 | K-1 | 19.7 | 3.1 | 4.5 | 0.27 | 51 |
| Example Y10 | 5.0 | J-1 | 0.01 | K-1 | 19.7 | 3.1 | 4.5 | 0.27 | 51 |
| Example Y11 | 5.0 | J-1 | 0.01 | K-1 | 19.7 | 3.1 | 4.5 | 0.27 | 51 |
| Example Y12 | [symbol] .0 | J-1 | 0.01 | K-1 | 19.7 | 3.1 | 4.5 | 0.27 | 51 |
| Example Y13 | 5.0 | J-1 | 0.01 | K-1 | 19.7 | 3.1 | 4.5 | 0.27 | 51 |
| Example Y14 | 5.0 | J-1 | 0.01 | K-1 | 19.7 | 3.1 | 4.5 | 0.27 | 51 |
| Example Y15 | [symbol] .0 | J-1 | 0.01 | K-1 | 19.7 | 3.1 | 4.5 | 0.27 | 51 |
| Example Y16 | 5.0 | J-1 | 0.01 | K-1 | 19.7 | 3.1 | 4.5 | 0.27 | 51 |
| Comparative | 5.0 | J-1 | 0.01 | K-1 | 19.7 | 3.7 | 3. [symbol] | 0.29 | 51 |
| Example Y1 | | | | | | | | | |
| Comparative | 5.0 | J-1 | 0.01 | K-1 | 19.0 | 3.7 | 3.8 | 0.29 | 49 |
| Example Y2 | | | | | | | | | |
| Comparative | 5.0 | J-1 | 0.01 | K-1 | 19.7 | 3.7 | 3.9 | 0.29 | 51 |
| Example Y3 | | | | | | | | | |
| Comparative | 5.0 | J-1 | 0.01 | K-1 | 19.7 | 5.6 | 2.8 | 0.31 | 51 |
| Example Y4 | | | | | | | | | |
| Comparative | 5.0 | J-1 | 0.01 | K-1 | 19.7 | 0.9 | 9.6 | 0.18 | 51 |
| Example Y5 | | | | | | | | | |

[symbol]

indicates data missing or illegible when filed

Among the raw materials described by the abbreviations in the above tables, raw materials other than the dispersion liquid are as follows. The dispersion liquids are the dispersion liquids produced above.

(Resin)

A-3: 20% by mass PGMEA solution of a resin having the following structure (the numerical value described together with the main chain indicates a molar ratio; Mw=11000, acid value: 69 mgKOH/g)

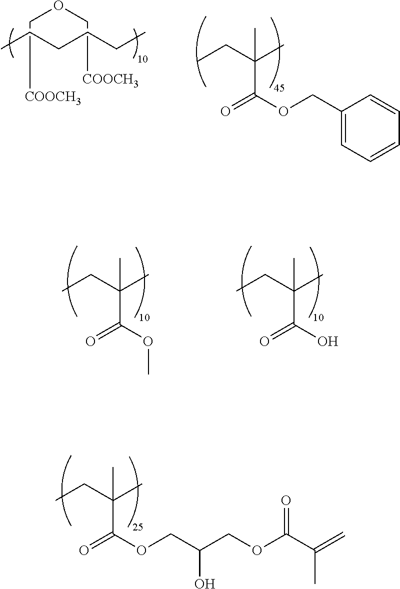

(Polymerizable Monomer)

M-1: trimethylolpropane triacrylate (manufactured by TOAGOSEI CO., LTD., ARONIX M-309, number of functional groups: 3, molecular weight: 296, ethylenically unsaturated bond-containing group value: 99 g/mol)

M-2: trimethylolpropane propyleneoxide-modified triacrylate (manufactured by TOAGOSEI CO., LTD., ARONIX M-310, number of functional groups: 3, molecular weight: 471, ethylenically unsaturated bond-containing group value: 157 g/mol, compound having an alkyleneoxy group (propyleneoxy group))

M-3: trimethylolpropane ethyleneoxide-modified triacrylate (manufactured by TOAGOSEI CO., LTD., ARONIX M-350, number of functional groups: 3, molecular weight: 429, ethylenically unsaturated bond-containing group value: 143 g/mol, compound having an alkyleneoxy group (ethyleneoxy group))

M-4: dipentaerythritol hexaacrylate (manufactured by TOAGOSEI CO., LTD., ARONIX M-402, number of functional groups: 6, molecular weight: 579, ethylenically unsaturated bond-containing group value: 96 g/mol)

M-5: tris(2-acryloyloxyethyl) isocyanurate (manufactured by TOAGOSEI CO., LTD., ARONIX M-315, number of functional groups: 3, molecular weight: 423, ethylenically unsaturated bond-containing group value: 141 g/mol)

M-6: caprolactone-modified dipentaerythritol hexaacrylate (manufactured by Nippon Kayaku Co., Ltd., KAYARAD DPCA-30, compound having the following structure (m=1, a=3, b=3), number of functional groups: 6, molecular weight: 921, ethylenically unsaturated bond-containing group value: 154 g/mol)

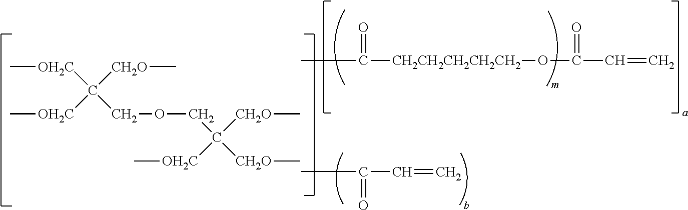

M-7: urethane acrylate (manufactured by Shin-Nakamura Chemical Co., Ltd., U-6LPA, molecular weight: 760, number of functional groups: 6, ethylenically unsaturated bond-containing group value: 127 g/mol)

M-8: compound having the following structure (number of functional groups: 6, molecular weight: 1107, ethylenically unsaturated bond-containing group value: 185 g/mol, compound having an alkyleneoxy group (ethyleneoxy group))

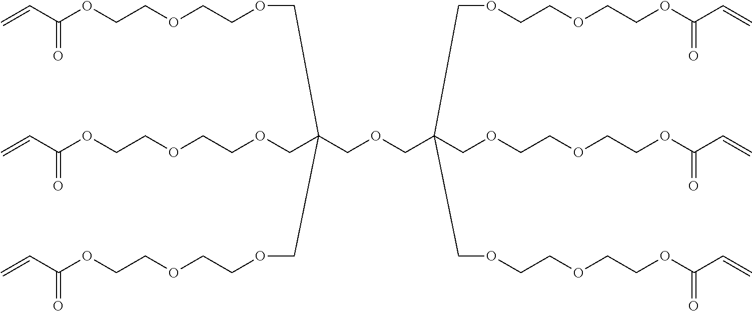 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

(Photopolymerization Initiator)

[Oxime compound OX having aromatic ring group Ar^{OX1} in which electron withdrawing group is introduced into aromatic ring]

G-1 to G-4: compounds having the following structures.

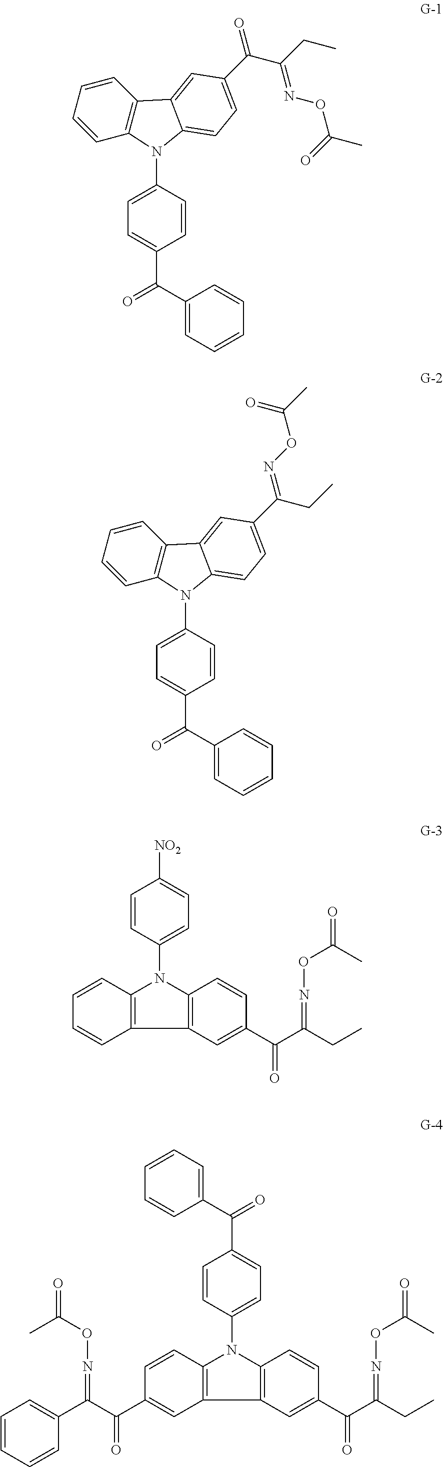 [SMILES: CC/C(=N\OC(C)=O)C(=O)c1ccc2c(c1)c1ccccc1n2-c1ccc(C(=O)c2ccccc2)cc1 ; CC/C(=N\OC(C)=O)c1ccc2c(c1)c1ccccc1n2-c1ccc(C(=O)c2ccccc2)cc1 ; CCC(=NOC(C)=O)C(=O)c1ccc2c(c1)c1ccccc1n2-c1ccc([N+](=O)[O-])cc1 ; CCC(=NOC(C)=O)C(=O)c1ccc2c(c1)c1cc(C(=O)C(=NOC(C)=O)c3ccccc3)ccc1n2-c1ccc(C(=O)c2ccccc2)cc1]

[Photopolymerization Initiator Other than Oxime Compound OX]

G-c1: compound having the following structure (oxime-based photopolymerization initiator)

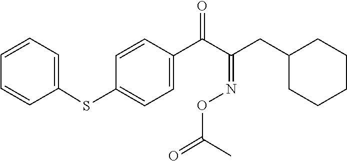 [SMILES: CC(=O)O/N=C(/CC1CCCCC1)C(=O)c1ccc(Sc2ccccc2)cc1]

G-c2: compound having the following structure (benzophenone-based photopolymerization initiator)

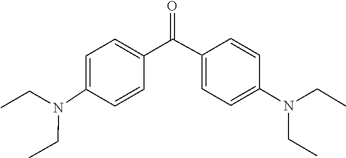

(Additive)

H-1: a compound having the following structure (ultraviolet absorber)

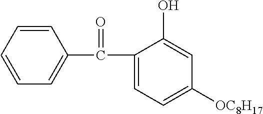

(Surfactant)

1-1: 1% by mass of PGMEA solution of a compound having the following structure (Mw=14000); in the following formula, “%” representing the proportion of a repeating unit is mol %

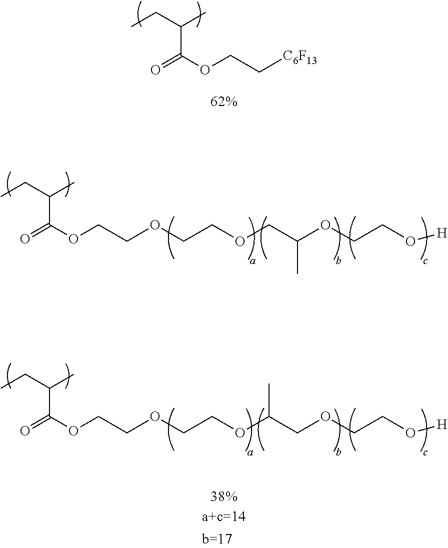

(Polymerization Inhibitor)

J-1: p-methoxyphenol

(Solvent)

K-1: propylene glycol monomethyl ether acetate (PGMEA)

<Performance Evaluation>

(Light Resistance)

Each photosensitive composition was applied to a glass substrate according to a spin coating method, subjected to a heating treatment (pre-baking) for 120 seconds using a hot plate at 100° C., exposed with i-rays at an exposure amount of 1000 mJ/cm², and then heated at 200° C. for 5 minutes to produce a film having a thickness of 0.6 μm. Light transmittance (transmittance) of the obtained film in a wavelength range of 400 to 700 nm was measured by using MCPD-3000 manufactured by OTSUKA ELECTRONICS Co., LTD. Next, the film produced above was irradiated with light of 100000 Lux over 1000 hours (total irradiation amount: 100 million Lux-hr) using a light resistance tester (Super Xenon Weather Meter SX75, manufactured by Suga Test Instruments Co., Ltd.). The transmittance of the film after light irradiation was measured, and light resistance was evaluated based on the following standard. A to C are in a range in which there is no problem in use.

A: integrated value of the transmittance of the film after light irradiation at a wavelength of 400 to 700 nm was 99% or more of the integrated value of the transmittance of the film before light irradiation at a wavelength of 400 to 700 nm.

B: integrated value of the transmittance of the film after light irradiation at a wavelength of 400 to 700 nm was 97% or more and less than 99% of the integrated value of the transmittance of the film before light irradiation at a wavelength of 400 to 700 nm.

C: integrated value of the transmittance of the film after light irradiation at a wavelength of 400 to 700 nm was 95% or more and less than 97% of the integrated value of the transmittance of the film before light irradiation at a wavelength of 400 to 700 nm.

D: integrated value of the transmittance of the film after light irradiation at a wavelength of 400 to 700 nm was less than 95% of the integrated value of the transmittance of the film before light irradiation at a wavelength of 400 to 700 nm.

(Adhesiveness)

CT-4000 (manufactured by Fujifilm Electronic Materials Co., Ltd.) was applied to a silicon wafer with a diameter of 8 inches (=203.2 mm) by a spin coating method so that a film thickness was 0.1 μm, and the silicon wafer was heated at 220° C. for 1 hour using a hot plate to form a base layer. Each photosensitive composition was applied to this silicon wafer with a base layer by a spin coating method, and then the silicon wafer with a base layer was heated at 100° C. for 2 minutes using a hot plate to obtain a composition layer having a film thickness of 0.5 μm. Using an i-ray stepper FPA-3000 i5+ (manufactured by Canon Inc.), the composition layer was irradiated with light having a wavelength of 365 nm through a mask pattern in which each of the square pixels with a side length of 1.1 μm was arranged on the substrate in a region of 4 mm×3 mm to perform exposure thereon with an exposure amount of 500 mJ/cm². The composition layer after exposure was subjected to puddle development for 60 seconds at 23° C. using a 0.3% by mass of aqueous solution of tetramethylammonium hydroxide. Next, the composition layer was rinsed by spin showering with water and was cleaned with pure water. Thereafter, water droplets were splashed by high-pressure air, and the silicon wafer was naturally dried. Next, post-baking was performed for 300 seconds at 220° C. using a hot plate to form a pixel. The obtained pixel was observed using an optical microscope, and among all pixels, the number of pixels closely attached to the silicon wafer were counted to evaluate the adhesiveness. A to C are in a range in which there is no problem in use.

A: all pixels were closely attached with each other,

B: pixels closely attached with each other were 98% or more and less than 100% of all pixels.

C: pixels closely attached with each other were 95% or more and less than 98% of all pixels.

D: pixels closely attached with each other were less than 95% of all pixels.

(Color Unevenness)

CT-4000 (manufactured by Fujifilm Electronic Materials Co., Ltd.) was applied to a glass substrate by a spin coating method so that a film thickness was 0.1 μm, and the glass substrate was heated at 220° C. for 1 hour using a hot plate to form a base layer. Each photosensitive composition was applied to this glass substrate with a base layer by a spin coating method, and then the glass substrate with a base layer was heated at 100° C. for 2 minutes using a hot plate to obtain a composition layer having a film thickness of 0.5 μm.

The composition layer was exposed to light having a wavelength of 365 nm by irradiating the composition layer with an exposure amount of 500 mJ/cm².

The composition layer after exposure was subjected to puddle development for 60 seconds at 23° C. using a 0.3% by mass of aqueous solution of tetramethylammonium hydroxide. Next, the composition layer was rinsed by spin showering with water and was cleaned with pure water. Thereafter, water droplets were splashed by high-pressure air, and the glass substrate was naturally dried. Next, post-baking was performed for 300 seconds at 220° C. using a hot plate to form a film. A brightness distribution was analyzed by the following method using the glass substrate (evaluation substrate) on which this film had been formed, and the color unevenness was evaluated based on the number of pixels having deviation from the average of ±10% or more.

A method of measuring the brightness distribution will be described. The evaluation substrate was installed between an observation lens and a light source of an optical microscope, and the light source irradiated light toward the observation lens. The transmitted light state was observed with an optical microscope MX-50 (manufactured by Olympus Corporation) equipped with a digital camera. The capturing of the surface of the film was performed for any five selected regions. The brightness of the captured image was digitized and stored as a density distribution of 256 gradations from 0 to 255. The brightness distribution was analyzed from this image, and the color unevenness was evaluated based on the number of pixels having deviation from the average of more than ±10%. The evaluation standard is as follows. It is judged that evaluations A to C have no problem in practical use.

A: number of pixels having deviation from the average of more than ±10% was 1000 or less.

B: number of pixels having deviation from the average of more than ±10% was more than 1000 and 3000 or less.

C: number of pixels having deviation from the average of more than ±10% was more than 3000 and 5000 or less.

D: number of pixels having deviation from the average of more than ±10% was more than 5000.

(Surface Roughness)

A surface roughness (Ra) of the pixels obtained in the adhesiveness evaluation was measured using an atomic force microscope Dimension FastScan AFM (manufactured by Bruker). The evaluation standard for the surface roughness is as follows. It is judged that evaluations A to C have no problem in practical use.

A: surface roughness (Ra) was 0 nm or more and less than 3 nm.

B: surface roughness (Ra) was 3 nm or more and less than 5 nm.

C: surface roughness (Ra) was 5 nm or more and less than 10 nm.

D: surface roughness (Ra) was 10 nm or more.

The above-described results are shown in the tables below.

TABLE 16

| | Evaluation | | | |
|---|---|---|---|---|
| | Light | | Color | Surface |
| | resistance | Adhesiveness | unevenness | roughness |
| Example R1 | A | A | A | A |
| Example R2 | A | A | A | A |
| Example R3 | A | A | A | A |
| Example R4 | A | A | A | A |
| Example R5 | A | A | A | A |
| Example R6 | A | A | A | A |
| Example R7 | A | A | A | A |
| Example R8 | A | A | A | A |
| Example R9 | A | A | A | A |
| Example R10 | A | A | A | A |
| Example R11 | A | A | A | A |
| Example R12 | A | A | A | A |
| Example R13 | A | A | A | A |
| Example R14 | A | A | A | A |
| Example R15 | A | B | B | A |
| Example R16 | A | A | B | A |
| Example R17 | A | B | A | A |
| Example R18 | A | A | A | A |
| Example R19 | A | A | A | A |
| Example R20 | A | A | A | A |
| Example R21 | A | A | A | A |
| Example R22 | A | A | A | A |
| Example R23 | A | B | A | A |
| Example R24 | A | B | C | B |
| Example R25 | A | B | B | A |
| Example R26 | A | A | B | A |
| Example R27 | A | A | A | A |
| Example R28 | A | A | A | A |
| Example R29 | A | A | A | B |
| Example R30 | A | A | A | C |
| Example R31 | A | A | A | B |
| Example R32 | A | C | B | A |
| Example R33 | A | B | B | A |
| Example R34 | A | B | A | A |
| Example R35 | A | B | A | A |
| Example R36 | A | B | A | B |
| Example R37 | A | B | A | C |
| Example R37 | A | A | A | B |
| Example R39 | A | A | A | A |
| Example R40 | A | A | A | C |

TABLE 17

| | Evaluation | | | |
|---|---|---|---|---|
| | Light | | Color | Surface |
| | resistance | Adhesiveness | unevenness | roughness |
| Example R41 | A | A | A | B |
| Example R42 | A | A | A | C |
| Example R43 | A | A | A | C |
| Example R44 | A | A | A | B |
| Example R45 | A | B | A | A |
| Example R46 | A | A | A | A |
| Example R47 | A | A | A | A |
| Example R48 | A | A | A | A |
| Example R49 | A | A | A | A |
| Exassglc R50 | A | B | A | A |
| Example R51 | A | A | A | A |
| Example R52 | A | A | A | A |
| Example R53 | A | A | A | A |
| Example R54 | A | A | A | A |
| Comparative | D | A | D | D |
| Example R1 | | | | |
| Comparative | B | D | D | D |
| Example R2 | | | | |
| Comparative | B | B | D | D |
| Example R3 | | | | |
| Comparative | A | C | D | D |
| Example R4 | | | | |
| Comparative | A | C | C | D |
| Example R5 | | | | |

TABLE 18

| | Evaluation | | | |
|---|---|---|---|---|
| | Light | | Color | Surface |
| | resistance | Adhesiveness | unevenness | roughness |
| Example G1 | A | A | A | A |
| Example G2 | A | A | A | A |
| Example G3 | A | A | A | A |
| Example G4 | A | A | A | A |
| Example G5 | A | A | A | A |
| Example G6 | A | A | A | A |
| Example G7 | A | A | A | A |
| Example G8 | A | A | A | A |
| Example G9 | A | A | A | A |
| Example G10 | A | A | A | A |
| Example G11 | A | A | A | A |
| Example G12 | A | A | A | A |
| Example G13 | A | A | A | A |
| Example G14 | A | A | A | A |
| Example G15 | A | B | B | A |
| Example G16 | A | A | B | A |
| Example G17 | A | B | A | A |
| Example G18 | A | A | A | A |
| Example G19 | A | A | A | A |
| Example G20 | A | A | A | A |
| Example G21 | A | A | A | A |
| Example G22 | A | A | A | A |
| Example G23 | A | B | A | A |
| Example G24 | A | B | C | B |
| Example G25 | A | B | B | A |
| Example G26 | A | A | B | A |
| Example G27 | A | A | A | A |
| Example G28 | A | A | A | A |
| Example G29 | A | A | A | B |
| Example G30 | A | A | A | C |
| Example G31 | A | C | C | B |
| Example G32 | A | C | B | A |
| Example G33 | A | B | B | A |
| Example G34 | A | B | A | A |
| Example G35 | A | B | A | A |
| Example G36 | A | B | A | B |
| Example G37 | A | B | A | C |
| Example G38 | A | A | A | B |
| Example G39 | A | A | A | A |
| Example G40 | A | A | A | C |
| Example G41 | A | A | A | B |
| Example G42 | A | A | A | C |
| Example G43 | A | A | A | C |
| Example G44 | A | A | A | B |
| Comparative | D | A | D | D |
| Example G1 | | | | |
| Comparative | B | D | D | D |
| Example G2 | | | | |
| Comparative | B | B | D | D |
| Example G3 | | | | |
| Comparative | A | C | D | D |
| Example G4 | | | | |
| Comparative | A | C | C | D |
| Example G5 | | | | |

TABLE 19

| | Evaluation | | | |
|---|---|---|---|---|
| | Light | | Color | Surface |
| | resistance | Adhesiveness | unevenness | roughness |
| Example B1 | A | A | A | A |
| Example B2 | A | A | A | A |
| Example B3 | A | A | A | A |
| Example B4 | A | A | A | A |
| Example B5 | A | A | A | A |
| Example B6 | A | A | A | A |
| Example B7 | A | A | A | A |
| Example B8 | A | A | A | A |
| Example B9 | A | A | A | A |
| Example B10 | A. | A | A | A |
| Example B11 | A | B | B | A |
| Example B12 | A | A | B | A |
| Example B13 | A | B | A | A |
| Example B14 | A | A | A | A |
| Example B15 | A | A | A | A |
| Example B16 | A | A | A | A |
| Example B17 | A | A | A | A |
| Example B18 | A | A | A | A |
| Example B19 | A | B | A | A |
| Example B20 | A | B | C | B |
| Example B21 | A | B | B | A |
| Example B22 | A | A | B | A |
| Example B23 | A | A | A | A |
| Example B24 | A | A | A | A |
| Exampls B25 | A | A | A | B |
| Example B26 | A | A | A | C |
| Example B27 | A | C | C | B |
| Example B28 | A | C | B | A |
| Example B29 | A | B | B | A |
| Exarsple B30 | A | B | A | A |
| Example B31 | A | B | A | A |
| Example B32 | A | B | A | B |
| Example B33 | A | B | A | C |
| Example B34 | A | A | A | B |
| Example B35 | A | A | A | A |
| Example B36 | A | A | A | C |
| Example B37 | A | A | A | B |
| Example B38 | A | A | A | C |
| Example B39 | A | A | A | C |
| Example B40 | A | A | A | B |
| Comparative | D | A | D | D |
| Example B1 | | | | |
| Comparative | B | D | D | D |
| Example B2 | | | | |
| Comparative | B | H | D | D |
| Example B3 | | | | |
| Comparative | A | C | D | D |
| Example B4 | | | | |
| Comparative | A | C | C | D |
| Example B5 | | | | |

TABLE 20

| | Evaluation | | | |
|---|---|---|---|---|
| | Light | | Color | Surface |
| | resistance | Adhesiveness | unevenness | roughness |
| Example C1 | A | A | A | A |
| Example C2 | A | A | A | A |
| Example C3 | A | A | A | A |
| Exasssle C4 | A | A | A | A |
| Example C5 | A | B | B | A |
| Example C6 | A | A | B | A |
| Example C7 | A | B | A | A |
| Example C8 | A | A | A | A |
| Example C9 | A | A | A | A |
| Exasspls C10 | A | A | A | A |
| Example C11 | A | A | A | A |
| Example C12 | A | A | A | A |
| Example C13 | A | B | A | A |
| Comparative | D | A | D | D |
| Example C1 | | | | |
| Comparative | B | D | D | D |
| Example C2 | | | | |
| Comparative | B | B | D | D |
| Example C3 | | | | |
| Comparative | A | C | D | D |
| Example C4 | | | | |
| Comparative | A | C | C | D |
| Example C5 | | | | |

TABLE 21

| | Evaluation | | | |
|---|---|---|---|---|
| | Light | | Color | Surface |
| | resistance | Adhesiveness | unevenness | roughness |
| Example M1 | A | A | A | A |
| Exsmple M2 | A | A | A | A |
| Example M3 | A | A | A | A |
| Example M4 | A | A | A | A |
| Example M5 | A | A | A | A |
| Exampie M6 | A | A | A | A |
| Example M7 | A | A | A | A |
| Example M8 | A | B | B | A |
| Example M9 | A | A | B | A |
| Example M10 | A | B | A | A |
| Example M11 | A | A | A | A |
| Example M12 | A | A | A | A |
| Example M13 | A | A | A | A |
| Example M14 | A | A | A | A |
| Example M15 | A | A | A | A |
| Example M16 | A | B | A | A |
| Comparative | D | A | D | D |
| Example M1 | | | | |
| Comparative | B | D | D | D |
| Example M2 | | | | |
| Comparative | B | B | D | D |
| Example M3 | | | | |
| Comparative | A | C | D | D |
| Example M4 | | | | |
| Comparative | A | C | C | D |
| Example M5 | | | | |

TABLE 22

| | Evaluation | | | |
|---|---|---|---|---|
| | Light | | Color | Surface |
| | resistance | Adhesiveness | unevenness | roughness |
| Example Y1 | A | A | A | A |
| Example Y2 | A | A | A | A |
| Example Y3 | A | A | A | A |
| Example Y4 | A | A | A | A |
| Example Y5 | A | A | A | A |
| Example Y6 | A | A | A | A |
| Example Y7 | A | A | A | A |
| Example Y8 | A | B | B | A |
| Example Y9 | A | A | B | A |
| Example Y10 | A | B | A | A |
| Example Y11 | A | A | A | A |
| Example Y12 | A | A | A | A |
| Example Y13 | A | A | A | A |
| Example Y14 | A | A | A | A |
| Example Y15 | A | A | A | A |
| Example Y16 | A | B | A | A |
| Comparative | D | A | D | D |
| Example Y1 | | | | |
| Comparative | B | D | D | D |
| Example Y2 | | | | |
| Comparative | B | B | D | D |
| Example Y3 | | | | |
| Comparative | A | C | D | D |
| Example Y4 | | | | |
| Comparative | A | C | C | D |
| Example Y5 | | | | |

As shown in the above tables, in Examples, each item of light resistance, adhesiveness, color unevenness, and surface roughness could be achieved at a high level. On the other hand, in Comparative Examples, any of light resistance, adhesiveness, color unevenness, or surface roughness was evaluated as D rank, which was inferior to Examples.

### Example 1001

A silicon wafer was coated with a green photosensitive composition by a spin coating method so that a thickness of a film after film formation was 1.0 μm. Next, the silicon wafer was heated using a hot plate at 100° C. for 2 minutes. Next, using an i-ray stepper exposure device FPA-3000 i5+ (manufactured by Canon Inc.), exposure was performed with light having an exposure amount of 1000 mJ/cm² through a mask having a dot pattern of 2 μm square. Next, puddle development was performed at 23° C. for 60 seconds using a 0.3% by mass of tetramethylammonium hydroxide (TMAH) aqueous solution. Next, the coating film was rinsed by spin showering and was cleaned with pure water. Next, the green photosensitive composition was patterned by heating at 200° C. for 5 minutes using a hot plate to form a green pixel. In the same process, a red photosensitive composition and a blue photosensitive composition were patterned to sequentially form a red pixel and a blue pixel, thereby forming a color filter having the green pixel, red pixel, and blue pixel. In this color filter, the green pixel was formed in a Bayer pattern, and the red pixel and blue pixel were formed in an island pattern in an adjacent region thereof. The obtained color filter was incorporated into a solid-state imaging element according to a known method. The solid-state imaging element had a suitable image recognition ability. As the green photosensitive composition, the photosensitive composition of Example G1 was used. As the red photosensitive composition, the photosensitive composition of Example R1 was used. As the blue photosensitive composition, the photosensitive composition of Example B1 was used.

### Example 1002

A silicon wafer was coated with a cyan photosensitive composition by a spin coating method so that a thickness of a film after film formation was 1.0 μm. Next, the silicon wafer was heated using a hot plate at 100° C. for 2 minutes. Next, using an i-ray stepper exposure device FPA-3000 i5+(manufactured by Canon Inc.), exposure was performed with light having an exposure amount of 1000 mJ/cm² through a mask having a dot pattern of 2 μm square. Next, puddle development was performed at 23° C. for 60 seconds using a 0.3% by mass of tetramethylammonium hydroxide (TMAH) aqueous solution. Next, the coating film was rinsed by spin showering and was cleaned with pure water. Next, the cyan photosensitive composition was patterned by heating at 200° C. for 5 minutes using a hot plate to form a cyan pixel. In the same process, a yellow photosensitive composition and a magenta photosensitive composition were patterned to sequentially form a yellow pixel and a magenta pixel, thereby forming a color filter having the cyan pixel, yellow pixel, and magenta pixel. In this color filter, the cyan pixel was formed in a Bayer pattern, and the yellow pixel and magenta pixel were formed in an island pattern in an adjacent region thereof. The obtained color filter was incorporated into a solid-state imaging element according to a known method. The solid-state imaging element had a suitable image recognition ability. As the cyan photosensitive composition, the photosensitive composition of Example C1 was used. As the yellow photosensitive composition, the photosensitive composition of Example Y1 was used. As the magenta photosensitive composition, the photosensitive composition of Example M1 was used.

What is claimed is:

1. A photosensitive composition comprising:
a coloring material;
a photopolymerization initiator;
a polymerizable monomer; and
a resin,
wherein the photopolymerization initiator includes an oxime compound OX having an aromatic ring group Ar^{OX1} in which an electron withdrawing group is introduced into an aromatic ring, and
a value obtained by dividing a mass of the polymerizable monomer by a mass of the photopolymerization initiator is 0.5 to 5.5.

2. The photosensitive composition according to claim 1,
wherein a content of the oxime compound OX in the photopolymerization initiator is 50% to 100% by mass.

3. The photosensitive composition according to claim 1,
wherein the electron withdrawing group included in the aromatic ring group Ar^{OX1} is at least one selected from an acyl group or a nitro group.

4. The photosensitive composition according to claim 1,
wherein the electron withdrawing group included in the aromatic ring group Ar^{OX1} is an acyl group.

5. The photosensitive composition according to claim 1,
wherein the aromatic ring group Ar^{OX1} is a group represented by Formula (OR-1), 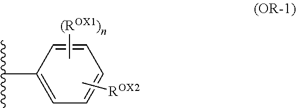
in the formula, R^{OX1} represents a substituent, R^{OX2} represents an electron withdrawing group, n represents an integer of 0 to 4, and a wavy line represents a bonding site.

6. The photosensitive composition according to claim 1,
wherein the oxime compound OX has at least one group selected from a group represented by Formula (OR-11) or a group represented by Formula (OR-12), 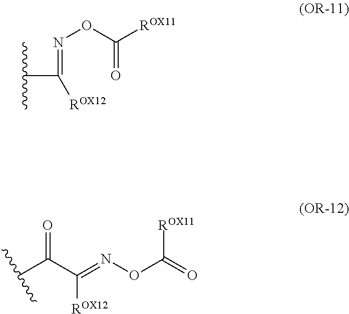
in the formula, R^{OX11} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyl group, an acyloxy group, an amino group, a phosphinoyl group, a carbamoyl group, or a sulfamoyl group,
R^{OX12} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyloxy group, or an amino group, and
a wavy line represents a bonding site.

7. The photosensitive composition according to claim 1,
wherein the oxime compound OX is at least one selected from a compound represented by Formula (OX1) or a compound represented by Formula (OX2), 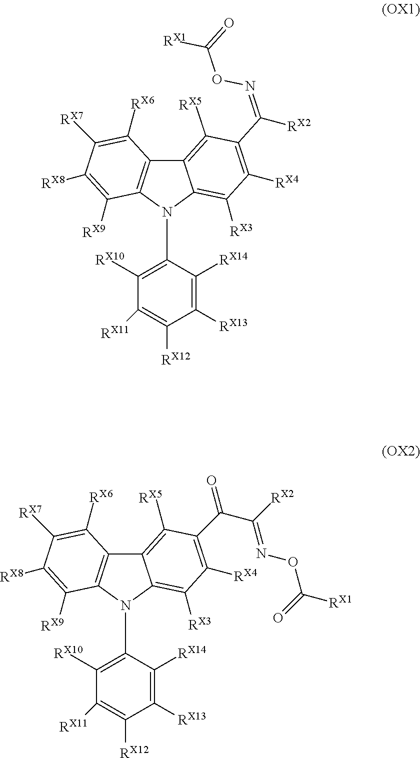
in the formula, R^{X1} represents an alkyl group, an alkenyl group, an alkoxy group, an aryl group, an aryloxy group, a heterocyclic group, a heterocyclic oxy group, an aikylsulfanyl group, an arylsulfanyl group, an alkylsulfinyl group, an arylsulfinyl group, an alkylsulfonyl group, an arylsulfonyl group, an acyl group, an acyloxy group, an amino group, a phosphinoyl group, a carbamoyl group, or asulfamoyl group,
R^{X2} represents an alkyl group, an alkenyl group, an alkoxy group, an aryl group, an aryloxy group, a heterocyclic group, a heterocyclic oxy group, an alkylsulfanyl group, an arylsulfanyl group, an alkylsulfinyl group, an arylsulfinyl group, an alkylsulfonyl group, an arylsulfonyl group, an acyloxy group, or an amino group,
R^{X3} to R^{X14} each independently represent a hydrogen atom or a substituent, and
at least one of R^{X10} to R^{X14} is an electron withdrawing group.

8. The photosensitive composition according to claim 1,
wherein the polymerizable monomer includes a compound having 3 ethylenically unsaturated bond-containing groups.

9. The photosensitive composition according to claim 1,
wherein an ethylenically unsaturated bond-containing group value of the polymerizable monomer is 100 to 300 g/mol.

10. The photosensitive composition according to claim 1,
wherein a content of the coloring material in a total solid content of the photosensitive composition is 50% by mass or more.

11. The photosensitive composition according to claim 1,
wherein a content of the polymerizable monomer in a total solid content of the photosensitive composition is 1% to 25% by mass.

12. The photosensitive composition according to claim 1,
wherein the photosensitive composition is used for a solid-state imaging element.

13. The photosensitive composition according to claim 1,
wherein the photosensitive composition is a photosensitive composition for forming a pixel for a cyan color, a yellow color, or a magenta color.

14. A film formed of the photosensitive composition according to claim 1.

15. An optical filter comprising:
the film according to claim 14.

16. A solid-state imaging element comprising:
the film according to claim 14.

17. An image display device comprising:
the film according to claim 14.
